(19) United States
(12) Patent Application Publication
(10) Pub. No.: US 2026/0314213 A1
(43) Pub. Date: Oct. 8, 2026

(54) Display Substrate and Manufacturing Method Therefor, and Display Device

(71) Applicants: Chongqing BOE Display Technology Co.,Ltd., Chongqing (CN); BOE Technology Group Co., Ltd., Beijing (CN)

(72) Inventors: Xiaoling HE, Beijing (CN); Runxin ZHANG, Beijing (CN); Rui WANG, Beijing (CN); Shouqiang ZHANG, Beijing (CN); Chao ZENG, Beijing (CN)

(21) Appl. No.: 19/481,541

(22) PCT Filed: Feb. 17, 2025
(86) PCT No.: PCT/CN2025/077591

§ 371 Date: Nov. 5, 2025

(30) Foreign Application Priority Data
Mar. 8, 2024 (CN) 202410268975.6

(51) Int. Cl. H10K 59/131; H10K 59/12; H10K 59/121; H10K 59/122; H10K 59/126

(52) U.S. Cl. CPC H10K 59/1315; H10K 59/1201; H10K 59/1213; H10K 59/1216; H10K 59/122; H10K 59/126

(57) ABSTRACT

A display substrate and a manufacturing method therefor, and a display device are provided. The display substrate includes a driving structure layer and a light-emitting structure layer. The driving structure layer includes a plurality of circuit units; a circuit unit includes a pixel driving circuit, a power connection line, and a first power line; the pixel driving circuit at least includes a power connection electrode; the power connection electrode is connected to the power connection line; and the first power line is connected to the power connection line or the power connection electrode through a power via hole. The light-emitting structure layer includes a plurality of light-emitting units; at least one light-emitting unit includes an anode and a pixel definition layer; the anode is connected to the pixel driving circuit of a corresponding circuit unit; a pixel opening exposing the anode is formed in the pixel definition layer.

### CROSS-REFERENCE TO RELATED APPLICATIONS

The present application is a U.S. National Phase Entry of International Application No. PCT/CN2025/077591 having an international filing date of Feb. 17, 2025, which claims priority to Chinese Patent Application No. 202410268975.6 filed to the CNIPA on Mar. 8, 2024 and entitled “Display Substrate and Manufacturing method Therefor, and Display device”, contents of which should be construed as being incorporated into the present application by reference.

### TECHNICAL FIELD

The present disclosure relates to, but is not limited to, the field of display technologies, and particularly to a display substrate and a manufacturing method therefor, and a display device.

### BACKGROUND

An organic light emitting diode (OLED) and a quantum dot light emitting diode (QLED) are active light emitting display devices and have advantages of self-illumination, a wide viewing angle, a high contrast ratio, low power consumption, an extremely high reaction speed, lightness and thinness, flexibility, and a low cost, etc. With constant development of display technologies, a flexible display device (Flexible Display) in which an OLED or a QLED is used as a light emitting device and signal control is performed through a thin film transistor (TFT) has become a mainstream product in the field of display at present.

### SUMMARY

The following is a summary of subject matters described herein in detail. This summary is not intended to limit the protection scope of claims.

In one aspect, the present disclosure provides a display substrate including a drive structure layer disposed on a base substrate and a light emitting structure layer disposed on a side of the drive structure layer away from the base substrate; on a plane parallel to the display substrate, the drive structure layer includes a plurality of circuit units, at least one circuit unit includes a pixel drive circuit, a power supply connection line extending along a first direction, and a first power supply line extending along a second direction, the first direction and the second direction intersect, the pixel drive circuit includes at least a power supply connection electrode connected to the power supply connection line, the first power supply line is connected to the power supply connection line or the power supply connection electrode through a power supply via; the light emitting structure layer includes a plurality of light emitting units, at least one light emitting unit includes an anode and a pixel definition layer disposed on a side of the anode away from the base substrate, the anode is connected with a pixel drive circuit of a corresponding circuit unit, the pixel definition layer is provided with a pixel opening exposing the anode, and an orthographic projection of at least one pixel opening on the base substrate and an orthographic projection of the power supply via on the base substrate do not overlap.

In an exemplary embodiment, the plurality of light emitting units include at least a first light emitting unit emitting light of a first color, a second light emitting unit emitting light of a second color, and a third light emitting unit emitting light of a third color, the first light emitting unit includes at least a first anode and a first pixel opening exposing the first anode, the second light emitting unit includes at least a second anode and a second pixel opening that exposes the second anode, the third light emitting unit includes at least a third anode and a third pixel opening that exposes the third anode; the second anode is disposed at a side of the first anode in the second direction, and the third anode is disposed at a side of the first anode in the first direction; orthographic projections of the first pixel opening and the second pixel opening on the base substrate are at least partially overlapped with an orthographic projection of the first power supply line on the base substrate, and an orthographic projection of the third pixel opening on the base substrate is not overlapped with the orthographic projection of the first power supply line on the base substrate.

In an exemplary embodiment, the orthographic projections of the first pixel opening and the second pixel opening on the base substrate are within a range of the orthographic projection of the first power supply line on the base substrate.

In an exemplary embodiment, in the at least one circuit unit and a circuit unit adjacent in the first direction, first power supply lines in the two circuit units are of an interconnected integral structure.

In an exemplary embodiment, the at least one circuit unit further includes a data signal line, and in the at least one circuit unit and a circuit unit adjacent in the first direction, the data signal line in one circuit unit is disposed at a side of the first power supply line in an opposite direction of the first direction, and the data signal line in the other circuit unit is disposed at a side of the first power supply line in the first direction; the orthographic projections of the first pixel opening and the second pixel opening on the base substrate are not overlapped with an orthographic projection of the data signal line on the base substrate, and the orthographic projection of the third pixel opening on the base substrate is at least partially overlapped with the orthographic projection of the data signal line on the base substrate.

In an exemplary embodiment, the pixel drive circuit further includes a fourth transistor and a data connection electrode, the fourth transistor includes at least a fourth active layer, and the data signal line is connected to the data connection electrode through a data via; in the at least one circuit unit and a circuit unit adjacent in the first direction, the data connection electrode in one circuit unit is connected to the first region of the fourth active layer through a via, and the data connection electrode in the other circuit unit is connected to the first region of the fourth active layer through a data connection line.

In an exemplary embodiment, the pixel drive circuit further includes a blocking electrode and a second transistor with a double-gate structure, the blocking electrode is connected to the first power supply line, an orthographic projection of the blocking electrode on the base substrate is at least partially overlapped with an orthographic projection of a second active layer between two gate electrodes of the second transistor on the base substrate, and the orthographic projection of the blocking electrode on the base substrate is at least partially overlapped with an orthographic projection of the data connection line on the base substrate.

In an exemplary embodiment, the pixel drive circuit further includes a fourth node electrode and an anode connection electrode, and an anode in the at least one light emitting unit is connected to the anode connection electrode through an anode via; in the at least one circuit unit and a circuit unit adjacent in the first direction, the anode connection electrode in one circuit unit is connected to the fourth node electrode through a via, and the anode connection electrode in the other circuit unit is connected to the fourth node electrode through an anode connection line; the orthographic projections of the first pixel opening and the second pixel opening on the base substrate are not overlapped with an orthographic projection of the anode connection line on the base substrate, and the orthographic projection of the third pixel opening on the base substrate is at least partially overlapped with the orthographic projection of the anode connection line on the base substrate.

In an exemplary embodiment, the third pixel opening has an opening centerline that is a straight line extending along the second direction and passing through a geometric center of the third pixel opening; in at least one third pixel opening, there is a first distance between the anode connection line and the opening centerline, there is a second distance between the data signal line and the opening centerline, and a ratio of the first distance to the second distance is 0.8 to 1.2.

In an exemplary embodiment, the at least one circuit unit further includes at least one initial signal line extending along the first direction and a second power supply line and an initial connection line extending along the second direction, the initial connection line is connected to the initial signal line, the orthographic projections of the first pixel opening and the second pixel opening on the base substrate are not overlapped with orthographic projections of the second power supply line and the initial connection line on the base substrate, and the orthographic projection of the third pixel opening on the base substrate is at least partially overlapped with the orthographic projections of the second power supply line and the initial connection line on the base substrate.

In an exemplary embodiment, the third pixel opening has an opening centerline that is a straight line extending along the second direction and passing through a geometric center of the third pixel opening; in at least one third pixel opening, there is a third distance between the second power supply line and the opening centerline, there is a fourth distance between the initial connection line and the opening centerline, and a ratio of the third distance to the fourth distance is 0.8 to 1.2.

In an exemplary embodiment, the pixel drive circuit further includes a storage capacitor, and the at least one circuit unit further includes a first scan signal line, a second scan signal line, a third scan signal line, a light emitting signal line, a first initial signal line, a second initial signal line, and a third initial signal line extending along the first direction and connected to the pixel drive circuit, the first scan signal line is disposed at a side of the storage capacitor in an opposite direction of the second direction, the third scan signal line is disposed at a side of the first scan signal line away from the storage capacitor, the first initial signal line is disposed at a side of the third scan signal line away from the storage capacitor, the light emitting signal line is disposed at a side of the storage capacitor in the second direction, the second scan signal line is disposed at a side of the light emitting signal line away from the storage capacitor, the second initial signal line is disposed at a side of the second scan signal line away from the storage capacitor, the third initial signal line is disposed at a side of the second initial signal line away from the storage capacitor; an orthographic projection of at least one first pixel opening on the base substrate is at least partially overlapped with an orthographic projection of the power supply connection line on the base substrate, an orthographic projection of at least one second pixel opening on the base substrate is at least partially overlapped with orthographic projections of the first initial signal line, the second initial signal line and the third initial signal line on the base substrate, and an orthographic projection of at least one third pixel opening on the base substrate is at least partially overlapped with orthographic projections of the second scan signal line, the light emitting signal line, the second initial signal line and the power supply connection line on the base substrate.

In an exemplary embodiment, the orthographic projection of the at least one first pixel opening on the base substrate is not overlapped with an orthographic projection of the first initial signal line on the base substrate, the orthographic projection of the at least one second pixel opening on the base substrate is not overlapped with orthographic projections of the first scan signal line and the power supply connection line on the base substrate, and the orthographic projection of the at least one third pixel opening on the base substrate is not overlapped with orthographic projections of the first scan signal line and the third scan signal line on the base substrate.

In an exemplary embodiment, the plurality of light emitting units include at least a first light emitting unit emitting light of a first color, a second light emitting unit emitting light of a second color, and a third light emitting unit emitting light of a third color, the first light emitting unit includes at least a first anode and a first pixel opening exposing the first anode, the second light emitting unit includes at least a second anode and a second pixel opening that exposes the second anode, the third light emitting unit includes at least a third anode and a third pixel opening that exposes the third anode; the second anode is disposed at a side of the first anode in the second direction, and the third anode is disposed at a side of the first anode in the first direction; the pixel drive circuit further includes a data connection electrode, and the at least one circuit unit further includes a data signal line connected to the data connection electrode through a data via; orthographic projections of the first pixel opening, the second pixel opening, and the third pixel opening on the base substrate are not overlapped with an orthographic projection of the data via on the base substrate.

In an exemplary embodiment, the plurality of circuit units include at least a first circuit unit, a second circuit unit and a third circuit unit disposed sequentially along the first direction, the first circuit unit includes at least a first pixel drive circuit and a first data signal line connected to the data connection electrode in the first pixel drive circuit through a first data via, the second circuit unit includes at least a second pixel drive circuit and a second data signal line connected to the data connection electrode in the second pixel drive circuit through a second data via, the third circuit unit includes at least a third pixel drive circuit and a third data signal line connected to the data connection electrode in the third pixel drive circuit through a third data via, orthographic projections of the first pixel opening and the second pixel opening on the base substrate are at least partially overlapped with an orthographic projection of the first data signal line on the base substrate, and an orthographic projection of the third pixel opening on the base substrate is not overlapped with orthographic projections of the first data signal line, the second data signal line, and the third data signal line on the base substrate.

In an exemplary embodiment, in the first direction, a pitch between the first data signal line and the second data signal line is smaller than a pitch between the second data signal line and the third data signal line, and a pitch between the first data via and the second data via is smaller than a pitch between the second data via and the third data via.

In an exemplary embodiment, the second data via and the third data via are disposed at two sides of the third pixel opening in the first direction, and the first data via is disposed between the first pixel opening and the second pixel opening in the second direction.

In an exemplary embodiment, the pixel drive circuit includes at least a storage capacitor, and the at least one circuit unit further includes a first scan signal line, a second scan signal line, a third scan signal line, a light emitting signal line, a first initial signal line, a second initial signal line, and a third initial signal line extending along the first direction and connected to the pixel drive circuit, the first scan signal line is disposed at a side of the storage capacitor in an opposite direction of the second direction, the third scan signal line is disposed at a side of the first scan signal line away from the storage capacitor, the first initial signal line is disposed at a side of the third scan signal line away from the storage capacitor, the light emitting signal line is disposed at a side of the storage capacitor in the second direction, the second scan signal line is disposed at a side of the light emitting signal line away from the storage capacitor, the second initial signal line is disposed at a side of the second scan signal line away from the storage capacitor, the third initial signal line is disposed at a side of the second initial signal line away from the storage capacitor; an orthographic projection of at least one first pixel opening on the base substrate is at least partially overlapped with an orthographic projection of the first initial signal line on the base substrate, an orthographic projection of at least one second pixel opening on the base substrate is at least partially overlapped with orthographic projections of the first scan signal line and the power supply connection line on the base substrate, and an orthographic projection of at least one third pixel opening on the base substrate is at least partially overlapped with orthographic projections of the first scan signal line and the third scan signal line on the base substrate.

In an exemplary embodiment, the orthographic projection of the at least one first pixel opening on the base substrate is not overlapped with an orthographic projection of the power supply connection line on the base substrate, the orthographic projection of the at least one second pixel opening on the base substrate is not overlapped with orthographic projections of the first initial signal line, the second initial signal line, and the third initial signal line on the base substrate, and the orthographic projection of the at least one third pixel opening on the base substrate is not overlapped with orthographic projections of the second scan signal line, the light emitting signal line, the power supply connection line, and the second initial signal line on the base substrate.

In another aspect, a display device is further provided in the present disclosure, and the display device includes the display substrate described above.

In another aspect, the present disclosure further provides a preparation method for a display substrate, including:
Forming a drive structure layer on a base substrate, the drive structure layer includes a plurality of circuit units, at least one circuit unit includes a pixel drive circuit, a power supply connection line extending along a first direction, and a first power supply line extending along a second direction, the first direction and the second direction intersect, the pixel drive circuit includes at least a power supply connection electrode connected to the power supply connection line, the first power supply line is connected to the power supply connection line or the power supply connection electrode through a power supply via; and
Forming a light emitting structure layer on the drive structure layer; the light emitting structure layer includes a plurality of light emitting units, at least one light emitting unit includes an anode and a pixel definition layer disposed on a side of the anode away from the base substrate, the anode is connected with a pixel drive circuit of a corresponding circuit unit, the pixel definition layer is provided with a pixel opening exposing the anode, and an orthographic projection of at least one pixel opening on the base substrate and an orthographic projection of the power supply via on the base substrate do not overlap.

Other aspects of the present disclosure may be comprehended after the drawings and the detailed descriptions are read and understood.

### BRIEF DESCRIPTION OF DRAWINGS

Accompanying drawings are used to provide an understanding of technical solutions of the present disclosure, and form a part of the specification. The accompanying drawings and embodiments of the present disclosure are adopted to explain the technical solutions of the present disclosure, and do not form limitations on the technical solutions of the present disclosure.

FIG. 1 is a schematic diagram of a structure of a display device.

FIG. 2 is a schematic diagram of a planar structure of a display substrate.

FIG. 3 is a schematic diagram of a sectional structure of a display substrate.

FIG. 4 is a schematic diagram of an equivalent circuit of a pixel drive circuit.

FIG. 5 is a schematic diagram of a planar structure of a display substrate according to an exemplary embodiment of the present disclosure.

FIG. 6 is a schematic diagram of a display substrate after a pattern of a shielding layer is formed according to the present disclosure.

FIG. 7A and FIG. 7B are schematic diagrams of a display substrate after a pattern of a semiconductor layer is formed according to the present disclosure.

FIGS. 8A and 8B are schematic diagrams of a display substrate after a pattern of a first conductive layer is formed according to the present disclosure.

FIGS. 9A and 9B are schematic diagrams of a display substrate after a pattern of a second conductive layer is formed according to the present disclosure.

FIG. 10 is a schematic diagram of a display substrate after a pattern of a fourth insulating layer is formed according to the present disclosure.

FIGS. 11A and 11B are schematic diagrams of a display substrate after a pattern of a third conductive layer is formed according to the present disclosure.

FIG. 12 is a schematic diagram of a display substrate after a pattern of a first planarization layer is formed according to the present disclosure.

FIGS. 13A and 13B are schematic diagrams of a display substrate after a pattern of a fourth conductive layer is formed according to the present disclosure.

FIG. 14 is a schematic diagram of a display substrate after a pattern of a second planarization layer is formed according to the present disclosure.

FIGS. 15A and 15B are schematic diagrams of a display substrate after a pattern of an anode conductive layer is formed according to the present disclosure.

FIG. 16 is a schematic diagram of a display substrate after a pattern of a pixel definition layer is formed according to the present disclosure.

FIG. 17 is a schematic diagram of a positional relationship between a third pixel opening and signal lines according to an embodiment of the present disclosure.

FIG. 18 is a schematic diagram of a planar structure of another display substrate according to an exemplary embodiment of the present disclosure.

FIG. 19 is a schematic diagram of another display substrate after a pattern of a shielding layer is formed according to the present disclosure.

FIG. 20A and FIG. 20B are schematic diagrams of another display substrate after a pattern of a semiconductor layer is formed according to the present disclosure.

FIGS. 21A and 21B are schematic diagrams of another display substrate after a pattern of a first conductive layer is formed according to the present disclosure.

FIGS. 22A and 22B are schematic diagrams of another display substrate after a pattern of a second conductive layer is formed according to the present disclosure.

FIG. 23 is a schematic diagram of another display substrate after a pattern of a fourth insulating layer is formed according to the present disclosure.

FIGS. 24A and 24B are schematic diagrams of another display substrate after a pattern of a third conductive layer is formed according to the present disclosure.

FIG. 25 is a schematic diagram of another display substrate after a pattern of a first planarization layer is formed according to the present disclosure.

FIGS. 26A and 26B are schematic diagrams of another display substrate after a pattern of a fourth conductive layer is formed according to the present disclosure.

FIG. 27 is a schematic diagram of another display substrate after a pattern of a second planarization layer is formed according to the present disclosure.

FIGS. 28A and 28B are schematic diagrams of another display substrate after a pattern of an anode conductive layer is formed according to the present disclosure.

FIG. 29 is a schematic diagram of yet another display substrate after a pattern of a pixel definition layer is formed according to the present disclosure.

Reference signs are described as follows.

| | | |
|---|---|---|
| 11-First active layer; | 12-Second active layer; | 13-Third active layer; |
| 14-Fourth active layer; | 15-Fifth active layer; | 16-Sixth active layer; |
| 17-Seventh active layer; | 18- eighth active layer; | 21-First gate electrode; |
| 22-Second gate electrode; | 24-Fourth gate electrode; | 31-First scan signal line; |
| 32-Second scan signal line | 33-Third scan signal line; | 34-Light emitting signal line; |
| 35- Blocking electrode; | 41-First initial signal line; | 42-Second initial signal line; |
| 43-Third initial signal line; | 44-Power supply connection | 45-Auxiliary scan signal line |
| | line; | |
| 46-Data connection line; | 51-First connection electrode; | 52-Second connection |
| | | electrode; |
| 53-Third connection | 54-Fourth connection | 55-Fifth connection electrode; |
| electrode; | electrode; | |
| 56-Sixth connection | 61-Data signal line; | 62-Anode connection |
| electrode; | | electrode; |
| 63-Anode connection line; | 64-Extension electrode; | 71-First power supply line; |
| 72-Second power supply line; | 73-Initial connection line; | 81-First plate; |
| 82-Second plate; | 83-Plate-level connection | 84-Opening; |
| | strip | |
| 90-Shielding electrode; | 91-First shielding connection | 92-Second shielding |
| | strip; | connection strip; |
| 93-Third shielding connection | 94-First shielding block; | 95-Second shielding block; |
| strip; | | |
| 101-Base substrate; | 102-Drive structure layer; | 103-Light emitting structure |
| | | layer; |
| 104-Encapsulation structure | | |
| layer. | | |

### DETAILED DESCRIPTION

To make objectives, technical solutions, and advantages of the present disclosure clearer, the embodiments of the present disclosure will be described in detail below with reference to the accompanying drawings. It is to be noted that implementations may be implemented in multiple different forms. Those of ordinary skills in the art may easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of various film layers, and a width and spacing of various signal lines may be adjusted according to actual needs. A quantity of pixels in a display substrate and a quantity of sub-pixels in each pixel are not limited to numbers shown in the drawings. The drawings described in the present disclosure are schematic structural diagram only, and one implementation of the present disclosure is not limited to shapes, numerical values, or the like shown in the drawings.

Ordinal numerals “first”, “second”, “third” and the like in the specification are set not to form limits in numbers but only to avoid confusion between constituent elements.

In the specification, for convenience, expressions “central”, “above”, “below”, “front”, “back”, “vertical”, “horizontal”, “top”, “bottom”, “inside”, “outside” and the like for indicating directional or positional relationships are used to illustrate positional relationships between the constituent elements with reference to the accompanying drawings, not to indicate or imply that involved devices or elements are required to have specific orientations or are structured and operated in the specific orientations but only to easily describe the present specification and simplify the description, and thus should not be understood as limitations on the present disclosure. The positional relationships between the constituent elements may be changed as appropriate based on a direction according to which each constituent element is described. Therefore, appropriate replacements based on situations are allowed, which is not limited to the expressions in the specification.

In the specification, unless otherwise explicitly specified and defined, terms “mounting”, “coupling”, and “connection” should be understood in a broad sense. For example, a connection may be a fixed connection, or a detachable connection, or an integral connection; it may be a mechanical connection or an electrical connection; it may be a direct connection, or an indirect connection through a middleware, or an internal communication between two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as a “source terminal” and a “drain terminal”, are interchangeable in the specification.

In the specification, an “electrical connection” includes a case that constituent elements are connected together through an element with a certain electrical action. The “element with a certain electrical action” is not particularly limited as long as electrical signals between the connected constituent elements may be sent and received. Examples of the “element with a certain electrical action” not only include an electrode and a wire, but also include a switching element such as a transistor, a resistor, an inductor, a capacitor, other elements with various functions, etc.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In the specification, a “film” and a “layer” are interchangeable. For example, a “conductive layer” may be replaced with a “conductive film” sometimes. Similarly, an “insulation film” may be replaced with an “insulating layer” sometimes.

A triangle, rectangle, trapezoid, pentagon, or hexagon, or the like in the specification is not strictly defined, and it may be an approximate triangle, rectangle, trapezoid, pentagon, or hexagon, or the like. There may be some small deformations caused by tolerance, and there may be a chamfer, an arc edge, deformation, etc.

In the present disclosure, “about” means that a boundary is not defined so strictly and numerical values within process and measurement error ranges are allowed.

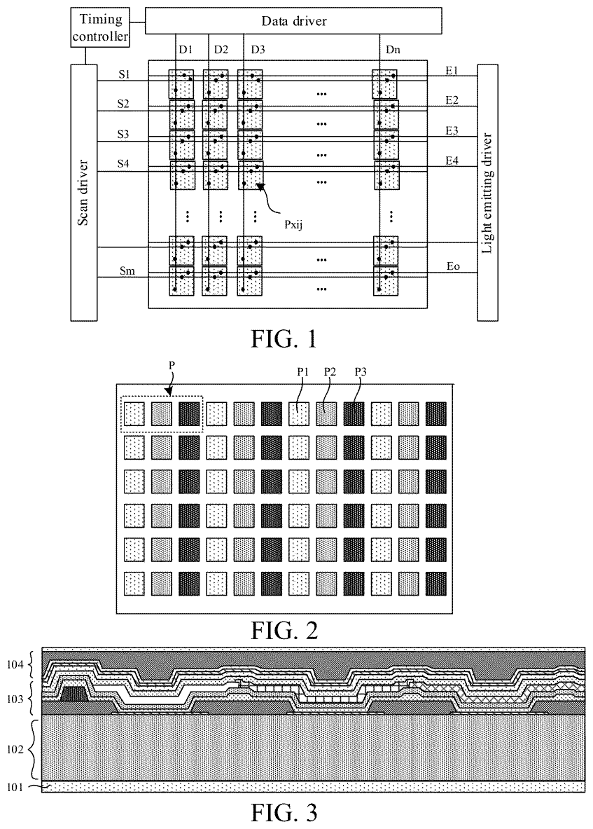

FIG. 1 is a schematic diagram of a structure of a display device. As shown in FIG. 1, the display device may include a timing controller, a data driver, a scan driver, a light emitting driver, and a pixel array. The timing controller is connected to the data driver, the scan driver, and the light emitting driver, respectively, the data driver is connected to a plurality of data signal lines (D1 to Dn) respectively, the scan driver is connected to a plurality of scan signal lines (S1 to Sm) respectively, and the light emitting driver is connected to a plurality of light emitting signal lines (E1 to Eo) respectively. The pixel array may include a plurality of sub-pixels Pxij, i and j may be natural numbers, at least one sub-pixel Pxij may include a circuit unit and a light emitting unit, the circuit unit may include, at least, a pixel drive circuit connected to a scan signal line, a light emitting signal line and a data signal line, respectively.

The light emitting unit may include a light emitting device connected to the pixel drive circuit of the circuit unit. In an exemplary embodiment, the timing controller may provide the data driver with a grayscale value and a control signal which are suitable for a specification of the data driver, provide the scan driver with a clock signal and a scan start signal and the like which are suitable for a specification of the scan driver, and provide the light emitting driver with a clock signal and an emission stop signal and the like which are suitable for a specification of the light emitting driver. The data driver may generate data voltages to be provided to the data signal lines D1, D2, D3, . . . , and Dn using the grayscale value and the control signal that are received from the timing controller. For example, the data driver may sample the grayscale value using the clock signal and apply a data voltage corresponding to the grayscale value to the data signal lines D1 to Dn by taking a pixel row as a unit, wherein n may be a natural number. The scan driver may generate a scan signals to be provided to the scan signal lines S1, S2, S3, . . . , and Sm by receiving the clock signal and the scan start signal from the timing controller. For example, the scan driver may sequentially provide a scan signal with an on-level pulse to the scan signal lines S1 to Sm. For example, the scan driver may be constructed in a form of a shift register and may generate a scan signal in a manner in which a scan start signal provided in a form of an on-level pulse is transmitted to a next-stage circuit sequentially under control of the clock signal, wherein m may be a natural number. The light emitting driver may receive a clock signal, an emission stop signal, etc., from the timing controller to generate an emission signal to be provided to the light emitting signal lines E1, E2, E3, . . . , and Eo. For example, the light emitting driver may sequentially provide an emission signal with an off-level pulse to the light emitting signal lines E1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number. In an exemplary implementation, the pixel array may be arranged on a display substrate.

FIG. 2 is a schematic diagram of a planar structure of a display substrate. As shown in FIG. 2, the display substrate may include a plurality of pixel units P arranged in a matrix. At least one pixel unit P may include a first sub-pixel P1 emitting light of a first color, a second sub-pixel P2 emitting light of a second color, and a third sub-pixel P3 emitting light of a third color. Each sub-pixel may include a circuit unit and a light emitting unit. The circuit unit may at least include a pixel drive circuit, the pixel drive circuit is connected to a scan signal line, a data signal line, and a light emitting signal line respectively, and is configured to receive a data voltage transmitted by the data signal line and output a corresponding current to the light emitting unit under control of the scan signal line and the light emitting signal line. A light emitting unit in each sub-pixel is connected to a pixel drive circuit of the sub-pixel where the light emitting unit is located, and is configured to emit light with corresponding brightness in response to a current output by the pixel drive circuit of the sub-pixel where the light emitting unit is located.

In an exemplary implementation, the first sub-pixels P1 may be red sub-pixels (R) emitting red light, the second sub-pixels P2 may be green sub-pixels (G) emitting green light, and the third sub-pixels P3 may be blue sub-pixels (B) emitting blue light. In an exemplary implementation, a sub-pixel may be in a shape of a rectangle, a rhombus, a pentagon, or a hexagon. Three sub-pixels may be arranged horizontally side by side, vertically side by side, or in a shape of delta, etc., which is not limited here in the present disclosure.

In some other exemplary embodiments, a pixel unit may include four sub-pixels, which may be arranged side by side horizontally, side by side vertically, or in a shape of a square, which is not limited herein in the present disclosure.

FIG. 3 is a schematic diagram of a sectional structure of a display substrate, which illustrates a structure of three sub-pixels. As shown in FIG. 3, on a plane perpendicular to the display substrate, the display substrate may include a drive structure layer 102 disposed on a base substrate 101, a light emitting structure layer 103 disposed on one side of the drive structure layer 102 away from the base substrate 101, and an encapsulation structure layer 104 disposed on one side of the light emitting structure layer 103 away from the base substrate 101. In some possible implementations, the display substrate may include other film layers, such as a touch structure layer, which is not limited here in the present disclosure.

In an exemplary embodiment, the base substrate 101 may be a flexible base substrate, or may be a rigid base substrate. The drive structure layer 102 may include a plurality of circuit units, each circuit unit may at least include a pixel drive circuit formed by a plurality of transistors and a storage capacitor. The light emitting structure layer 103 may include a plurality of light emitting units, and each light emitting unit may at least include an anode, an organic emitting layer, and a cathode. The anode is connected with a pixel drive circuit. The organic emitting layer is connected with the anode. The cathode is connected with the organic emitting layer. The organic emitting layer emits light of a corresponding color under drive of the anode and the cathode. The encapsulation structure layer 104 may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer is arranged between the first encapsulation layer and the third encapsulation layer to form a stacked structure of inorganic material/organic material/inorganic material and ensure that external moisture cannot enter the light emitting structure layer 103.

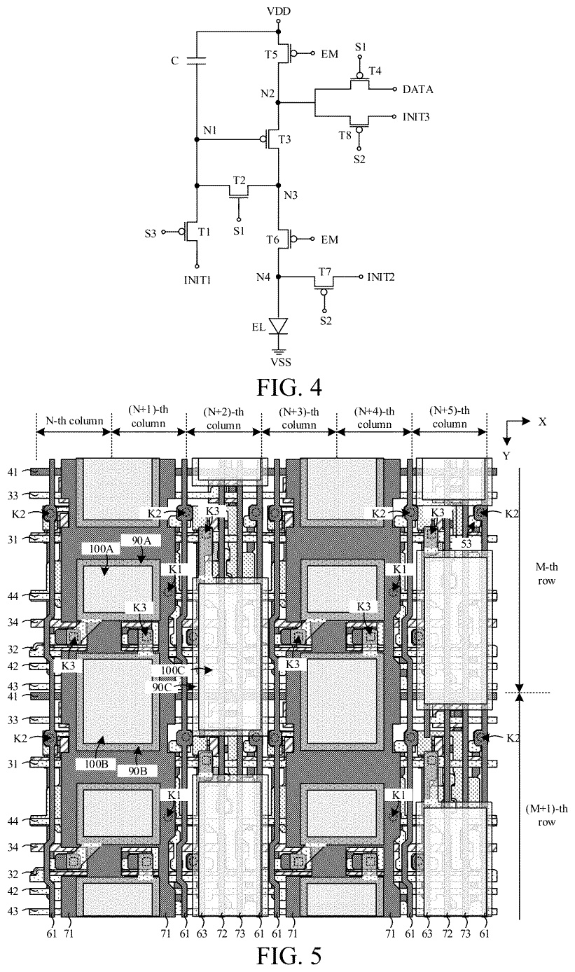

FIG. 4 is an equivalent circuit diagram of a pixel drive circuit. As shown in FIG. 4, the pixel drive circuit may include eight transistors (a first transistor T1 to an eighth transistor T8) and one storage capacitor C, and the pixel drive circuit is connected to 9 signal lines (a first scan signal line S1, a second scan signal line S2, a third scan signal line S3, a light emitting signal line EM, a first initial signal line INIT1, a second initial signal line INIT2, a third initial signal line INIT3, a data signal line DATA and a first power supply line VDD), respectively.

In an exemplary embodiment, the pixel drive circuit may include a first node N1, a second node N2, a third node N3, and a fourth node N4. Herein, the first node N1 is connected with a second electrode of the first transistor T1, a first electrode of the second transistor T2, a gate electrode of the third transistor T3, and a first terminal of the storage capacitor C, respectively, the second node N2 is connected with a first electrode of the third transistor T3, a second electrode of the fourth transistor T4, a second electrode of the fifth transistor T5, and a second electrode of the eighth transistor T8, respectively, the third node N3 is connected with a second electrode of the second transistor T2, a second electrode of the third transistor T3, and a first electrode of the sixth transistor T6, respectively, and the fourth node N4 is connected with a second electrode of the sixth transistor T6 and a second electrode of the seventh transistor T7, respectively.

In an exemplary embodiment, the first terminal of the storage capacitor C is connected with the first node N1, and a second terminal of the storage capacitor C is connected with the first power supply line VDD.

In an exemplary implementation, the first transistor T1 may be referred to as a first initialization transistor, a gate electrode of the first transistor T1 is connected with the third scan signal line S3, a first electrode of the first transistor T1 is connected with the first initial signal line INIT1, and the second electrode of the first transistor T1 is connected with the first node N1.

In an exemplary embodiment, the second transistor T2 may be referred to as a compensation transistor, a gate electrode of the second transistor T2 is connected with the first scan signal line S1, the first electrode of the second transistor T2 is connected with the first node N1, and the second electrode of the second transistor T2 is connected with the third node N3.

In an exemplary embodiment, the third transistor T3 may be referred to as a drive transistor. The gate electrode of the third transistor T3 is connected to the first node N1, the first electrode of the third transistor T3 is connected to the second node N2, and the second electrode of the third transistor T3 is connected to the third node N3.

In an exemplary embodiment, the fourth transistor T4 may be referred to as a data writing transistor, a gate electrode of the fourth transistor T4 is connected with the first scan signal line S1, a first electrode of the fourth transistor T4 is connected with the data signal line DATA, and the second electrode of the fourth transistor T4 is connected with the second node N2.

In an exemplary embodiment, the fifth transistor T5 may be referred to as a first light emitting control transistor, a gate electrode of the fifth transistor T5 is connected to the light emitting signal line EM, a first electrode of the fifth transistor T5 is connected to the first power supply line VDD, and the second electrode of the fifth transistor T5 is connected to the second node N2.

In an exemplary embodiment, the sixth transistor T6 may be referred to as a second light emitting control transistor, a gate electrode of the sixth transistor T6 is connected to the light emitting signal line EM, the first electrode of the sixth transistor T6 is connected to the third node N3, and a second electrode of the sixth transistor T6 is connected to the fourth node N4.

In an exemplary implementation, the seventh transistor T7 may be referred to as a second initialization transistor, a gate electrode of the seventh transistor T7 is connected with the second scan signal line S2, a first electrode of the seventh transistor T7 is connected with the second initial signal line INIT2, and the second electrode of the seventh transistor T7 is connected with the fourth node N4.

In an exemplary implementation, the eighth transistor T8 may be referred to as a third initialization transistor, a gate electrode of the eighth transistor T8 is connected with the second scan signal line S2, a first electrode of the eighth transistor T8 is connected with the third initial signal line INIT3, and the second electrode of the eighth transistor T8 is connected with the second node N2.

In an exemplary embodiment, a first electrode of a light emitting device EL is connected with the fourth node N4, and a second electrode of the light emitting device EL is connected with the second power supply line VSS. The light emitting device EL may be an OLED, including a first electrode (an anode), an organic light emitting layer, and a second electrode (an cathode) which are stacked, or may be a QLED including a first electrode (an anode), a quantum dot light emitting layer, and a second electrode (a cathode) which are stacked.

In an exemplary implementation, a signal of the first power supply line VDD is a high-level signal continuously provided, and a signal of the second power supply line VSS is a low-level signal continuously provided.

In an exemplary embodiment, the first transistor T1 to the eighth transistor T8 may be P-type transistors or N-type transistors. Use of a same type of transistors in a pixel drive circuit may simplify a process flow, reduce a process difficulty of a display panel, and improve a product yield. In some possible implementations, the first transistor T1 to the eighth transistor T8 may include P-type transistors and N-type transistors.

In an exemplary embodiment, the first transistor T1 to the eighth transistor T8 may employ a low temperature poly-silicon transistor, or may employ an oxide transistor, or may employ both of the low temperature poly-silicon transistor and the oxide transistor. An active layer of a low temperature polysilicon transistor is made of Low Temperature Poly-Silicon (LTPS), and an active layer of an oxide transistor is made of an oxide semiconductor (Oxide). The low temperature polysilicon transistor has advantages such as a high migration rate and fast charging, and the oxide transistor has advantages such as a low current leakage. The low temperature polysilicon transistor and the oxide transistor are integrated on one display substrate to form a Low Temperature Polycrystalline Oxide (LTPO) display substrate, such that advantages of the low temperature polysilicon transistor and the oxide transistor may be utilized, low-frequency drive can be achieved, power consumption can be reduced, and display quality can be improved.

The inventors of the present application have found that the main reason for problems such as color deviation in conventional display devices is the defect of flatness of the anode.

A display substrate is provided in an exemplary embodiment of the present disclosure. In an exemplary embodiment, on a plane perpendicular to the display substrate, the display substrate may include a drive structure layer disposed on a base substrate and a light emitting structure layer disposed on a side of the drive structure layer away from the base substrate; on a plane parallel to the display substrate, the drive structure layer includes a plurality of circuit units, at least one circuit unit includes a pixel drive circuit, a power supply connection line extending along a first direction, and a first power supply line extending along a second direction, the first direction and the second direction intersect, the pixel drive circuit includes at least a power supply connection electrode connected to the power supply connection line, the first power supply line is connected to the power supply connection line or the power supply connection electrode through a power supply via; the light emitting structure layer includes a plurality of light emitting units, at least one light emitting unit includes an anode and a pixel definition layer disposed on a side of the anode away from the base substrate, the anode is connected with a pixel drive circuit of a corresponding circuit unit, the pixel definition layer is provided with a pixel opening exposing the anode, and an orthographic projection of at least one pixel opening on the base substrate and an orthographic projection of the power supply via on the base substrate do not overlap.

In an exemplary embodiment, circuit units mentioned in the present disclosure refer to areas divided according to pixel drive circuits, and light emitting units mentioned in the present disclosure refer to areas divided according to light emitting devices. In an exemplary implementation, a position and a shape of an orthographic projection of a light emitting unit on the base substrate may correspond to a position and a shape of an orthographic projection of a circuit unit on the base substrate, or a position and a shape of an orthographic projection of a light emitting unit on the base substrate may not correspond to a position and a shape of an orthographic projection of a circuit unit on the base substrate.

In an exemplary embodiment, the plurality of light emitting units include at least a first light emitting unit emitting light of a first color, a second light emitting unit emitting light of a second color, and a third light emitting unit emitting light of a third color, the first light emitting unit includes at least a first anode and a first pixel opening exposing the first anode, the second light emitting unit includes at least a second anode and a second pixel opening that exposes the second anode, the third light emitting unit includes at least a third anode and a third pixel opening that exposes the third anode; the second anode is disposed at a side of the first anode in the second direction, and the third anode is disposed at a side of the first anode in the first direction; orthographic projections of the first pixel opening and the second pixel opening on the base substrate are at least partially overlapped with an orthographic projection of the first power supply line on the base substrate, and an orthographic projection of the third pixel opening on the base substrate is not overlapped with the orthographic projection of the first power supply line on the base substrate.

In an exemplary embodiment, the orthographic projections of the first pixel opening and the second pixel opening on the base substrate are within a range of the orthographic projection of the first power supply line on the base substrate.

In an exemplary embodiment, the at least one circuit unit further includes a data signal line, and in the at least one circuit unit and a circuit unit adjacent in the first direction, the data signal line in one circuit unit is disposed at a side of the first power supply line in an opposite direction of the first direction, and the data signal line in the other circuit unit is disposed at a side of the first power supply line in the first direction; the orthographic projections of the first pixel opening and the second pixel opening on the base substrate are not overlapped with an orthographic projection of the data signal line on the base substrate, and the orthographic projection of the third pixel opening on the base substrate is at least partially overlapped with the orthographic projection of the data signal line on the base substrate.

In an exemplary embodiment, the plurality of light emitting units include at least a first light emitting unit emitting light of a first color, a second light emitting unit emitting light of a second color, and a third light emitting unit emitting light of a third color, the first light emitting unit includes at least a first anode and a first pixel opening exposing the first anode, the second light emitting unit includes at least a second anode and a second pixel opening that exposes the second anode, the third light emitting unit includes at least a third anode and a third pixel opening that exposes the third anode; the second anode is disposed at a side of the first anode in the second direction, and the third anode is disposed at a side of the first anode in the first direction; the pixel drive circuit further includes a data connection electrode, and the at least one circuit unit further includes a data signal line connected to the data connection electrode through a data via; orthographic projections of the first pixel opening, the second pixel opening, and the third pixel opening on the base substrate are not overlapped with an orthographic projection of the data via on the base substrate.

In an exemplary embodiment, the plurality of circuit units include at least a first circuit unit, a second circuit unit and a third circuit unit disposed sequentially along the first direction, the first circuit unit includes at least a first pixel drive circuit and a first data signal line connected to the first pixel drive circuit through a first data via, the second circuit unit includes at least a second pixel drive circuit and a second data signal line connected to the second pixel drive circuit through a second data via, the third circuit unit includes at least a third pixel drive circuit and a third data signal line connected to the third pixel drive circuit through a third data via, orthographic projections of the first pixel opening and the second pixel opening on the base substrate are at least partially overlapped with an orthographic projection of the first data signal line on the base substrate, and an orthographic projection of the third pixel opening on the base substrate is not overlapped with orthographic projections of the first data signal line, the second data signal line, and the third data signal line on the base substrate.

In an exemplary embodiment, a pitch between the first data signal line and the second data signal line is smaller than a pitch between the second data signal line and the third data signal line, and a pitch between the first data via and the second data via is smaller than a pitch between the second data via and the third data via.

FIG. 5 is a schematic diagram of a planar structure of a display substrate according to an exemplary embodiment of the present disclosure. In an exemplary implementation mode, on a plane perpendicular to the display substrate, the display substrate may include a drive structure layer arranged on a base substrate and a light emitting structure layer arranged on a side of the drive structure layer away from the base substrate. On a plane parallel to the display substrate, the drive structure layer includes a plurality of circuit units, and the light emitting structure layer includes a plurality of light emitting units.

In an exemplary implementation, the plurality of circuit units may form a plurality of unit rows and a plurality of unit columns, the plurality of circuit units in each unit row are sequentially arranged along the first direction X, and the plurality of circuit units in each unit column are sequentially arranged along the second direction Y, forming a circuit unit array arranged in an array, and the first direction X intersects with the second direction Y.

In an exemplary embodiment, at least one circuit unit may include at least a pixel drive circuit, and the pixel drive circuit may include at least a storage capacitor and a plurality of transistors, and the pixel drive circuit is connected to the first scan signal line 31, the second scan signal line 32, the third scan signal line 33, the light emitting signal line 34, the first initial signal line 41, the second initial signal line 42, the third initial signal line 43, the data signal line 61, and the first power supply line 71, respectively. The first scan signal line 31, the second scan signal line 32, and the third scan signal line 33 are configured to provide a first scan signal, a second scan signal, and a third scan signal to the pixel drive circuit, respectively, the light emitting signal line 34 is configured to provide a light emitting control signal to the pixel drive circuit, the first initial signal line 41, the second initial signal line 42, and the third initial signal line 43 are configured to provide the pixel drive circuit with a first initial signal, a second initial signal, and a third initial signal, respectively, the data signal line 61 is configured to provide a data signal to the pixel drive circuit, and the first power supply line 71 is configured to provide a first power supply signal to the pixel drive circuit.

In an exemplary embodiment, the first scan signal line 31, the second scan signal line 32, the third scan signal line 33, the light emitting signal line 34, the first initial signal line 41, the second initial signal line 42, and the third initial signal line 43 may be in a shape of a straight line or a bend line with a main body portion extending in the first direction X, and the data signal line 61 and the first power supply line 71 may be in a shape of a straight line or a bend line with a main body portion extending along the second direction Y.

In the present disclosure, “A extends in a B direction” refers to that A may include a main portion and a secondary portion connected to the main portion, wherein the main portion is a line, a line segment, or a strip-shaped body, the main portion extends in the B direction, and a length of the main portion extending in the B direction is greater than a length of the secondary portion extending in another direction. In following description, “A extends in a B direction” means “a main body portion of A extends in the B direction”.

In an exemplary embodiment, in the second direction Y, the first scan signal line 31 may be located at a side of the storage capacitor in the opposite direction of the second direction Y, the third scan signal line 33 may be located at a side of the first scan signal line 31 away from the storage capacitor, and the first initial signal line 41 may be located at a side of the third scan signal line 33 away from the storage capacitor. The light emitting signal line 34 may be located at a side of the storage capacitor in the second direction Y, the second scan signal line 32 may be located at a side of the light emitting signal line 34 away from the storage capacitor, the second initial signal line 42 may be located at a side of the second scan signal line 32 away from the storage capacitor, and the third initial signal line 43 may be located at a side of the second initial signal line 42 away from the storage capacitor.

In an exemplary embodiment, the at least one circuit unit may further include a power supply connection line 44, the power supply connection line 44 may be in a shape of a straight line or a bend line with a main body portion extending along the first direction X, the power supply connection line 44 may be located between the first scan signal line 31 and the light emitting signal line 34, and an orthographic projection of the power supply connection line 44 on the base substrate is at least partially overlapped with an orthographic projection of the storage capacitor on the base substrate. In an exemplary embodiment, the first power supply line 71 may be connected to the power supply connection line 44 through the power supply via K1, so that the first power supply line 71 and the power supply connection line 44 form, on the display substrate, a mesh communication structure for transmitting the first power supply signal. In an exemplary embodiment, the power supply connection line 44 is connected to the second plate of the storage capacitor in the pixel drive circuit. In an exemplary embodiment, the pixel drive circuit further includes a power supply connection electrode, and the power supply connection electrode is connected to the power supply connection line 44.

In an exemplary embodiment, the first power supply line 71 may be provided in some circuit units. For example, the first power supply line 71 may be provided in the circuit units of the N-th unit column, the (N+₁)-th unit column, the (N+3)-th unit column, and the (N+4)-th unit column, and the first power supply line 71 may not be provided in the circuit units of the (N+2)-th unit column and the (N+5)-th unit column.

In an exemplary embodiment, in at least one circuit unit and a circuit unit adjacent in the first direction X, the first power supply lines 71 in the two circuit units are of an interconnected integral structure. For example, the first power supply line 71 of the N-th unit column and the first power supply line 71 of the (N+1)-th unit column may be of an interconnected integral structure, so that the first power supply lines 71 in the two unit columns are of an integral full-surface structure. As another example, the first power supply line 71 of the (N+3)-th unit column and the first power supply line 71 of the (N+4)-th unit column may be of an interconnected integral structure, so that the first power supply lines 71 in the two unit columns are of an integral full-surface structure.

In an exemplary embodiment, in the at least one circuit unit and a circuit unit adjacent in the first direction X, the data signal line 61 in one circuit unit may be provided at a side of the first power supply line 71 in the circuit unit in the opposite direction of the first direction X, and the data signal line 61 in the other circuit unit may be provided at a side of the first power supply line 71 in the circuit unit in the first direction X. For example, in the N-th unit column, the data signal line 61 may be located at a side of the first power supply line 71 in the opposite direction of the first direction X, and in the (N+1)-th unit column, the data signal line 61 may be located at a side of the first power supply line 71 in the first direction X. Because the first power supply lines 71 in the N-th unit column and the (N+1)-th unit column are of an interconnected integral structure, two data signal lines 61 in the two adjacent unit columns are respectively located at two sides of the first power supply line 71 of the integral structure. For another example, in the (N+3)-th unit column, the data signal line 61 may be located at a side of the first power supply line 71 in the opposite direction of the first direction X, and in the (N+4)-th unit column, the data signal line 61 may be located at a side of the first power supply line 71 in the first direction X. Because the first power supply lines 71 in the (N+3)-th unit column and the (N+4)-th unit column are of an interconnected integral structure, the two data signal lines 61 in the two adjacent unit columns are respectively located at two sides of the first power supply line 71 of the integral structure.

In an exemplary embodiment, in the at least one circuit unit and a circuit unit adjacent in the first direction X, the positions of the data signal lines 61 in the two circuit units may be symmetrical with respect to a column centerline, and the column centerline may be a straight line located between adjacent circuit units in the first direction X and extending along the second direction Y.

In an exemplary embodiment, the at least one pixel drive circuit may include at least a fourth transistor and a data connection electrode, the fourth transistor may include at least a fourth active layer, the data signal line 61 is connected to the data connection electrode through the data via K2, and the data connection electrode is connected to the first region of the fourth active layer.

In an exemplary embodiment, in the at least one circuit unit and a circuit unit adjacent in the first direction X, the data signal line 61 in one circuit unit is connected to the data connection electrode in the circuit unit in which the data signal line is located through the data via K2, and the data connection electrode is connected to the first region of the fourth active layer in the circuit unit in which the data connection electrode is located through a via; the data signal line 61 in the other circuit unit is connected to the data connection electrode in the circuit unit in which the data signal line is located via the data via K2, and the data connection electrode is connected to the first region of the fourth active layer in the circuit unit in which the data connection electrode is located via the data connection line. Herein, the data connection electrode is connected to the first end of the data connection line, and after the second end of the data connection line extends along the first direction X, it is connected to the first region of the fourth active layer through a via, so that the two data signal lines 61 in two adjacent circuit units are respectively located at two sides of the first power supply line 71.

In an exemplary embodiment, the at least one pixel drive circuit may further include a sixth transistor, a seventh transistor, a fourth node electrode, and an anode connection electrode, the sixth transistor may include at least a sixth active layer, the seventh transistor may include at least a seventh active layer, an anode in at least one light emitting unit is connected with the anode connection electrode through an anode via K3, the anode connection electrode is connected to the fourth node electrode, and the fourth node electrode is connected to the second region of the sixth active layer and the second region of the seventh active layer through a via.

In an exemplary embodiment, in the at least one circuit unit and a circuit unit adjacent in the first direction X, the anode connection electrode in one circuit unit is connected to the fourth node electrode in the circuit unit in which the anode connection electrode is located through a via, the fourth node electrode is connected to the second region of the sixth active layer and the second region of the seventh active layer through a via, the anode connection electrode in the other circuit unit is connected to the fourth node electrode in the circuit unit in which the anode connection electrode is located through an anode connection line 63, and the fourth node electrode is connected to the second region of the sixth active layer and the second region of the seventh active layer through a via. The anode connection line 63 may be in a shape of a straight line or a bend line extending along the second direction Y, the anode connection electrode is connected to the first end of the anode connection line 63, and the second end of the anode connection line 63 extends along the second direction Y, and then is connected to the fourth node electrode through a via. In an exemplary embodiment, the anode connection line 63 is configured to improve the flatness of the anode.

In an exemplary embodiment, at least one circuit unit may further include an initial connection line 73, and the initial connection line 73 may be in a shape of a straight line or a bend line extending along the second direction Y, and the initial connection line 73 is connected to the first initial signal line 41, the second initial signal line 42, and/or the third initial signal line 43, so that the initial connection line 73 and the initial signal line form a mesh communication structure for transmitting initial signals on the display substrate.

In an exemplary embodiment, the at least one circuit unit may further include a second power supply line 72, and the second power supply line 72 may be in a shape of a straight line or a bend line extending along the second direction Y, and the second power supply line 72 is configured to provide a second power supply signal to a cathode in the light emitting unit, achieving a structure of VSS in pixel.

In an exemplary embodiment, the plurality of light emitting units may include a first light emitting unit emitting light of a first color, a second light emitting unit emitting light of a second color, and a third light emitting unit emitting light of a third color, the first light emitting unit may include at least a first anode 90A and a first pixel opening 100A exposing the first anode 90A, the second light emitting unit may include at least a second anode 90B and a second pixel opening 100B exposing the second anode 90B, the third light emitting unit can include at least a third anode 90C and a third pixel opening 100C exposing the third anode 90C, the first anode 90A, the second anode 90B and the third anode 90C can be disposed in the anode conductive layer, and the first pixel opening 100A, the second pixel opening 100B, and the third pixel opening 100C can be disposed in the pixel definition layer.

In an exemplary embodiment, the second anode 90B may be disposed at a side of the first anode 90A in the second direction Y, and the third anode 90C may be disposed at a side of the first anode 90A and the second anode 90B in the first direction X, that is, the second pixel opening 100B is disposed at a side of the first pixel opening 100A in the second direction Y, and the third pixel opening 100C is disposed at a side of the first pixel opening 100A and the second pixel opening 100B in the first direction X.

In an exemplary embodiment, an orthographic projection of any one or more of the first pixel opening 100A, the second pixel opening 100B, and the third pixel opening 100C on the base substrate is not overlapped with an orthographic projection of the power supply via K1 on the base substrate.

In an exemplary embodiment, orthographic projections of the first pixel opening 100A and the second pixel opening 100B on the base substrate are at least partially overlapped with an orthographic projection of the first power supply line 71 on the base substrate, and an orthographic projection of the third pixel opening 100C on the base substrate is not overlapped with the orthographic projection of the first power supply line 71 on the base substrate.

In an exemplary embodiment, orthographic projections of the first pixel opening 100A and the second pixel opening 100B on the base substrate are not overlapped with an orthographic projection of the second power supply line 72 on the base substrate, and an orthographic projection of the third pixel opening 100C on the base substrate is at least partially overlapped with the orthographic projection of the second power supply line 72 on the base substrate.

In an exemplary embodiment, orthographic projections of the first pixel opening 100A and the second pixel opening 100B on the base substrate are not overlapped with an orthographic projection of the data signal line 61 on the base substrate, and the orthographic projection of the third pixel opening 100C on the base substrate is at least partially overlapped with the orthographic projection of the data signal line 61 on the base substrate.

In an exemplary embodiment, orthographic projections of the first pixel opening 100A and the second pixel opening 100B on the base substrate are not overlapped with an orthographic projection of the initial connection line 63 on the base substrate, and an orthographic projection of the third pixel opening 100C on the base substrate is at least partially overlapped with the orthographic projection of the initial connection line 63 on the base substrate.

In an exemplary embodiment, orthographic projections of the first pixel opening 100A and the second pixel opening 100B on the base substrate are within a range of an orthographic projection of the first power supply line 71 on the base substrate.

In an exemplary embodiment, the third pixel opening 100C may have an opening centerline, the opening centerline is a dummy line, and the opening centerline is a straight line extending along the second direction Y and passing through the geometric center of the third pixel opening 100C. In at least one third pixel opening 100C, the data signal line 61 and the anode connection line 63 may be symmetrically disposed with respect to the opening centerline, and the second power supply line 72 and the initial connection line 73 may be symmetrically disposed with respect to the opening centerline.

In an exemplary embodiment, an orthographic projection of any one or more of the first pixel opening 100A, the second pixel opening 100B, and the third pixel opening 100C on the base substrate is not overlapped with an orthographic projection of the data via K2 on the base substrate, and is not overlapped with an orthographic projection of the anode via K3 on the base substrate.

In an exemplary embodiment, in the second direction Y, the first pixel opening 100A, the second pixel opening 100B, and the third pixel opening 100C may be provided in a region of the corresponding circuit unit close to the next unit row.

In an exemplary embodiment, an orthographic projection of the first pixel opening 100A on the base substrate is at least partially overlapped with an orthographic projection of the power supply connection line 44 on the base substrate, and the orthographic projection of the first pixel opening 100A on the base substrate is not overlapped with an orthographic projection of the first initial signal line 41 on the base substrate.

In an exemplary embodiment, an orthographic projection of the second pixel opening 100B on the base substrate is at least partially overlapped with orthographic projections of the first initial signal line 41, the second initial signal line 42, and the third initial signal line 43 on the base substrate, and the orthographic projection of the second pixel opening 100B on the base substrate is not overlapped with orthographic projections of the first scan signal line 31 and the power supply connection line 44 on the base substrate.

In an exemplary embodiment, an orthographic projection of the third pixel opening 100C on the base substrate is at least partially overlapped with orthographic projections of the second scan signal line 32, the light emitting signal line 34, the second initial signal line 42, and the power supply connection line 44 on the base substrate, and the orthographic projection of the third pixel opening 100C on the base substrate is not overlapped with orthographic projections of the first scan signal line 31 and the third scan signal line 33 on the base substrate.

In an exemplary embodiment, on a plane perpendicular to the display substrate, the drive structure layer may include at least a shielding layer disposed on the base substrate, a first insulating layer disposed on a side of the shielding layer away from the base substrate, a semiconductor layer disposed on a side of the first insulating layer away from the base substrate, a second insulating layer disposed on a side of the semiconductor layer away from the base substrate, a first conductive layer disposed on a side of the second insulating layer away from the base substrate, a third insulating layer disposed on a side of the first conductive layer away from the base substrate, a second conductive layer disposed on a side of the third insulating layer away from the base substrate, a fourth insulating layer disposed on a side of the second conductive layer away from the base substrate, a third conductive layer disposed on a side of the fourth insulating layer away from the base substrate, a first planarization layer disposed on a side of the third conductive layer away from the base substrate, a fourth conductive layer disposed on a side of the first planarization layer away from the base substrate, and a second planarization layer disposed on a side of the fourth conductive layer away from the base substrate. The light emitting structure layer may include at least an anode conductive layer disposed on a side of the second planarization layer away from the base substrate, a pixel definition layer disposed on a side of the anode conductive layer away from the base substrate, an organic light emitting layer disposed on a side of the pixel definition layer away from the base substrate, and a cathode layer disposed on a side of the organic light emitting layer away from the base substrate.

In an exemplary embodiment, the shielding layer may include at least a shielding electrode, the semiconductor layer may include at least active layers of a plurality of transistors and a first initial signal line, the first conductive layer may include at least a second scan signal line, a light emitting signal line, and a first plate of a storage capacitor, the second conductive layer may include at least a blocking electrode and a second plate of the storage capacitor, the third conductive layer may include at least a first scan signal line, a third scan signal line, a second initial signal line, a third initial signal line, a power supply connection line, and a plurality of connection electrodes, and the fourth conductive layer may include at least a data signal line, a first power supply line, a second power supply line, and an initial connection line.

Exemplary description is made below through a manufacturing process for a display substrate. A “patterning process” mentioned in the present disclosure includes treatments such as deposition of a film, photoresist coating on a film, mask exposure, development, etching, and photoresist stripping for a metal material, an inorganic material, or a transparent conductive material, and includes treatments such as organic material coating, mask exposure, and development for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire preparation process, the “thin film” may also be called a “layer”. If the “thin film” need to be processed through the patterning process in the entire preparation process, the “thin film” is called a “thin film” before the patterning process is performed and is called a “layer” after the patterning process is performed. At least one “pattern” is contained in the “layer” which has been processed through the patterning process. “A and B are provided in a same layer” in the present disclosure means that A and B are formed simultaneously through a same patterning process, and a “thickness” of a film is a dimension of the film in a direction perpendicular to a display substrate. In an exemplary implementation of the present disclosure, “an orthographic projection of B is within a range of an orthographic projection of A” or “an orthographic projection of A contains an orthographic projection of B” refers to that a boundary of the orthographic projection of B falls within a range of a boundary of the orthographic projection of A, or the boundary of the orthographic projection of A coincides with the boundary of the orthographic projection of B.

In an exemplary embodiment, taking 12 circuit units (the M-th unit row and the (M+1)-th unit row, the N-th unit column to the (N+5)-th unit column) as an example, the preparation process of the display substrate of the present embodiment may include the following operations.

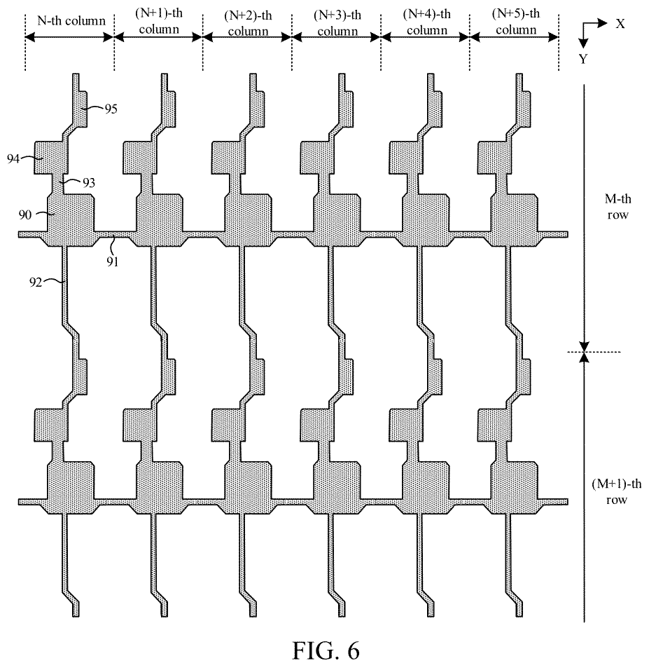

(11) A pattern of a shielding layer is formed. In an exemplary implementation, forming the pattern of the shielding layer may include: depositing a shielding thin film on a base substrate, patterning the shielding thin film through a patterning process to form the pattern of the shielding layer on the base substrate, as shown in FIG. 6. In an exemplary embodiment, the shielding layer may be referred to as an underlying metal (LS) layer.

In an exemplary embodiment, the pattern of the shielding layer of each circuit unit may include at least a shielding electrode 90, a first shielding connection strip 91, a second shielding connection strip 92, a third shielding connection strip 93, a first shielding block 94, and a second shielding block 95.

In an exemplary embodiment, the shielding electrode 90 may be in a shape of a rectangle, a chamfer or a groove may be provided at a corner of the rectangle, and the shielding electrode 90 may be provided in the middle region of the circuit unit in the first direction X and the second direction Y.

In an exemplary embodiment, the first shielding connection strip 91 may be in a shape of a straight line or a bend line with a main body portion extending along the first direction X, the first shielding connection strip 91 may be provided at a side of the shielding electrode 90 in the first direction X or at a side of the shielding electrode 90 in the opposite direction of the first direction X, the first end of the first shielding connection strip 91 is connected with the shielding electrode 90 of the present circuit unit, and the second end of the first shielding connection strip 91 is connected to the shielding electrode 90 of an adjacent circuit unit on the first direction X.

In an exemplary embodiment, in at least one unit row, the shielding electrode 90 and the first shielding connection strip 91 may be of an interconnected integral structure.

In an exemplary embodiment, the second shielding connection strip 92 may be in a shape of a straight line or a bend line with a main body portion extending along the second direction Y, the second shielding connection strip 92 may be provided at a side of the shielding electrode 90 in the second direction Y, the first end of the second shielding connection strip 92 is connected to the shielding electrode 90 of the present circuit unit, and the second end of the second shielding connection strip 92 is connected to the second shielding block 95 of an adjacent circuit unit in the second direction Y.

In an exemplary embodiment, the third shielding connection strip 93 may be in a shape of a straight line or a bend line with a main body portion extending along the second direction Y, the third shielding connection strip 93 may be provided on a side of the shielding electrode 90 in the opposite direction of the second direction Y, the first end of the third shielding connection strip 93 is connected to the shielding electrode 90, and the second end of the third shielding connection strip 93 is connected to the first shielding block 94.

In an exemplary embodiment, the first shielding block 94 may be in a shape of a block (such as a rectangle), and may be provided on a side of the shielding electrode 90 in the opposite direction of the second direction Y, the first end of the first shielding block 94 is connected to the third shielding connection strip 93, and the second end of the first shielding block 94 is connected to the second shielding block 95.

In an exemplary embodiment, the second shielding block 95 may be in a shape of a block (such as a rectangle), and may be provided on a side of the second shielding block 95 away from the shielding electrode 90, the first end of the second shielding block 95 is connected to the first shielding block 94, and the second end of the second shielding block 95 is connected to the second shielding connection strip 92 of an circuit unit adjacent in the opposite direction of the second direction Y.

In an exemplary embodiment, in at least one unit column, the second shielding block 95, the first shielding block 94, the third shielding connection strip 93, the shielding electrode 90, and the second shielding connection strip 92 are sequentially connected, and are of an interconnected integral structure.

In an exemplary embodiment, the shielding layers in a plurality of unit rows and a plurality of unit columns may be of an interconnected integral structure, which may ensure that the shielding layers in the display substrate have a same potential, which is beneficial to improving uniformity of a panel, avoiding display defect of the display substrate, and ensuring a display effect of the display substrate.

In an exemplary embodiment, the positions and shapes of the shielding layers in a plurality of unit rows may be substantially the same, and the positions and shapes of the shielding layers in a plurality of unit columns may be substantially the same.

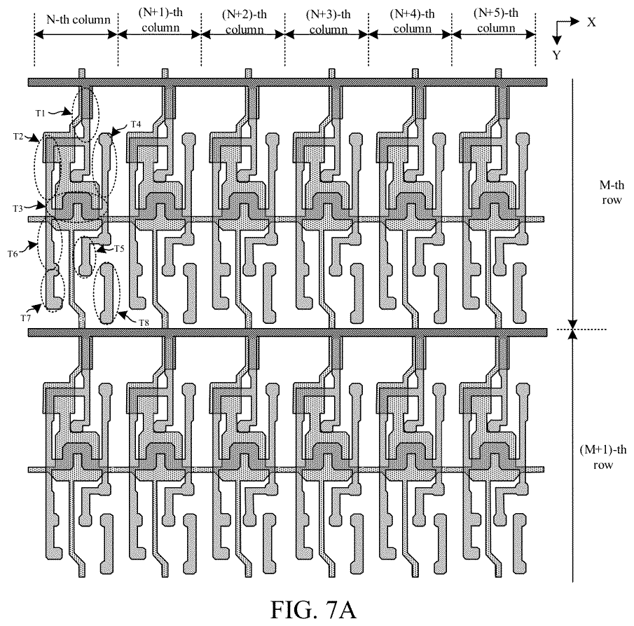

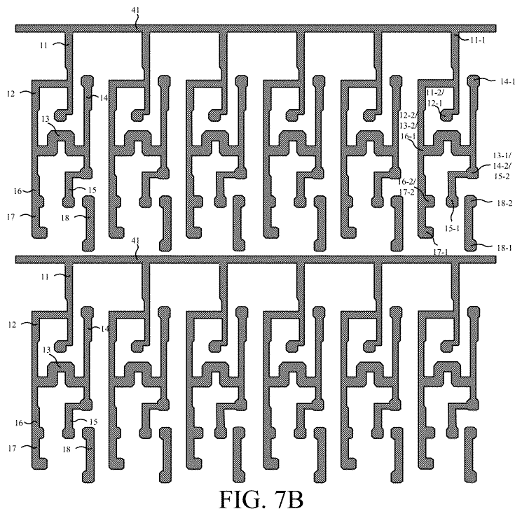

(12) A pattern of a semiconductor layer is formed. In an exemplary implementation, forming the pattern of the semiconductor layer may include: sequentially depositing a first insulating thin film and a semiconductor thin film on the base substrate on which the aforementioned pattern is formed, and patterning the semiconductor thin film through a patterning process to form a first insulating layer covering the shielding layer, and a pattern of a semiconductor layer arranged on the first insulating layer, as shown in FIG. 7A and FIG. 7B. FIG. 7B is a schematic plan view of the semiconductor layer in FIG. 7A.

In an exemplary embodiment, the pattern of the semiconductor layer of each circuit unit may include at least the first active layer 11 of the first transistor T1 to the eighth active layer 18 of the eighth transistor T8, and the first initial signal line 41, and the first active layer 11 to the seventh active layer 17 and the first initial signal line 41 are of an interconnected integral structure, and the eighth active layer 18 may be separately provided.

In an exemplary embodiment, in the first direction X, the second active layer 12, the sixth active layer 16, and the seventh active layer 17 may be located on a side of the third active layer 13 in the opposite direction of the first direction X, and the fourth active layer 14 and the eighth active layer 18 may be located on a side of the third active layer 13 in the first direction X. In the second direction Y, the first active layer 11, the second active layer 12, the fourth active layer 14, and the first initial signal line 41 may be located on a side of the third active layer 13 in the opposite direction of the second direction Y, and the fifth active layer 15, the sixth active layer 16, the seventh active layer 17, and the eighth active layer 18 may be located on a side of the third active layer 13 in the second direction Y.

In an exemplary embodiment, the third active layer 13 may be in an “Q” shape, the first active layer 11, the fourth active layer 14, the sixth active layer 16, the seventh active layer 17, and the eighth active layer 18 may be in an “I” shape, the second active layer 12 and the fifth active layer 15 may be in an “L” shape, and the first initial signal line 41 may be in a shape of a straight line or a bend line with a main body portion extending along the first direction X.

In an exemplary implementation, each of the first active layer 11 to the eighth active layer 18 may include a first region, a second region, and a channel region located between the first region and the second region. In an exemplary implementation, a second region 11-2 of the first active layer and a first region 12-1 of the second active layer may be connected to each other, so that the second region 11-2 of the first active layer may act as the first region 12-1 of the second active layer. The first region 13-1 of the third active layer, the second region 14-2 of the fourth active layer, and the second region 15-2 of the fifth active layer may be connected to each other, and the first region 13-1 of the third active layer may simultaneously serve as the second region 14-2 of the fourth active layer and the second region 15-2 of the fifth active layer. A second region 12-1 of the second active layer, a second region 13-2 of the third active layer, and a first region 16-1 of the sixth active layer may be connected with each other, and the second region 12-1 of the second active layer may simultaneously act as the second region 13-2 of the third active layer and the first region 16-1 of the sixth active layer. A second region 16-2 of the sixth active layer and a second region 17-2 of the seventh active layer may be connected with each other, and the second region 16-2 of the sixth active layer may act as the second region 17-2 of the seventh active layer. The first region 11-1 of the first active layer and the first initial signal line 41 may be connected to each other, and the first region 14-1 of the fourth active layer, the first region 15-1 of the fifth active layer, the first region 17-1 of the seventh active layer, the first region 18-1 of the eighth active layer, and the second region 18-2 of the eighth active layer may be separately provided.

In an exemplary embodiment, the first initial signal line 41 may be in a shape of a bend line or a straight line with a main body portion extending along the first direction X, may be located on a side of the first active layer 11 away from the third active layer 13, and the first initial signal line 41 is connected to the first regions 11-1 of the first active layers of a plurality of circuit units in one unit row.

In an exemplary embodiment, the first initial signal line 41 and the first active layers of a plurality of circuit units in one unit row may be of an interconnected integral structure. Because the first region of the first active layer and the first initial signal line 41 are of an interconnected integral structure, not only can the reliable connection between the first initial signal line and the first electrode of the first transistor be improved, but also the quantity of vias can be reduced, and the occupied space of the pixel drive circuits can be reduced, which is beneficial to achieving high-resolution (PPI) display.

In an exemplary embodiment, in at least one circuit unit, a first initial connection block may be provided on the first initial signal line, and the first initial connection block is configured to be connected to the subsequently formed initial connection line such that the first initial signal line extending along the first direction and the initial connection line extending along the second direction form a mesh communication structure for transmitting the first initial signal, which is not limited in the present disclosure.

In an exemplary implementation, an orthographic projection of the third active layer 13 on the base substrate is at least partially overlapped with an orthographic projection of the shielding electrode 90 on the base substrate, and the shielding electrode 90 may act as a shielding layer of the third transistor T3 to shield the channel region of the third transistor T3, thereby ensuring the electrical performance of the third transistor T3.

In an exemplary embodiment, an orthographic projection of the channel region of the third active layer 13 on the base substrate is within a range of an orthographic projection of the shielding electrode 90 on the base substrate.

In an exemplary embodiment, an orthographic projection of the second active layer 12 on the base substrate is at least partially overlapped with an orthographic projection of the first shielding block 94 on the base substrate, and the first shielding block 94 may serve as a shielding layer of the second transistor T2, shielding the channel region of the second transistor T2, and ensuring the electrical performance of the second transistor T2.

In an exemplary embodiment, an orthographic projection of the channel region of the second active layer 12 on the base substrate is within a range of an orthographic projection of the first shielding block 94 on the base substrate.

In an exemplary embodiment, an orthographic projection of the first active layer 11 on the base substrate is at least partially overlapped with an orthographic projection of the second shielding block 95 on the base substrate, and the second shielding block 95 may serve as a shielding layer of the first transistor T1, shielding the channel region of the first transistor T1, and ensuring the electrical performance of the first transistor T1.

In an exemplary embodiment, an orthographic projection of the channel region of the first active layer 11 on the base substrate is within a range of an orthographic projection of the second shielding block 95 on the base substrate.

In an exemplary embodiment, the positions and shapes of the semiconductor layers in a plurality of unit rows may be substantially the same, and the positions and shapes of the semiconductor layers in a plurality of unit columns may be substantially the same.

In an exemplary implementation, the semiconductor layer may be made of poly Silicon (p-Si), i.e., the third transistor to the seventh transistor are LTPS transistors. In an exemplary implementation, patterning the semiconductor thin film through a patterning process may include: an amorphous silicon (a-si) thin film is formed on the first insulation thin film, the amorphous silicon thin film is dehydrogenated, and the dehydrogenated amorphous silicon thin film is crystallized to form a poly silicon thin film. Subsequently, the polysilicon thin film is patterned to form the pattern of the semiconductor layer.

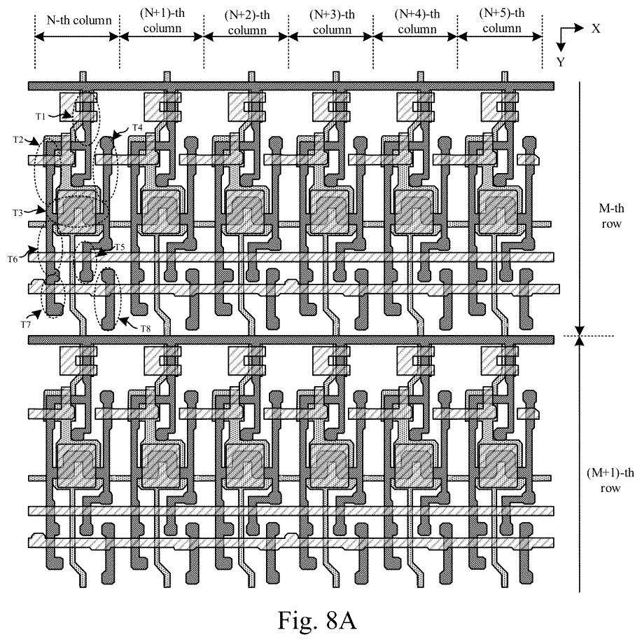

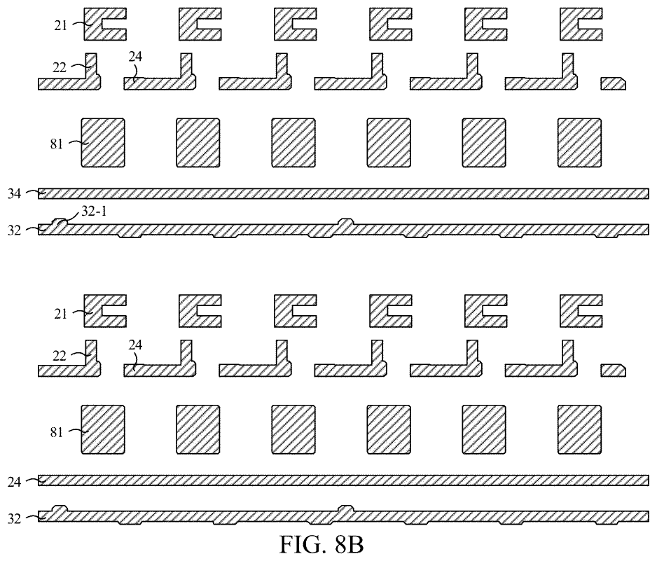

(13) A pattern of a first conductive layer is formed. In an exemplary implementation, forming the pattern of the first conductive layer may include: a second insulation thin film and a first conductive thin film are deposited sequentially on the base substrate on which the aforementioned patterns are formed, and the first conductive thin film is patterned through a patterning process to form a second insulating layer that covers the pattern of the semiconductor layer and form the pattern of the first conductive layer disposed on the second insulating layer, as shown in FIG. 8A and FIG. 8B, wherein FIG. 8B is a schematic plan view of the first conductive layer in FIG. 8A. In an exemplary implementation, the first conductive layer may be referred to as a first gate metal (GATE1) layer.

In an exemplary implementation, the pattern of the first conductive layer of each circuit unit at least includes a first gate electrode 21, a second gate electrode 22, a fourth gate electrode 24, a second scan signal line 32, a light emitting signal line 34, and a first plate 81 of the storage capacitor.

In an exemplary implementation, the first plate 81 may be in a shape of a rectangle, and a chamfer or a groove may be provided at a corner of the rectangle. An orthographic projection of the first plate 81 on the base substrate is overlapped, at least partially, with an orthographic projection of the third active layer of the third transistor T3 on the base substrate. In an exemplary implementation, the first plate 81 may serve as a plate of the storage capacitor and a gate electrode of the third transistor T3 simultaneously.

In an exemplary embodiment, an orthographic projection of the channel region of the third active layer on the base substrate is within a range of an orthographic projection of the first plate 81 on the base substrate.

In an exemplary implementation, an orthographic projection of the first plate 81 on the base substrate is at least partially overlapped with an orthographic projection of the shielding electrode 90 on the base substrate.

In an exemplary embodiment, the first gate electrode 21 may be in a “C” shape, may be located on a side of the first plate 81 in the opposite direction of the second direction Y, an orthographic projection of the first gate electrode 21 on the base substrate and an orthographic projection of the first active layer on the base substrate are at least partially overlapped, and a region where the first gate electrode 21 and the first active layer are overlapped may serve as the gate electrode of the first transistor T1 with a double-gate structure. In an exemplary embodiment, the first gate electrode 21 is configured to be connected to a third scan signal line formed subsequently.

In an exemplary embodiment, the second gate electrode 22 may be in an “L” shape, may be located between the first plate 81 and the first gate electrode 21, an orthographic projection of the second gate electrode 22 on the base substrate is at least partially overlapped with an orthographic projection of the second active layer on the base substrate, and a region where the second gate electrode 22 and the second active layer overlap may serve as a gate electrode of the second transistor T2 with a double-gate structure. In an exemplary embodiment, the second gate electrode 22 is configured to be connected to a subsequently formed first scan signal line.

In an exemplary embodiment, the fourth gate electrode 24 may be in a shape of a strip extending along the first direction X, may be located between the first plate 81 and the first gate electrode 21, an orthographic projection of the fourth gate electrode 24 on the base substrate is at least partially overlapped with an orthographic projection of the fourth active layer on the base substrate and a region where the fourth gate electrode 24 and the fourth active layer overlap may serve as a gate electrode of the fourth transistor T4. In an exemplary embodiment, the second gate electrode 22 is configured to be connected to a subsequently formed first scan signal line.

In an exemplary embodiment, the fourth gate electrode 24 in the present circuit unit and the second gate electrode 22 in a circuit unit adjacent in the first direction X may be of an interconnected integral structure. For example, in one unit row, the fourth gate electrode 24 in the N-th unit column and the second gate electrode 22 in the (N+1)-th unit column may be of an interconnected integral structure.

In an exemplary implementation, the second scan signal line 32 may be in a shape of a straight line or a polyline with a main body portion extending along the first direction X, the second scan signal line 32 may be located on a side of the first plate 81 in the second direction Y, a region where the second scan signal line 32 is overlapped with the seventh active layer may serve as a gate electrode of the seventh transistor T7, and a region where the second scan signal line 32 is overlapped with the eighth active layer may serve as a gate electrode of the eighth transistor T8.

In an exemplary embodiment, a second scan connection block 32-1 may be provided on the second scan signal line 32. The second scan connection block 32-1 may be in a shape of a block (such as a rectangle), the first end of the second scan connection block 32-1 is connected to a side of the second scan signal line 32 close to the first plate 81, the second end of the second scan connection block 32-1 extends in the direction of the first plate 81, and the second scan connection block 32-1 is configured to be connected to the subsequently formed auxiliary scan signal line.

In an exemplary embodiment, the light emitting signal line 34 may be in a shape of a straight line or a bend line in which a main portion extends along the first direction X, the light emitting signal line 34 may be located between the first plate 81 and the second scan signal line 32, a region where the light emitting signal line 34 overlaps the fifth active layer may serve as the gate electrode of the fifth transistor T5, and a region where the light emitting signal line 34 overlaps the sixth active layer may serve as the gate electrode of the sixth transistor T6.

In an exemplary embodiment, the positions and shapes of the first conductive layers in a plurality of unit rows may be substantially the same, and the positions and shapes of the first conductive layers in a plurality of unit columns may be substantially the same.

In an exemplary implementation, after the pattern of the first conductive layer is formed, a conductive treatment may be performed on the semiconductor layer by using the first conductive layer as a shield. A region of the semiconductor layer, which is shielded by the first conductive layer, forms channel regions of the first transistor T1 to the eighth transistor T8, and a region of the semiconductor layer, which is not shielded by the first conductive layer, is made to be conductive, that is, the first initial signal line 41, first regions and second regions of the first transistor T1 to the eighth active layer T8 are all made to be conductive.

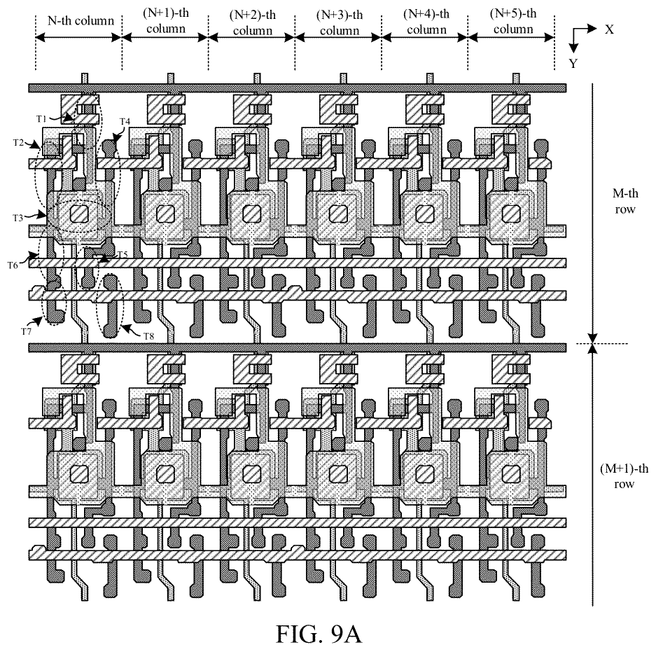

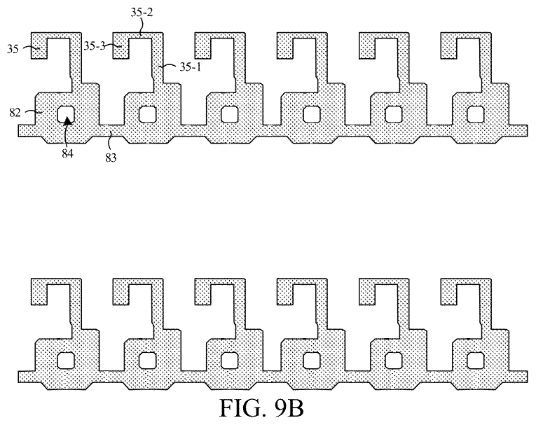

(14) A pattern of a second conductive layer is formed. In an exemplary embodiment, forming the pattern of the second conductive layer may include: depositing sequentially a third insulation thin film and a second conductive thin film on the base substrate on which the aforementioned patterns are formed, and the second conductive thin film is patterned through a patterning process to form a third insulating layer that covers the first conductive layer, and the pattern of the second conductive layer disposed on the third insulating layer, as shown in FIG. 9A and FIG. 9B. FIG. 9B is a schematic plan diagram of the second conductive layer in FIG. 9A. In an exemplary implementation, the second conductive layer may be referred to as a second gate metal (GATE2) layer.

In an exemplary implementation, the pattern of the second conductive layer of each circuit unit at least includes: a second plate 82 of the storage capacitor, and a blocking electrode 35.

In an exemplary implementation, a profile of the second plate 82 of the storage capacitor may be in a shape of a rectangle, a chamfer or a groove may be provided at a corner of the rectangle, an orthographic projection of the second plate 82 on the base substrate is at least partially overlapped with an orthographic projection of the first plate 81 on the base substrate, the second plate 82 may serve as anther plate of the storage capacitor, and the first plate 81 and the second plate 82 form the storage capacitor of the pixel drive circuit.

In an exemplary embodiment, the second plate 82 may be provided with a plate-level connection strip 83. The plate-level connection strip 83 may be in a shape of a straight line or a bend line extending along the first direction X, the plate-level connection strip 83 may be provided on a side of the second plate 82 in the first direction X or in an opposite direction of the first direction X. The first end of the plate-level connection strip 83 is connected to the second plate 82 in the present circuit unit, and the second end of the plate-level connection strip 83 is connected to the second plate 82 in an circuit unit adjacent in the first direction X. Because the second plate 82 in each circuit unit is connected to the subsequently formed first power supply line, by connecting the second plates 82 of adjacent circuit units to each other, the second plate 82 and the plate-level connection strip 83 can be reused as power supply signal lines, so that a plurality of second plates in a unit row may be ensured to be have a same potential, which is beneficial for improving uniformity of the display substrate, avoiding display defect of the display substrate and ensuring a display effect of the display substrate.

In an exemplary embodiment, the second plates 82 and the plate-level connection strips 83 in a plurality of circuit units in a unit row may be of an interconnected integral structure.

In an exemplary implementation, the second plate 82 is provided with an opening 84. The opening 84 may have a rectangular shape and may be located in a middle region of the second plate 82, so that the second plate 82 forms an annular structure. The opening 84 exposes the third insulating layer covering the first plate 81, and an orthographic projection of the first plate 81 on the base substrate contains an orthographic projection of the opening 84 on the base substrate. In an exemplary implementation, the opening 84 is configured to accommodate a ninth via formed subsequently, and the ninth via is located within the opening 84 and exposes the first plate 81, so that a first connection electrode formed subsequently is connected with the first plate 81.

In an exemplary embodiment, the blocking electrode 35 may be in an inverted “U” shape, may be located on a side of the second plate 82 close to the second transistor T2, and an orthographic projection of the blocking electrode 35 on the base substrate is at least partially overlapped with an orthographic projection of the second active layer between two gate electrodes (the node between the two gate electrodes) of the second transistor T2 on the base substrate. In an exemplary implementation, the blocking electrode 35 is configured to shield an influence of data voltage jump on the first transistor T1 and the second transistor T2, so as to avoid the data voltage jump affecting normal operation of the pixel drive circuit, and to improve the display effect.

In an exemplary implementation, the blocking electrode 35 may be provided in each circuit unit. The inverted “U”-shaped blocking electrode 35 may include a first extension segment 35-1, a second extension segment 35-2, and a third extension segment 35-3 connected sequentially. The first end of the first extension segment 35-1 is connected to the second plate 82, the second end of the first extension segment 35-1 is connected to the first end of the second extension segment 35-2 after extending in a direction away from the second plate 82 along the second direction Y, and an orthographic projection of the first extension segment 35-1 on the base substrate is at least partially overlapped with an orthographic projection of the first active layer on the base substrate. After the second end of the second extension segment 35-2 extends in a direction close to the second transistor T2 along the first direction X, it is connected to the first end of the third extension segment 35-3, and the second extension segment 35-2 is configured to be overlapped with the data connection line formed subsequently to avoid the data voltage jump affecting the first transistor T1. The second end of the third extension segment 35-3 extends along the second direction Y in a direction close to the second plate 82, an orthographic projection of the third extension segment 35-3 on the base substrate is at least partially overlapped with an orthographic projection of the semiconductor layer between the two gate electrodes of the second transistor T2 on the base substrate, the third extension segment 35-3 is configured to shield the effect of the data voltage jump on the second transistor T2.

In an exemplary embodiment, in at least one circuit unit, the blocking electrode 35 and the second plate 82 may be of an interconnected integral structure. Because the second plate 82 is connected to the first power supply line formed subsequently, the blocking electrode 35 has the potential of the first power supply line.

In an exemplary embodiment, the positions and shapes of the second conductive layers in a plurality of unit rows may be substantially the same, and the positions and shapes of the second conductive layers in a plurality of unit columns may be substantially the same.

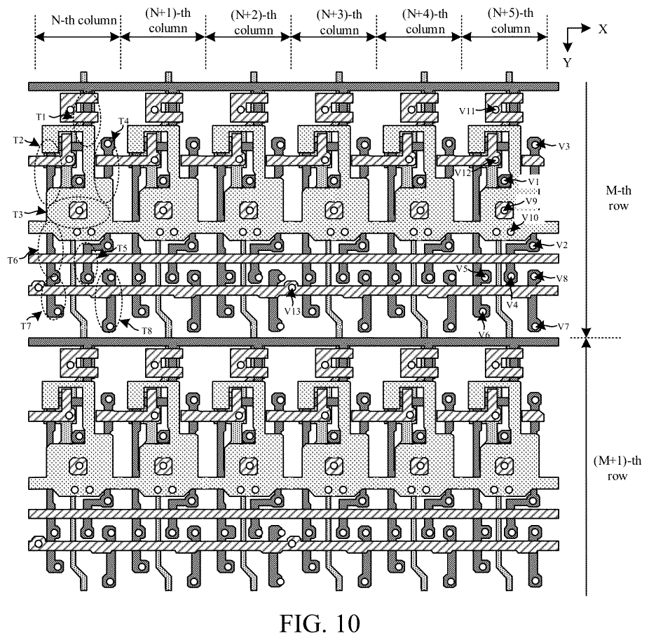

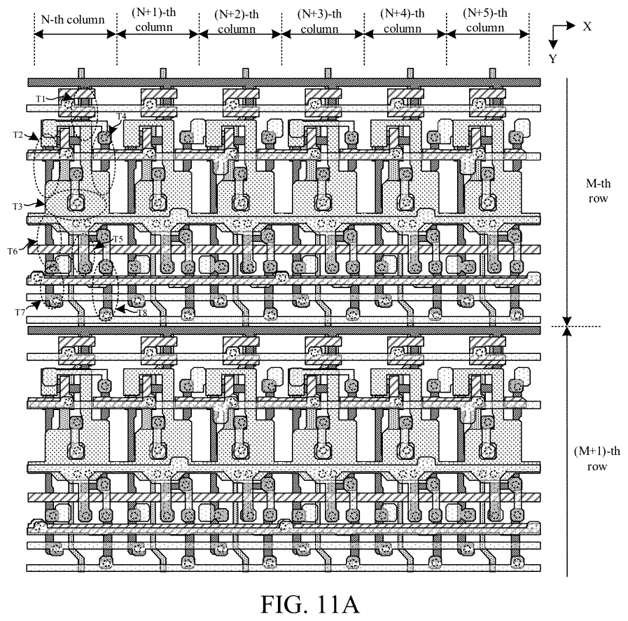

(15) A pattern of a fourth insulating layer is formed. In an exemplary implementation, forming the pattern of the fourth insulating layer may include: depositing a fourth insulation thin film on the base substrate on which the aforementioned patterns are formed, and patterning the fourth insulation thin film by a patterning process, to form a fourth insulating layer covering the second conductive layer, and a plurality of vias are provided on the fourth insulating layer, as shown in FIG. 10.

In an exemplary implementation, a plurality of vias of each circuit unit at least include: a first via V1, a second via V2, a third via V3, a fourth via V4, a fifth via V5, a sixth via V6, a seventh via V7, an eighth via V8, a ninth via V9, a tenth via V10, an eleventh via V11, and a twelfth via V12.

In an exemplary implementation, an orthographic projection of the first via V1 on the base substrate is within a range of an orthographic projection of the second region of the first active layer (that is, the first region of the second active layer) on the base substrate. A fourth insulating layer, a third insulating layer, and a second insulating layer within the first via V1 are etched away to expose a surface of the second region of the first active layer (that is, the first region of the second active layer), and the first via V1 is configured such that a first connection electrode formed subsequently is connected to the second region of the first active layer (that is, the first region of the second active layer) through this via.

In an exemplary embodiment, an orthographic projection of the second via V2 on the base substrate is within a range of an orthographic projection of the first region of the third active layer (also the second region of the fourth active layer and the second region of the fifth active layer) on the base substrate, the fourth insulating layer, the third insulating layer, and the second insulating layer within the second via V2 are etched away to expose the surface of the first region of the third active layer (also the second region of the fourth active layer and the second region of the fifth active layer), and the second via V2 is configured so that a subsequently formed second connection electrode is connected to the first region of the third active layer (also the second region of the fourth active layer and the second region of the fifth active layer) through the via.

In an exemplary embodiment, an orthographic projection of the third via V3 on the base substrate is within a range of an orthographic projection of the first region of the fourth active layer on the base substrate, the fourth insulating layer, the third insulating layer, and the second insulating layer within the third via V3 are etched away to expose the surface of the first region of the fourth active layer, and the third via V3 is configured such that a subsequently formed third connection electrode is connected with the first region of the fourth active layer through the via.

In an exemplary embodiment, an orthographic projection of the fourth via V4 on the base substrate is within a range of an orthographic projection of the first region of the fifth active layer on the base substrate, the fourth insulating layer, the third insulating layer, and the second insulating layer within the fourth via V4 are etched away to expose the surface of the first region of the fifth active layer, and the fourth via V4 is configured such that a subsequently formed fourth connection electrode is connected with the first region of the fifth active layer through the via.

In an exemplary implementation, an orthographic projection of the fifth via V5 on the base substrate is within a range of an orthographic projection of the second region of the sixth active layer (also the second region of the seventh active layer) on the base substrate. A fourth insulating layer, a third insulating layer, and a second insulating layer within the fifth via V5 are etched away to expose a surface of the second region of the sixth active layer (also the second region of the seventh active layer), and the fifth via V5 is configured such that a fifth connection electrode formed subsequently is connected to the second region of the sixth active layer (also the second region of the seventh active layer) through the via.

In an exemplary embodiment, an orthographic projection of the sixth via V6 on the base substrate is within a range of an orthographic projection of the first region of the seventh active layer on the base substrate, the fourth insulating layer, the third insulating layer, and the second insulating layer within the sixth via V6 are etched away to expose the surface of the first region of the seventh active layer, and the sixth via V6 is configured such that a subsequently formed second initial signal line is connected with the first region of the seventh active layer through the via.

In an exemplary embodiment, an orthographic projection of the seventh via V7 on the base substrate is within a range of an orthographic projection of the first region of the eighth active layer on the base substrate, the fourth insulating layer, the third insulating layer and the second insulating layer within the seventh via V7 are etched away to expose the surface of the first region of the eighth active layer, the seventh via V7 is configured such that a subsequently formed third initial signal line is connected with the first region of the eighth active layer through the via.

In an exemplary embodiment, an orthographic projection of the eighth via V8 on the base substrate is within a range of an orthographic projection of the second region of the eighth active layer on the base substrate, the fourth insulating layer, the third insulating layer, and the second insulating layer within the eighth via V8 are etched away to expose the surface of the second region of the eighth active layer, and the eighth via V8 is configured such that a subsequently formed second connection electrode is connected with the second region of the eighth active layer through the via.

In an exemplary implementation, an orthographic projection of the ninth via V9 on the base substrate is located within a range of an orthographic projection of the opening 84 on the base substrate, the fourth insulating layer and the third insulating layer within the ninth via V9 are etched away to expose a surface of the first plate 81, and the ninth via V9 is configured such that the subsequently formed first connection electrode is connected to the first plate 81 through the via.

In an exemplary implementation, an orthographic projection of the tenth via V10 on the base substrate is located within a range of an orthographic projection of the second plate 82 on the base substrate, the fourth insulating layer within the tenth via V10 is etched away to expose a surface of the second plate 82, and the tenth via V10 is configured such that the subsequently formed power supply connection line is connected to the second plate 82 through the via. In an exemplary implementation, the tenth via V10 may be plural and a plurality of tenth vias V10 may be disposed sequentially along the first direction X to improve connection reliability.

In an exemplary embodiment, an orthographic projection of the eleventh via V11 on the base substrate is located within a range of an orthographic projection of the first gate electrode 21 on the base substrate, the fourth insulating layer and the third insulating layer in the eleventh via V11 are etched away to expose the surface of the first gate electrode 21, and the eleventh via V11 is configured such that a third scan signal line formed subsequently is connected with the first gate electrode 21 through the via.

In an exemplary embodiment, an orthographic projection of the twelfth via V12 on the base substrate is within a range of an orthographic projection of the second gate electrode 22 (also the fourth gate electrode 24) on the base substrate, the fourth insulating layer and the third insulating layer within the twelfth via V12 are etched away to expose the surface of the second gate electrode 22 (also the fourth gate electrode 24), and the twelfth via V12 is configured such that a subsequently formed first scan signal line is connected with the second gate electrode 22 (also the fourth gate electrode 24) through the via.

In an exemplary embodiment, the fourth insulating layer of at least one circuit unit may further include a thirteenth via V13.

In an exemplary embodiment, an orthographic projection of the thirteenth via V13 on the base substrate is within a range of an orthographic projection of the second scan connection block 32-1 of the second scan signal line 32 on the base substrate, the fourth insulating layer and the third insulating layer in the thirteenth via V13 are etched away to expose the surface of the second scan connection block 32-1, and the thirteenth via V13 is configured such that a subsequently formed auxiliary scan signal line is connected with the second scan connection block 32-1 through the via.

In an exemplary embodiment, the positions and shapes of a plurality of vias in a plurality of unit rows may be substantially the same, and the positions and shapes of a plurality of vias in a plurality of unit columns may be substantially the same.

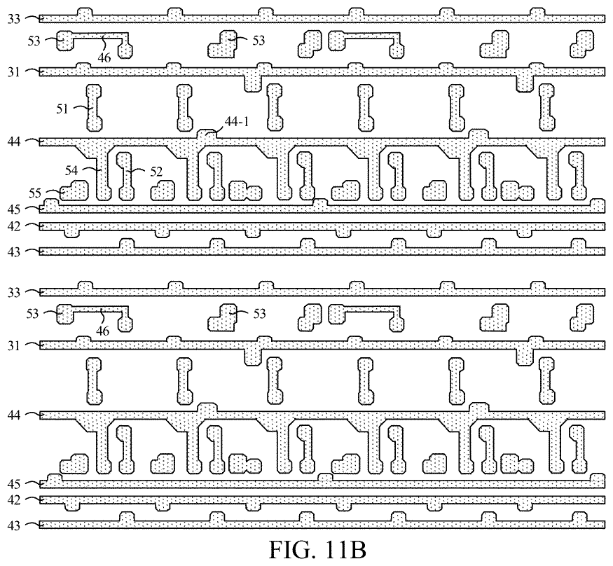

(16) A pattern of a third conductive layer is formed. In an exemplary implementation, forming the third conductive layer may include: depositing a third conductive thin film on the base substrate on which the aforementioned patterns are formed, and patterning the third conductive thin film through a patterning process to form a third conductive layer disposed on the fourth insulating layer, as shown in FIG. 11A and FIG. 11B, herein FIG. 11B is a planar schematic diagram of the third conductive layer in FIG. 11A. In an exemplary implementation, the third conductive layer may be referred to as a first source-drain metal (SD1) layer.

In an exemplary embodiment, the third conductive layer of each circuit unit includes at least a first scan signal line 31, a third scan signal line 33, a second initial signal line 42, a third initial signal line 43, a power supply connection line 44, an auxiliary scan signal line 45, a first connection electrode 51, a second connection electrode 52, a third connection electrode 53, a fourth connection electrode 54, and a fifth connection electrode 55.

In an exemplary embodiment, the first scan signal line 31 may be in a shape of a straight line or a bend line with a main body portion extending along the first direction X, the first scan signal line 31 may be located on a side of the second plate 82 in the opposite direction of the second direction Y, and the first scan signal line 31 is connected to the second gate electrode 22 (also the fourth gate electrode 24) in each circuit unit through the twelfth via V12 in each circuit unit, it is achieved that the first scan signal line 31 writes the first scan signal to the gate electrode of the second transistor T2 and the gate electrode of the fourth transistor T4, respectively.

In an exemplary embodiment, the third scan signal line 33 may be in a shape of a straight line or a bend line with a main body portion extending along the first direction X, the first scan signal line 33 may be located on a side of the first scan signal line 31 away from the second plate 82, and the third scan signal line 33 is connected to the first gate electrode 21 in each circuit unit through the eleventh via V11 in each circuit unit, it is achieved that the third scan signal line 33 writes the third scan signal to the gate electrode of the first transistor T1.

In an exemplary embodiment, the second initial signal line 42 be in a shape of a straight line or a bend line with a main body portion extending along the first direction X, the second initial signal line 42 may be located on a side of the second plate 82 in the second direction Y, and the second initial signal line 42 is connected to the first region of the seventh active layer in each circuit unit through the sixth via V6 in each circuit unit, it is achieved that the second initial signal line 42 writes the second initial signal to the first electrode of the seventh transistor T7.

In an exemplary embodiment, in at least one circuit unit, a second initial connection block may be provided on the second initial signal line, and the second initial connection block is configured to be connected to the subsequently formed initial connection line such that the second initial signal line extending along the first direction and the initial connection line extending along the second direction form a mesh communication structure for transmitting the second initial signal, which is not limited in the present disclosure.

In an exemplary embodiment, the third initial signal line 43 may be in a shape of a straight line or a bend line with a main body portion extending along the first direction X, the third initial signal line 43 may be located on a side of the second initial signal line 42 away from the second plate 82, and the third initial signal line 43 is connected to the first region of the eighth active layer in each circuit unit through the seventh via V7 in each circuit unit, it is achieved that the third initial signal line 43 writes the third initial signal to the first electrode of the eighth transistor T7.

In an exemplary embodiment, in at least one circuit unit, a third initial connection block may be provided on the third initial signal line, and the third initial connection block is configured to be connected to the subsequently formed initial connection line such that the third initial signal line extending along the first direction and the initial connection line extending along the second direction form a mesh communication structure for transmitting the third initial signal, which is not limited in the present disclosure.

In an exemplary embodiment, the power supply connection line 44 may be in a shape of a straight line or a bend line with a main body portion extending along the first direction X, the power supply connection line 44 may be located between the first scan signal line 31 and the light emitting signal line 34, an orthographic projection of the power supply connection line 44 on the base substrate is at least partially overlapped with an orthographic projection of the second plate 82 on the base substrate, and the power supply connection line 44 is connected to the second plate 82 in each circuit unit through the tenth via V10 in each circuit unit. Because the power supply connection line 44 is configured to be connected to the first power supply line formed subsequently, it is achieved that the first power supply line writes the first power supply signal to the second plate 82 of the storage capacitor.

In an exemplary embodiment, the power supply connection line 44 in some circuit units may be provided with a power supply connection block 44-1. The power supply connection block 44-1 may be in a shape of a block (such as a rectangle), a first end of the power supply connection block 44-1 is connected to a side of the power supply connection line 44 close to the first scan signal line 31, and a second end of the power supply connection block 44-1 extends in a direction close to the first scan signal line 31. In an exemplary implementation, the power supply connection block 44-1 is configured to be connected to a first power supply line formed subsequently.

In an exemplary implementation, the power supply connection block 44-1 may be provided in a plurality of circuit units of the (N+1)-th unit column and the (N+4)-th unit column.

In an exemplary embodiment, the power supply connection line 44 and the power supply connection block 44-1 may be of an interconnected integral structure.

In an exemplary embodiment, the auxiliary scan signal line 45 may be in a shape of a straight line or a bend line with a main body portion extending along the first direction X, an orthographic projection of the auxiliary scan signal line 45 on the base substrate and an orthographic projection of the second scan signal line 32 on the base substrate are at least partially overlapped, and the auxiliary scan signal line 45 is connected to the second scan connection block 32-1 through the thirteenth via V13. Because the second scan connection block 32-1 is connected to the second scan signal line 32, the second scan signal line 32 and the auxiliary scan signal line 45 form a scan signal line with a double-layer structure, which can effectively reduce the resistance of the scan signal line and can reduce the voltage drop of the scan signal.

In an exemplary embodiment, the first connection electrode 51 may be in a shape of a strip extending along the second direction Y, the first end of the first connection electrode 51 is connected to the second region of the first active layer (also the first region of the second active layer) through the first via V1, and the second end of the first connection electrode 51 is connected to the first plate 81 through the ninth via V9 after extending along the second direction Y. In an exemplary implementation mode, because the first plate 81 simultaneously serves as a gate electrode of the third transistor T3, the first connection electrode 51 enables the second electrode of the first transistor T1, the first electrode of the second transistor T2, the gate electrode of the third transistor T3, and the first plate 81 to have a same potential and form a first node N1 of the pixel drive circuit.

In an exemplary embodiment, the second connection electrode 52 may be in a shape of a strip extending along the second direction Y, the first end of the second connection electrode 52 is connected to the first region of the third active layer (also the second region of the fourth active layer and the second region of the fifth active layer) through the second via V2, and the second end of the second connection electrode 52 is connected to the second region of the eighth active layer through the eighth via V8 after extending along the second direction Y. In an exemplary embodiment, the second connection electrode 52 enables the first electrode of the third transistor T3, the second electrode of the fourth transistor T4, the second electrode of the fifth transistor T5, and the second electrode of the eighth transistor T8 to have a same potential, and form the second node N2 of the pixel drive circuit.

In an exemplary embodiment, the third connection electrode 53 in each circuit unit may be in a shape of a block (such as a rectangle), and the third connection electrode 53 is configured to be connected to a subsequently formed data signal line. In an exemplary embodiment, the third connection electrode 53 may be referred to as a data connection electrode.

In an exemplary embodiment, the third connection electrode 53 of a circuit unit in the (N+1)-th unit column, the (N+2)-th unit column, the (N+4)-th unit column, and the (N+5)-th unit column may be provided on a side of the first connection electrode 51 in the present circuit unit in the first direction X, and the third connection electrode 53 is connected to the first region of the fourth active layer through the third via V3.

In an exemplary embodiment, the positions and shapes of the third connection electrodes 53 in the (N+1)-th unit column, the (N+2)-th unit column, the (N+4)-th unit column, and the (N+5)-th unit column may be substantially the same.

In an exemplary embodiment, the third connection electrode 53 of a circuit unit in the N-th unit column and the N+3 unit column may be provided on a side of the first connection electrode 51 in the present circuit unit in the opposite direction of the first direction X, and the third connection electrode 53 is connected to the first region of the fourth active layer through the data connection line 46.

In an exemplary embodiment, the third conductive layer of a circuit unit in the N-th unit column and the (N+3)-th unit column may further include a data connection line 46, the data connection line 46 may be in a shape of a strip extending along the first direction X, the first end of the data connection line 46 is connected to the third connection electrode 53, and the second end of the data connection line 46 is connected to the first region of the fourth active layer through the third via V3 after extending along the first direction X.

In an exemplary embodiment, in at least one circuit unit, the third connection electrode 53 and the data connection line 46 may be of an interconnected integral structure.

In an exemplary embodiment, an orthographic projection of the data connection line 46 on the base substrate is at least partially overlapped with an orthographic projection of the second extension segment 35-2 of the blocking electrode 35 on the base substrate. Because the data connection line transmits data signals, the data voltage jump can be effectively prevented from affecting the first transistor T1 by providing a blocking electrode having the potential of the first power supply line below the data connection line.

In an exemplary embodiment, the positions and shapes of the third connection electrode 53 and the data connection lines 46 in the N-th unit column and the (N+3)-th unit column may be substantially the same.

In an exemplary embodiment, the fourth connection electrode 54 may be in a shape of a strip with a main body portion extending along the second direction Y, the first end of the fourth connection electrode 54 is connected to the power supply connection line 44, and the second end of the fourth connection electrode 54 is connected to the first region of the fifth active layer through the fourth via V4 after extending along the second direction Y. Because the power supply connection line 44 is configured to be connected to the first power supply line formed subsequently, it is achieved that the first power supply line writes the first power supply signal to the first electrode of the fifth transistor T5. In an exemplary embodiment, the fourth connection electrode 54 may be referred to as a power supply connection electrode.

In an exemplary embodiment, in at least one unit row, the power supply connection line 44 and a plurality of fourth connection electrodes 54 can be of an interconnected integral structure, which may ensure that the first electrode of the fifth transistor T5 and the second plate 82 of the storage capacitor in a plurality of circuit units in one unit row have the same potential, which is beneficial for improving uniformity of the display substrate, avoiding display defect of the display substrate and ensuring a display effect of the display substrate.

In an exemplary implementation, the fifth connection electrode 55 may be in a shape of a block (e.g., a rectangle), the fifth connection electrode 55 is connected with the second region of the sixth active layer (also the second region of the seventh active layer) through the fifth via V5, and the fifth connection electrode 55 is configured to be connected with an anode connection electrode formed subsequently. In an exemplary embodiment, the fifth connection electrode 55 may be referred to as a fourth node electrode.

In an exemplary embodiment, the shapes of the fifth connection electrodes 55 in the (N+1)-th unit column, the (N+2)-th unit column, the (N+4)-th unit column, and the (N+5)-th unit column may be substantially the same, and the shapes of the fifth connection electrodes 55 in the Nth unit column and the (N+3)-th unit column may be substantially the same, but the shapes of the fifth connection electrodes 55 in the Nth unit column and the (N+1)-th unit column may be different.

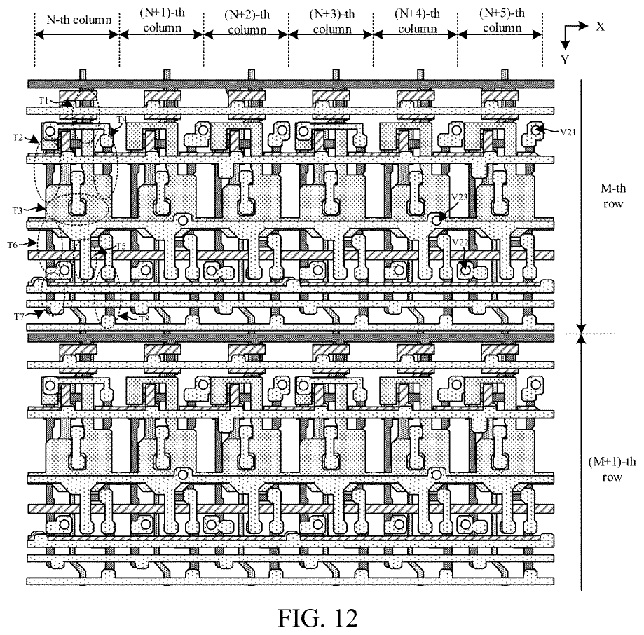

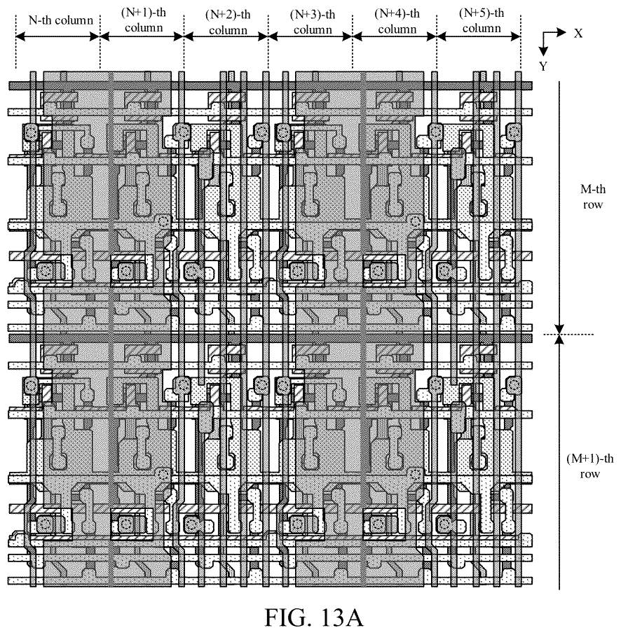

(17) A pattern of a first planarization layer is formed. In an exemplary implementation, forming a pattern of a first planarization layer may include coating a first planarization film on the base substrate on which the above-mentioned patterns are formed, patterning the first planarization film through a patterning process, forming a first planarization layer covering the third conductive layer, the first planarization layer is provided with a plurality of vias, as shown in FIG. 12.

In an exemplary embodiment, the plurality of vias of each circuit unit includes at least a twenty-first via V21 and a twenty-second via V22.

In an exemplary implementation, an orthographic projection of the twenty-first via V21 on the base substrate is located within a range of an orthographic projection of the third connection electrode 53 on the base substrate, the first planarization layer within the twenty-first via V21 is removed to expose a surface of the third connection electrode 53, and the twenty-first via V21 is configured such that a data signal line formed subsequently is connected with the third connection electrode 53 through the via. In an exemplary embodiment, the twenty-first via V21 may be referred to as a data via.

In an exemplary embodiment, the positions of data vias in some adjacent unit columns may be mirror-symmetric with respect to a column centerline, the column centerline may be a straight line located between the adjacent unit columns and extending along the second direction Y. For example, the position of the data via in the N-th unit column and the position of the data via in the (N+1)-th unit column may be mirror-symmetric with respect to the column centerline. As another example, the position of the data via in the (N+3)-th unit column and the position of the data via in the (N+4)-th unit column may be mirror-symmetrical with respect to the column centerline.

In an exemplary implementation, an orthographic projection of the twenty-second via V22 on the base substrate is located within a range of an orthographic projection of the fifth connection electrode 55 on the base substrate, the first planarization layer within the twenty-second via V22 is removed to expose a surface of the fifth connection electrode 55, and the twenty-second via V22 is configured such that the subsequently formed anode connection electrode is connected to the fifth connection electrode 55 through the via.

In an exemplary embodiment, a twenty-third via V23 may be further provided on the first planarization layer of some circuit units. An orthographic projection of the twenty-third via V23 on the base substrate is within a range of an orthographic projection of the power supply connection block 44-1 of the power supply connection line 44 on the base substrate, the first planarization layer in the twenty-third via V23 is removed to expose the surface of the power supply connection block 44-1, and the twenty-third via V23 is configured such that a subsequently formed first power supply line is connected with the power supply connection block 44-1 through the via. In an exemplary embodiment, the twenty-third via V23 may be referred to as a power supply via.

In an exemplary implementation, the twenty-third via V23 may be disposed in a plurality of circuit units of the (N+1)-th unit column and the (N+4)-th unit column.

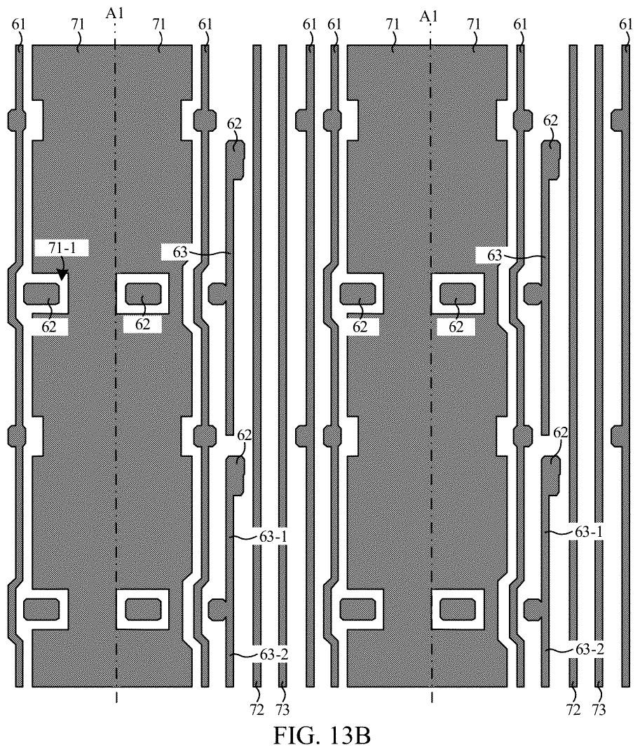

(18) A pattern of a fourth conductive layer is formed. In an exemplary implementation, forming the fourth conductive layer may include: depositing a fourth conductive thin film on the base substrate on which the aforementioned patterns are formed, and patterning the third conductive thin film through a patterning process to form a fourth conductive layer disposed on the first planarization layer, as shown in FIG. 13A and FIG. 13B, herein FIG. 13B is a planar schematic diagram of the fourth conductive layer in FIG. 13A. In an exemplary implementation, the fourth conductive layer may be referred to as a second source-drain metal (SD2) layer.

In an exemplary implementation, the fourth conductive layer of each circuit unit at least includes a data signal line 61 and an anode connection electrode 62.

In an exemplary embodiment, the data signal line 61 may be in a shape of a straight line or a bend line extending along the second direction Y, and the data signal line 61 is connected to the third connection electrode 53, which is served as a data connection electrode, through the twenty-first via V21. Because the third connection electrode 53 is connected to the first region of the fourth active layer, it is achieved that the data signal line 61 can write a data signal to the first electrode of the fourth transistor T4.

In an exemplary embodiment, the position of the data signal line 61 in different unit columns may be different. The data signal lines 61 in the N-th unit column and the (N+3)-th unit column may be located on a side of the first connection electrode 51 (the first power supply line 71) in the opposite direction of the first direction X, and the data signal lines 61 in the (N+1)-th unit column, the (N+2)-th unit column, the (N+4)-th unit column, and the (N+5)-th unit column may be located on a side of the first connection electrode 51 (the first power supply line 71) in the first direction X.

In an exemplary embodiment, the data signal line 61 may include a main body portion in a shape of a straight line extending along the second direction Y, and a connection portion connected to the main body portion, and the connection portion is connected to the third connection electrode 53 through the twenty-first via V21. The position of the main body portion of the data signal line 61 in some adjacent unit columns may be mirror-symmetrical with respect to the column centerline A1, the column centerline Almay be a straight line located between adjacent unit columns and extending along the second direction Y, and the column centerline A11 is a dummy line. For example, the position of the main body portion of the data signal line 61 in the N-th unit column and the position of the main body portion of the data signal line 61 in the (N+1)-th unit column may be mirror-symmetrical with respect to the column centerline A1. As another example, the position of the main body portion of the data signal line 61 in the (N+3)-th unit column and the position of the main body portion of the data signal line 61 in the (N+4)-th unit column may be mirror-symmetrical with respect to the column centerline A1.

In an exemplary embodiment, the anode connection electrode 62 in each circuit unit may be in a shape of a block (e.g., a rectangle), and the anode connection electrode 62 is configured to be connected with a subsequently formed anode.

In an exemplary embodiment, the anode connection electrode 62 of the circuit unit in the N-th unit column, the (N+1)-th unit column, the (N+3)-th unit column, and the (N+4)-th unit column may be disposed on a side of the power supply connection line 44 in the present circuit unit in the second direction Y, and the anode connection electrode 62 is connected to the fifth connection electrode 55 through the twenty-second via V22.

In an exemplary embodiment, the positions and shapes of the anode connection electrodes 62 in the N-th unit column, the (N+1)-th unit column, the (N+3)-th unit column, and the (N+4)-th unit column may be substantially the same.

In an exemplary embodiment, the anode connection electrode 62 of the circuit unit in the (N+2)-th unit column and the (N+5)-th unit column may be provided on a side of the power supply connection line 44 in the present circuit unit in the opposite direction of the second direction Y, and the anode connection electrode 62 is connected to the fifth connection electrode 55 served as the fourth node electrode through the anode connection line 63.

In an exemplary embodiment, the fourth conductive layer of the circuit unit in the (N+2)-th unit column and the (N+5)-th unit column may further include an anode connection line 63, and the anode connection line 63 may be in a shape of a strip extending along the second direction Y, and the first end of the anode connection line 63 is connected to the anode connection electrode 62, and the second end of the anode connection line 63 is connected to the fifth connection electrode 55 through the twenty-second via V22 after extending along the first direction X.

In an exemplary embodiment, the anode connection line 63 may include a first connection sub-line 63-1 and a second connection sub-line 63-2, the first end of the first connection sub-line 63-1 is connected to the anode connection electrode 62, the second end of the first connection sub-line 63-1 extends in a direction close to the fifth connection electrode 55 along the second direction Y, and then is connected to the fifth connection electrode 55 through the twenty-second via V22. The first end of the second connection sub-line 63-2 is connected to the second end of the first connection sub-line 63-1, and the second end of the second connection sub-line 63-2 extends in a direction close to the anode connection electrode 62 in the next unit row along the second direction Y.

In an exemplary embodiment, the anode connection line 63 is configured, on the one hand, to change the position of the anode via so that the anode connection electrode 62 is connected to the fifth connection electrode 55 through the anode connection line 63, and on the other hand, to improve the flatness of the anode.

In an exemplary embodiment, the positions and shapes of the anode connection electrodes 62 and the anode connection lines 63 in the (N+2)-th unit column and the (N+5)-th unit column may be substantially the same.

In an exemplary embodiment, in at least one circuit unit of the (N+2)-th unit column and the (N+5)-th unit column, the anode connection electrode 62 and the anode connection line 63 may be of an interconnected integral structure.

In an exemplary embodiment, the fourth conductive layer in some circuit units may further include the first power supply line 71. The first power supply line 71 may be in a shape of a straight line or a bend line extending along the second direction Y.

In an exemplary embodiment, the first power supply line 71 may be provided in the circuit units of the N-th unit column, the (N+1)-th unit column, the (N+3)-th unit column, and the (N+4)-th unit column, and the first power supply line 71 is not provided in the circuit units of the (N+2)-th unit column and the (N+5)-th unit column. A groove 71-1 may be provided on the first power supply line 71, the groove 71-1 may be in a shape of a block (such as a rectangle), the groove 71-1 may be provided on a side of the first power supply line 71 in the opposite direction of the first direction X, and the groove 71-1 is configured to accommodate the anode connection electrode 62 in present unit column.

In an exemplary embodiment, the first power supply lines 71 of the circuit units in the (N+1)-th unit column and the (N+4)-th unit column are connected to the power supply connection block 44-1 through the twenty-third via V23. Because the power supply connection block 44-1 is connected to the power supply connection line 44, it is achieved that the power supply connection line 44 with a main body portion extending in the first direction X and the first power supply line 71 with a main body portion extending in the second direction Y are connected to each other, so that the first power supply line 71 and the power supply connection line 44 form a mesh communication structure for transmitting the first power supply signal in the display substrate, which can not only effectively reduce a resistance of the first power supply line 71 and reduce a voltage drop of the first power supply signal, but also effectively improve uniformity of the first power supply signal in the display substrate, effectively improve display uniformity and improve display quality.

In an exemplary embodiment, the position of the first power supply lines 71 in adjacent unit columns may be mirror-symmetrical with respect to the column centerline A1. For example, the position of the first power supply line 71 in the N-th unit column and the position of the first power supply line 71 in the (N+1)-th unit column may be mirror-symmetrical with respect to the column centerline A1. As another example, the position of the first power supply line 71 in the (N+3)-th unit column and the position of the first power supply line 71 in the (N+4)-th unit column may be mirror-symmetrical with respect to the column centerline A1.

In an exemplary embodiment, the first power supply lines 71 of the N-th unit column and the (N+1)-th unit column may be of an interconnected integral structure, so that the first power supply lines 71 in the N-th unit column and the (N+1)-th unit column are of an integral full-surface structure. The first power supply lines 71 of the (N+3)-th unit column and the (N+4)-th unit column may be of an interconnected integral structure, so that the first power supply lines 71 in the (N+3)-th unit column and the (N+4)-th unit column are of an integral full-surface structure.

In an exemplary embodiment, in the N-th unit column, the (N+1)-th unit column, the (N+3)-th unit column, and the (N+4)-th unit column, an orthographic projection of the first power supply line 71 on the base substrate is at least partially overlapped with an orthographic projection of the first connection electrode 51 on the base substrate. Because the first connection electrode 51 serves as the first node N1 in the pixel drive circuit, the first power supply line 71 which is at a constant voltage can effectively shield an influence of other signals in the pixel drive circuit on the first node N1, thereby avoiding an influence of other signals (such as a data voltage jump) on a potential at the first node N1 in the pixel drive circuit, and improving display effect.

In an exemplary embodiment, an orthographic projection of the first power supply line 71 on the base substrate may include an orthographic projection of the first connection electrode 41 on the base substrate.

In an exemplary embodiment, the fourth conductive layer of some circuit units may further include a second power supply line 72, and the second power supply line 72 may be in a shape of a straight line or a bend line extending along the second direction Y.

In an exemplary embodiment, the second power supply line 72 may be provided in the (N+2)-th unit column and the (N+5)-th unit column, on the one hand, the symmetry of the signal lines below the anodes can be ensured, the flatness and symmetry of the anoded can be improved, and on the other hand, the structure of the VSS in pixel can be achieved, the width of the power supply lead in the bezel region can be greatly reduced, and the bezel width can be reduced, which is beneficial to the full-screen display.

In an exemplary embodiment, in the (N+2)-th unit column and the (N+5)-th unit column, an orthographic projection of the second power supply line 72 on the base substrate is at least partially overlapped with an orthographic projection of the first connection electrode 51 on the base substrate. Because the first connection electrode 51 serves as the first node N1 in the pixel drive circuit, the second power supply line 72 which is at a constant voltage can effectively shield an influence of other signals in the pixel drive circuit on the first node N1, thereby avoiding an influence of other signals (such as a data voltage jump) on a potential at the first node N1 in the pixel drive circuit, and improving display effect.

In an exemplary embodiment, the fourth conductive layer of some circuit units may further include an initial connection line 73, and the initial connection line 73 may be in a shape of a straight line or a bend line extending along the second direction Y.

In an exemplary embodiment, the initial connection line 73 may be provided in the (N+2)-th unit column and the (N+5)-th unit column, and may be provided on a side of the second power supply line 72 in the first direction X. On the one hand, the initial connection line 73 can ensure the symmetry of the signal lines below the anodes, improve the flatness and symmetry of the anodes, and on the other hand, it can form a mesh communication structure for transmitting the initial signal.

In an embodiment, in at least one unit column, the initial connection line may be connected to the first initial connection block on the first initial signal line through a via, so that the first initial signal line with a main body portion extending along the first direction X and the initial connection line with a main body portion extending along the second direction Y form a mesh communication structure for transmitting the first initial signal on the display substrate, which can not only effectively reduce the resistance of the first initial signal line, reduce the voltage drop of the first initial signal, but also effectively improve the uniformity of the first initial signal, effectively improve display uniformity, and improve the display quality.

In another embodiment, in at least one unit column, the initial connection line may be connected to the second initial connection block on the second initial signal line through a via, so that the second initial signal line with a main body portion extending along the first direction X and the initial connection line with a main body portion extending along the second direction Y form a mesh communication structure on the display substrate for transmitting the second initial signal, which can not only effectively reduce the resistance of the second initial signal line, reduce the voltage drop of the second initial signal, but also effectively improve the uniformity of the second initial signal, effectively improve display uniformity, and improve the display quality.

In yet another embodiment, in at least one unit column, the initial connection line may be connected to the third initial connection block on the third initial signal line through a via, so that the third initial signal line with a main body portion extending along the first direction X and the initial connection line with a main body portion extending along the second direction Y form a mesh communication structure on the display substrate for transmitting the third initial signal, which can not only effectively reduce the resistance of the third initial signal line, reduce the voltage drop of the third initial signal, but also effectively improve the uniformity of the third initial signal, effectively improve display uniformity, and improve the display quality.

In one possible embodiment, the initial connection line 73 in one unit column (e.g., the (N+2)-th unit column) may be connected to the first initial signal line 41, the initial connection line 73 in another unit column (e.g., the (N+5)-th unit column) may be connected to the second initial signal line 42, and the initial connection line 73 in yet another unit column (e.g., the (N+8)-th unit column) may be connected to the third initial signal line 43, respectively forming on the display substrate a first mesh communication structure for transmitting the first initial signal, a second mesh communication structure for transmitting the second initial signal, and a third mesh communication structure for transmitting the third initial signal.

In an exemplary embodiment, in at least one unit column, the positions of the second power supply line 72 and the initial connection line 73 may be interchanged, and the second power supply line 72 may be disposed on a side of the initial connection line 73 in the first direction X, which is not limited in the present disclosure.

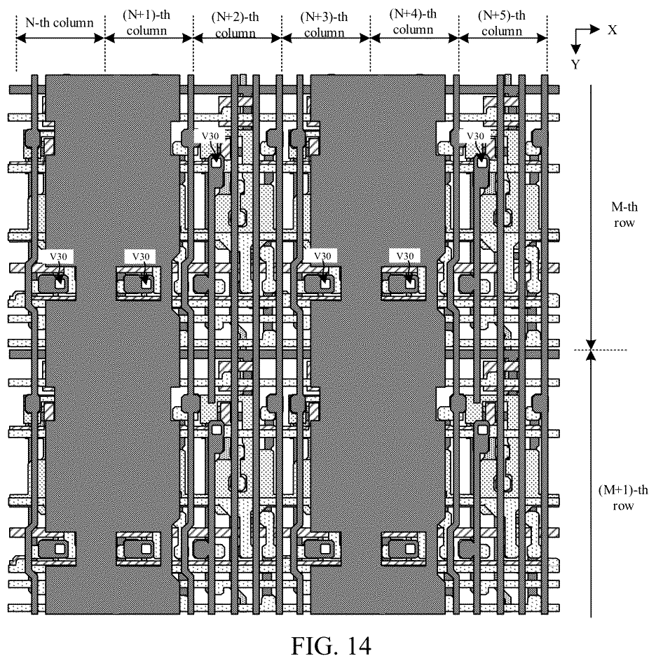

(19) A pattern of a second planarization layer is formed. In an exemplary implementation, forming the pattern of the second planarization layer may include: coating a second planarization thin film on the base substrate on which the aforementioned patterns are formed, patterning the first planarization thin film through a patterning process to form a second planarization layer covering the fourth conductive layer, herein the second planarization layer is provided with a plurality of vias, as shown in FIG. 14.

In an exemplary implementation, the plurality of vias of each circuit unit at least include an anode via V30. An orthographic projection of the anode via V30 on the base substrate is within a range of an orthographic projection of the anode connection electrode 62 on the base substrate, the second planarization layer within the anode via V30 is removed to expose a surface of the anode connection electrode 62, and the anode connection electrode is configured such that an anode formed subsequently is connected to the anode connection electrode 62 through the via.

So far, a drive structure layer has been prepared on the base substrate. In a plane parallel to the display substrate, the drive structure layer may include multiple circuit units, each of the circuit units may include a pixel drive circuit, and a first scan signal line, a second scan signal line, a third scan signal line, a light emitting signal line, a first initial signal line, a second initial signal line, a third initial signal line, a data signal line, and a first power supply line connected with the pixel drive circuit. In a plane perpendicular to the display substrate, the drive structure circuit layer may at least include a shielding layer, a first insulating layer, a semiconductor layer, a second insulating layer, a first conductive layer, a third insulating layer, a second conductive layer, a fourth insulating layer, a third conductive layer, a first planarization layer, a fourth conductive layer, and the second planarization layer which are disposed sequentially on the base substrate. The shielding layer may include at least a shielding electrode, the semiconductor layer may include at least a first initial signal line, active layers of the first transistor to the eighth transistor, the first conductive layer may include at least a second scan signal line, a light emitting signal line, and a first plate of the storage capacitor, the second conductive layer may include at least a blocking electrode and a second plate of the storage capacitor, the third conductive layer may include at least a first scan signal line, a third scan signal line, a second initial signal line, a third initial signal, and a plurality of connection electrodes, and the fourth conductive layer may include at least a data signal line and a first power supply line.

In an exemplary embodiment, the base substrate may be a flexible base substrate, or a rigid base substrate. The rigid base substrate may include, but is not limited to, one or more of glass and quartz. The flexible base substrate may be made of, but is not limited to, one or more of polyethylene terephthalate, ethylene terephthalate, polyether ether ketone, polystyrene, polycarbonate, polyarylate, polyarylester, polyimide, polyvinyl chloride, polyethylene, and textile fiber. In an exemplary embodiment, the flexible base substrate may include a first flexible material layer, a first inorganic material layer, a semiconductor layer, a second flexible material layer, and a second inorganic material layer which are stacked. Materials of the first flexible material layer and the second flexible material layer may be Polyimide (PI), Polyethylene Terephthalate (PET), or a surface-treated polymer soft film, etc., and materials of the first inorganic material layer and the second inorganic material layer may be Silicon Nitride (SiNx), Silicon Oxide (SiOx), or the like, for improving water and oxygen resistance of the base substrate. The first inorganic material layer and the second inorganic material layer may also be referred to as barrier layers, and a material of the semiconductor layer may be amorphous silicon (a-si).

In an exemplary implementation, the shielding layer, the first conductive layer, the second conductive layer, the third conductive layer, and the fourth conductive layer may be made of a metal material, such as any one or more of Argentum (Ag), Copper (Cu), Aluminum (Al), and Molybdenum (Mo), or an alloy material of the above-mentioned metals, such as an Aluminum-Neodymium alloy (AlNd) or a Molybdenum-Niobium alloy (MoNb), which may be in a single-layer structure, or a multilayer composite structure such as Mo/Cu/Mo. The first insulating layer, the second insulating layer, the third insulating layer, and the fourth insulating layer may be made of any one or more of Silicon Oxide (SiOx), Silicon Nitride (SiNx), and Silicon Oxynitride (SiON), and may be a single layer, a multi-layer, or a composite layer. The first planarization layer and the second planarization layer may be made of an organic material, such as resin.

In an exemplary implementation, after preparation of the drive structure layer is completed, a light emitting structure layer is prepared on the drive structure layer, and a preparation process of the light emitting structure layer may include following operations.

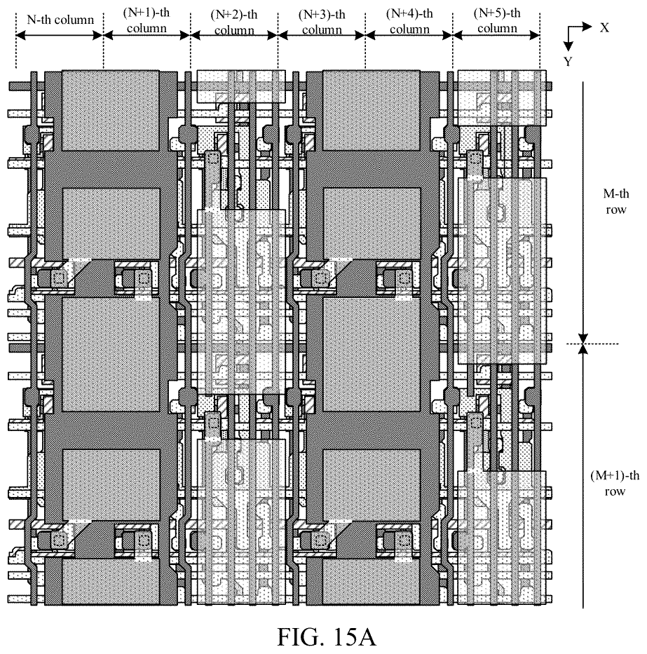

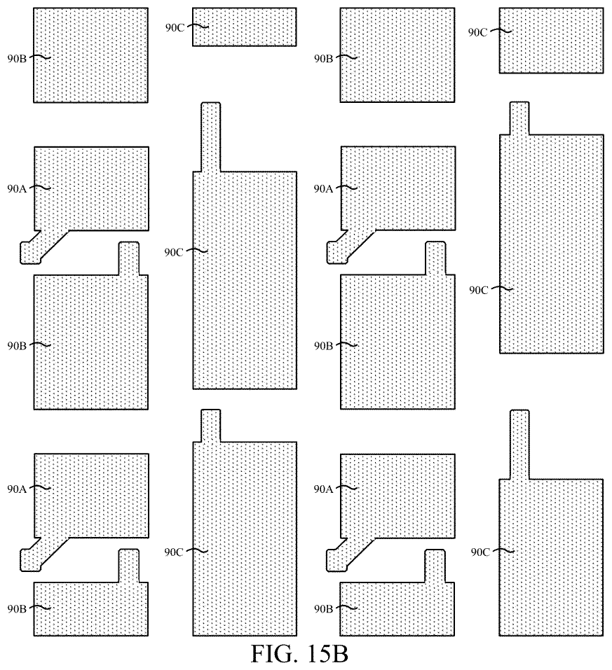

(20) A pattern of an anode conductive layer is formed. In an exemplary implementation mode, forming the pattern of the anode conductive layer may include: depositing an anode conductive thin film on the base substrate on which the aforementioned patterns are formed, and patterning the anode conductive thin film using a patterning process to form an anode conductive layer disposed on the second planarization layer, wherein the anode conductive layer at least includes patterns of a plurality of anodes, as shown in FIG. 15A and FIG. 15B, and FIG. 15B is a schematic plan view of the anode conductive layer in FIG. 15A.

In an exemplary embodiment, the plurality of anodes may include at least a first anode 90A located in the first light emitting unit, a second anode 90B located in the second light emitting unit, and a third anode 90C located in the third light emitting unit.

In an exemplary embodiment, the first light emitting unit may be a red light emitting unit emitting red light, the second light emitting unit may be a green light emitting unit emitting green light, and the third light emitting unit may be a blue light emitting unit emitting blue light.

In an exemplary embodiment, the second anode 90B may be disposed on a side of the first anode 90A in the second direction Y, and the third anode 90C may be disposed on a side of the first anode 90A and the second anode 90B in the first direction X.

In an exemplary embodiment, the first anode 90A, the second anode 90B, and the third anode 90C may be connected to the anode connection electrode 62 of the corresponding circuit unit through the anode via V30, respectively.

In an exemplary embodiment, at least one of the first anode 90A, the second anode 90B, and the third anode 90C may include an anode main body portion and an anode connection portion connected to each other, wherein the anode connection portion is connected to the anode main body portion on the one hand and connected to the anode connection electrode 62 through the anode via V30 on the other hand.

In an exemplary embodiment, the first anode 90A may include a first anode main body portion and a first anode connection portion connected to each other, the first anode main body portion may have a rectangular shape, a corner of the rectangle may be provided with an arc-shaped chamfer, the first anode connection portion may be in a shape of a strip extending in a direction away from the first anode main body portion, and the end portion of the first anode connection portion away from the first anode main body portion is connected to the anode connection electrode 62 through the anode via V30.

In an exemplary embodiment, an orthographic projection of the first anode body portion of the first anode 90A on the base substrate is at least partially overlapped with an orthographic projection of the first power supply line 71 on the base substrate, and the orthographic projection of the first anode body portion of the first anode 90A on the base substrate is not overlapped with orthographic projections of the data signal line 61, the anode connection line 63, the second power supply line 72, and the initial connection line 73 on the base substrate.

In an exemplary embodiment, an orthographic projection of the first anode body portion of the first anode 90A on the base substrate may be located within a range of an orthographic projection of the first power supply line 71 on the base substrate.

In an exemplary implementation, the second anode 90B may include a second anode main body portion and a second anode connection portion connected with each other, the second anode main body portion may have a rectangular shape, a circular arc-shaped chamfer may be provided at a corner of the rectangle, the second anode connection portion may be in a shape of a strip extending in a direction away from the second anode main body portion, and the end portion of the second anode connection portion away from the second anode main body portion is connected to the anode connection electrode 62 through the anode via V30.

In an exemplary embodiment, an orthographic projection of the second anode main body portion of the second anode 90B on the base substrate is at least partially overlapped with an orthographic projection of the first power supply line 71 on the base substrate, and the orthographic projection of the second anode body portion of the second anode 90B on the base substrate is not overlapped with orthographic projections of the data signal line 61, the anode connection line 63, the second power supply line 72, and the initial connection line 73 on the base substrate.

In an exemplary embodiment, an orthographic projection of the second anode main body portion of the second anode 90B on the base substrate may be located within a range of an orthographic projection of the first power supply line 71 on the base substrate.

In an exemplary implementation, the third anode 90C may include a third anode main body portion and a third anode connection portion connected with each other, the third anode main body portion may have a rectangular shape, a circular arc-shaped chamfer may be provided at a corner of the rectangle, the third anode connection portion may be in a shape of a strip extending in a direction away from the third anode main body portion, and the end portion of the third anode connection portion away from the third anode main body portion is connected to the anode connection electrode 62 through the anode via V30.

In an exemplary embodiment, an orthographic projection of the third anode main body portion of the third anode 90C on the base substrate is at least partially overlapped with orthographic projections of the data signal line 61, the anode connection line 63, the second power supply line 72, and the initial connection line 73 on the base substrate, and the orthographic projection of the third anode main body portion of the third anode 90C on the base substrate is not overlapped with an orthographic projection of the first power supply line 71 on the base substrate.

In an exemplary embodiment, orthographic projections of the first anode main body portion, the second anode main body portion, and the third anode main body portion on the base substrate are not overlapped with the orthographic projection of the power supply via on the base substrate and are not overlapped with the orthographic projection of the anode via on the base substrate.

In an exemplary implementation, the anode conductive layer may be of a single-layer structure, such as Indium Tin Oxide (ITO) or Indium Zinc Oxide (IZO), or may be of a multi-layer composite structure, such as ITO/Ag/ITO.

In an exemplary embodiment, in the second direction Y, the first anode 90A, the second anode 90B, and the third anode 90C may be disposed in a region of the corresponding circuit unit close to the next unit row.

In an exemplary embodiment, an orthographic projection of the first anode 90A on the base substrate is at least partially overlapped with an orthographic projection of the power supply connection line 44 on the base substrate, and the orthographic projection of the first anode 90A on the base substrate is not overlapped with an orthographic projection of the first initial signal line 41 on the base substrate.

In an exemplary embodiment, an orthographic projection of the second anode 90B on the base substrate is at least partially overlapped with orthographic projections of the first initial signal line 41, the second initial signal line 42, and the second initial signal line 43 on the base substrate, and the orthographic projection of the second anode 90B on the base substrate is not overlapped with orthographic projections of the first scan signal line 31 and the power supply connection line 44 on the base substrate.

In an exemplary embodiment, an orthographic projection of the third anode 90C on the base substrate is at least partially overlapped with orthographic projections of the power supply connection line 44, the light emitting signal line 34, the second scan signal line 32, and the second initial signal line 42 on the base substrate, and the orthographic projection of the third anode 90C on the base substrate is not overlapped with an orthographic projection of the first scan signal line 31 on the base substrate.

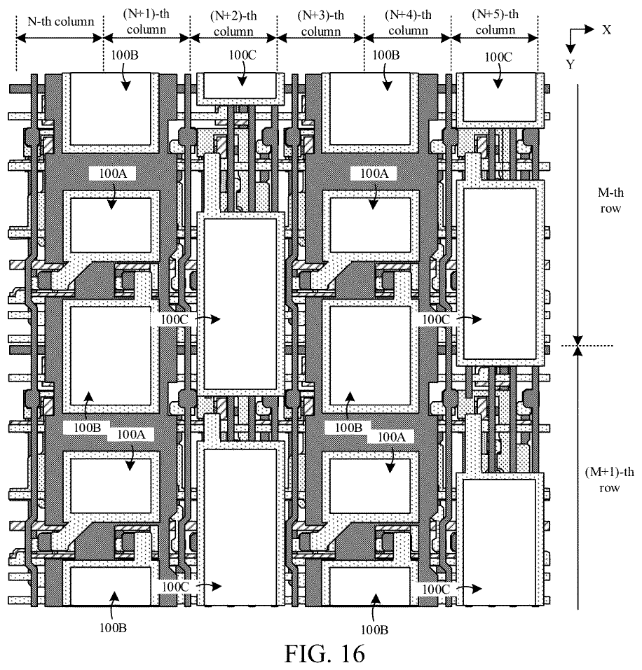

(21) A pattern of a pixel definition layer is formed. In an exemplary implementation, forming the pattern of the pixel definition layer may include: coating a pixel definition thin film on the base substrate on which the above-mentioned patterns are formed, patterning the pixel definition thin film using a patterning process, to form the pattern of the pixel definition layer covering the pattern of the anode conductive layer, and a plurality of pixel openings are provided on the pixel definition layer, as shown in FIG. 16.

In an exemplary embodiment, the plurality of pixel openings may include a first pixel opening 100A located in the red light emitting unit, a second pixel opening 100B located in the green light emitting unit, and a second pixel opening 100B located in the blue light emitting unit. An orthographic projection of the first pixel opening 100A on the base substrate is within a range of an orthographic projection of the first anode 90A on the base substrate, and the pixel definition thin film within the first pixel opening 100A is removed to expose the surface of the first anode 90A. An orthographic projection of the second pixel opening 100B on the base substrate is within a range of an orthographic projection of the second anode 90B on the base substrate, and the pixel definition thin film within the second pixel opening 100B is removed to expose the surface of the second anode 90B. An orthographic projection of the third pixel opening 100C on the base substrate is within a range of an orthographic projection of the third anode 90C on the base substrate, and the pixel definition thin film within the third pixel opening 100C is removed to expose the surface of the third anode 90C.

In an exemplary embodiment, the first pixel opening 100A may have a rectangular shape, a circular arc-shaped chamfer may be provided at a corner of the rectangle, an orthographic projection of the first pixel opening 100A on the base substrate is at least partially overlapped with an orthographic projection of the first power supply line 71 on the base substrate and an orthographic projection of the first pixel opening 100A on the base substrate is not overlapped with orthographic projections of the data signal line 61, the anode connection line 63, the second power supply line 72, and the initial connection line 73.

In an exemplary embodiment, an orthographic projection of the first pixel opening 100A on the base substrate and an orthographic projection of the power supply via on the base substrate do not overlap, that is, there is no power supply via in a range where the first pixel opening 100A is located.

In an exemplary embodiment, an orthographic projection of the first pixel opening 100A on the base substrate may be within a range of an orthographic projection of the first power supply line 71 on the base substrate.

In an exemplary embodiment, an orthographic projection of the first pixel opening 100A on the base substrate is not overlapped with orthographic projections of the data via and the anode via on the base substrate, that is, there are no data via and anode via in a range where the first pixel opening 100A is located.

In an exemplary embodiment, an orthographic projection of the second pixel opening 100B on the base substrate is at least partially overlapped with an orthographic projection of the first power supply line 71 on the base substrate, and the orthographic projection of the second pixel opening 100B on the base substrate is not overlapped with orthographic projections of the data signal line 61, the anode connection line 63, the second power supply line 72, and the initial connection line 73 on the base substrate.

In an exemplary embodiment, an orthographic projection of the second pixel opening 100B on the base substrate is not overlapped with an orthographic projection of the power supply via on the base substrate, that is, there is no power supply via in a range where the second pixel opening 100B is located.

In an exemplary embodiment, an orthographic projection of the second pixel opening 100B on the base substrate may be within a range of an orthographic projection of the first power supply line 71 on the base substrate.

In an exemplary embodiment, an orthographic projection of the second pixel opening 100B on the base substrate is not overlapped with orthographic projections of the data via and the anode via on the base substrate, that is, there are no data via and anode via in a range where the third pixel opening is located.

In an exemplary embodiment, an orthographic projection of the third pixel opening 100C on the base substrate is at least partially overlapped with orthographic projections of the data signal line 61, the anode connection line 63, the second power supply line 72, and the initial connection line 73 on the base substrate, and the orthographic projection of the third pixel opening 100C on the base substrate is not overlapped with an orthographic projection of the first power supply line 71 on the base substrate.

In an exemplary embodiment, an orthographic projection of the third pixel opening 100C on the base substrate is not overlapped with an orthographic projection of the power supply via on the base substrate, that is, there is no power supply via in a range where the third pixel opening 100C is located.

In an exemplary embodiment, an orthographic projection of the third pixel opening 100C on the base substrate is not overlapped with orthographic projections of the data via and the anode via on the base substrate, that is, there are no data via and anode via in a range where the third pixel opening 100C is located.

In an exemplary embodiment, the first pixel opening 100A and the second pixel opening 100B are overlapped with the first power supply line but are not overlapped with the second power supply line 72 and the initial connection line 73, and the third pixel opening 100C is overlapped with the second power supply line 72 and the initial connection line 73 but is not overlapped with the first power supply line, thus effectively ensuring the flatness and symmetry of the anode in the pixel opening.

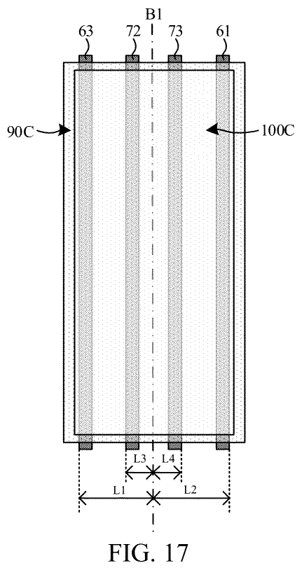

FIG. 17 is a schematic diagram of a positional relationship between a third pixel opening and signal lines according to an embodiment of the present disclosure. As shown in FIG. 17, in an exemplary embodiment, the third pixel opening 100C may have an opening centerline B1, which may be a straight line extending along the second direction Y and passing through the geometric center of the third pixel opening, and the opening centerline B1 is a dummy line.

In an exemplary embodiment, in at least one third pixel opening 100C, in the first direction X, the anode connection line 63 at least partially overlapped with the third pixel opening 100C has a first distance L1 from the opening centerline B1, and the data signal line 61 at least partially overlapped with the third pixel opening 100C has a second distance L2 from the opening centerline B1, and the ratio of the first distance L1 to the second distance L2 may be about 0.8 to 1.2.

In an exemplary implementation, a ratio of the first distance L1 to the second distance L2 may be about 0.9 to 1.1.

In an exemplary embodiment, the first distance L1 and the second distance L2 may be substantially the same, i.e., the anode connection line 63 and the data signal line 61 may be substantially mirror-symmetrical with respect to the opening centerline B1.

In an exemplary embodiment, both the first distance L1 and the second distance L2 are dimensions in the first direction X. The first distance L1 may be a distance between an edge of the anode connection line 63 on a side close to the opening centerline B1 and the opening centerline B1, or the first distance L1 may be a distance between an edge of the anode connection line 63 on a side away from the opening centerline B1 and the opening centerline B1. The second distance L2 may be a distance between an edge of the data signal line 61 on a side close to the opening centerline B1 and the opening centerline B1, or the second distance L2 may be a distance between an edge of the data signal line 61 on a side away from the opening centerline B1 and the opening centerline B1.

In an exemplary embodiment, in at least one third pixel opening 100C, in the first direction X, the second power supply line 72 at least partially overlapped with the third pixel opening 100C has a third distance L3 from the opening centerline B1, and the initial connection line 73 at least partially overlapped with the third pixel opening 100C has a fourth distance L4 from the opening centerline B1, and the ratio of the third distance L3 to the fourth distance L4 may be about 0.8 to 1.2.

In an exemplary implementation, a ratio of the third distance L3 to the fourth distance L4 may be about 0.9 to 1.1.

In an exemplary embodiment, the third distance L3 and the fourth distance L4 may be substantially the same, i.e., the second power supply line 72 and the initial connection line 73 may be substantially mirror-symmetrical with respect to the opening centerline B1.

In an exemplary embodiment, both the third distance L3 and the fourth distance L4 are dimensions in the first direction X. The third distance L3 may be a distance between an edge of the second power supply line 72 on a side close to the opening centerline B1 and the opening centerline B1, or the third distance L3 may be a distance between an edge of the second power supply line 72 on a side away from the opening centerline B1 and the opening centerline B1. The fourth distance L4 may be a distance between an edge of the initial connection line 73 on a side close to the opening centerline B1 and the opening centerline B1, or the fourth distance L4 may be a distance between an edge of the initial connection line 73 on a side away from the opening centerline B1 and the opening centerline B1.

In an exemplary embodiment, in the second direction Y, the anode connection line 63 at least partially overlapped with the third pixel opening 100C has a first extension length, the second power supply line 72 at least partially overlapped with the third pixel opening 100C has a second extension length, the initial connection line 73 at least partially overlapped with the third pixel opening 100C has a third extension length, and the data signal line 61 at least partially overlapped with the third pixel opening 100C has a fourth extension length, the first extension length, the second extension length, the third extension length, and the fourth extension length may be substantially the same.

In this disclosure, there is no power supply via, data via and anode via in a range where the pixel opening is located, orthographic projections of the first pixel opening and the third pixel opening on the substrate is within the range of the orthographic projection of the first power supply line 71 on the substrate, namely, a second source-drain metal layer of a full-surface is arranged below the first pixel openings and the second pixel openings, the third pixel opening is overlapped with the data signal line, the anode connection line, the second power supply line and the initial connection line, the data signal line and the anode connection line are symmetrical with respect to the third pixel opening, the second power supply line 72 and the initial connection line 73 are symmetrical with respect to the third pixel opening, so that the first anode, the second anode, and the third anode not only have good flatness, which can effectively avoid defects such as screen-off watermark (Mura) caused by anode flatness variation, but also have good symmetry, which can effectively improve color deviation and improve display quality.

In an exemplary embodiment, in the second direction Y, the first pixel opening 100A, the second pixel opening 100B, and the third pixel opening 100C may be provided in a region of the corresponding circuit unit close to the next unit row.

In an exemplary embodiment, an orthographic projection of at least one first pixel opening 100A on the base substrate is at least partially overlapped with an orthographic projection of the power supply connection line 44 on the base substrate, and the orthographic projection of the at least one first pixel opening 100A on the base substrate is not overlapped with an orthographic projection of the first initial signal line 41 on the base substrate.

In an exemplary embodiment, the orthographic projection of the at least one first pixel opening 100A on the base substrate is not overlapped with orthographic projections of the first scan signal line 31, the second scan signal line 32, the third scan signal line 33, the light emitting signal line 34, the second initial signal line 42, and the third initial signal line 43 on the base substrate.

In an exemplary embodiment, an orthographic projection of the at least one second pixel opening 100B on the base substrate is at least partially overlapped with orthographic projections of the first initial signal line 41, the second initial signal line 42, and the third initial signal line 43 on the base substrate, and the orthographic projection of the at least one second pixel opening 100B on the base substrate is not overlapped with orthographic projections of the first scan signal line 31 and the power supply connection line 44 on the base substrate.

In an exemplary embodiment, an orthographic projection of the at least one second pixel opening 100B on the base substrate is at least partially overlapped with an orthographic projection of the third scan signal line 33 on the base substrate, and the orthographic projection of the at least one second pixel opening 100B on the base substrate is not overlapped with an orthographic projection of the second scan signal line 32 and the light emitting signal line 34 on the base substrate.

In an exemplary embodiment, an orthographic projection of the at least one third pixel opening 100C on the base substrate is at least partially overlapped with orthographic projections of the second scan signal line 32, the light emitting signal line 34, the second initial signal line 42, and the power supply connection line 44 on the base substrate, and the orthographic projection of the at least one third pixel opening 100C on the base substrate is not overlapped with an orthographic projection of the first scan signal line 31 on the base substrate.

In an exemplary embodiment, an orthographic projection of the at least one third pixel opening 100C on the base substrate is at least partially overlapped with orthographic projections of the third scan signal line 33, the first initial signal line 41, and the third initial signal line 43 on the base substrate.

In an exemplary implementation, a subsequent preparation process may include: forming an organic light emitting layer using an evaporation process and inkjet printing process at first, then forming a cathode on the organic light emitting layer, and then forming an encapsulation structure layer, wherein the encapsulation structure layer may include a first encapsulation layer, a second encapsulation layer and a third encapsulation layer which are stacked, the first encapsulation layer and the third encapsulation layer may be made of an inorganic material, the second encapsulation layer may be made of an organic material, and the second encapsulation layer is disposed between the first encapsulation layer and the third encapsulation layer, which may ensure that external water vapor cannot enter the light emitting device.

In the display substrate provided by the exemplary embodiment of the present disclosure, by adjusting the arrangement of the data signal line and the first power supply line, there are no data vias and power supply vias in the range where the pixel opening is located, and the anode exposed by the pixel opening has good flatness, defects such as screen-off watermark (Mura) caused by flatness variation of the anode can be effectively avoided, color deviation can be effectively improved, and display quality is improved.

In the exemplary embodiment of the present disclosure, orthographic projections of the first pixel opening and the second pixel opening on the base substrate are within a range of an orthographic projection of the first power supply line 71 on the base substrate, that is, a second source-drain metal layer of a full-surface is arranged below the first pixel openings and the second pixel openings, the third pixel opening is overlapped with the data signal line, the anode connection line, the second power supply line and the initial connection line, and the data signal line and the anode connection line are symmetrical with respect to the third pixel opening, and the second power supply line 72 and the initial connection line 73 are symmetrical with respect to the third pixel opening, such that the anode exposed by the pixel opening has good symmetry, color deviation can be effectively improved, and display quality is improved.

In the present disclosure, the second power supply line is provided in the second source-drain metal layer, on the one hand, the symmetry of the signal lines below the anodes can be ensured, the flatness and symmetry of the anode can be improved, and on the other hand, the structure of the VSS in pixel can be achieved, the width of the power supply lead in the bezel region can be greatly reduced, and the bezel width can be reduced, which is beneficial to the achievement of full-screen display.

In the present disclosure, the initial connection line is provided in the second source-drain metal layer, on the one hand, the symmetry of the signal lines below the anodes can be ensured, and the flatness and symmetry of the anodes can be improved; on the other hand, the initial signal line and the initial connection line can form a mesh communication structure for transmitting the initial signal on the display substrate, which can not only effectively reduce the resistance of the initial signal line, reduce the voltage drop of the initial signal, but also effectively improve the uniformity of the initial signal, effectively improve display uniformity, and improve the display quality.

In the present disclosure, a power supply connection line extending along the first direction and a first power supply line extending along the second direction are provided, and the first power supply line is connected with the power supply connection line, such that the first power supply line and the power supply connection line form a mesh communication structure for transmitting the first power supply signal on the display substrate, which can not only effectively reduce the resistance of the first power supply signal line, reduce the voltage drop of the first power supply signal, but also effectively improve the uniformity of the first power supply signal, effectively improve the display uniformity, and improve display quality.

By providing the first initial signal line in the semiconductor layer, in the embodiment of the present disclosure, not only can the reliable connection between the first initial signal line and the first electrode of the first transistor be improved, but also the number of vias is reduced, the occupied space of the pixel drive circuits is reduced, and thereby facilitating the achievement of high resolution (PPI) display.

In the embodiment of the present disclosure, by providing the blocking electrode, an influence of a data voltage jump on the first transistor T1 and the second transistor T2 may be shielded, so as to avoid an influence of the data voltage jump on a normal operation of the pixel drive circuit and improve a display effect.

By providing the first power supply line to shield the first node N1 of the pixel drive circuit, in the embodiment of the present disclosure, another signal affecting potential of the first node N1 of the pixel drive circuit can be effectively avoided, and a display effect is improved.

The manufacturing process in the present disclosure may be compatible well with an existing manufacturing process, is simple in process implementation, is easy to implement, and has a high production efficiency, a low production cost, and a high yield.

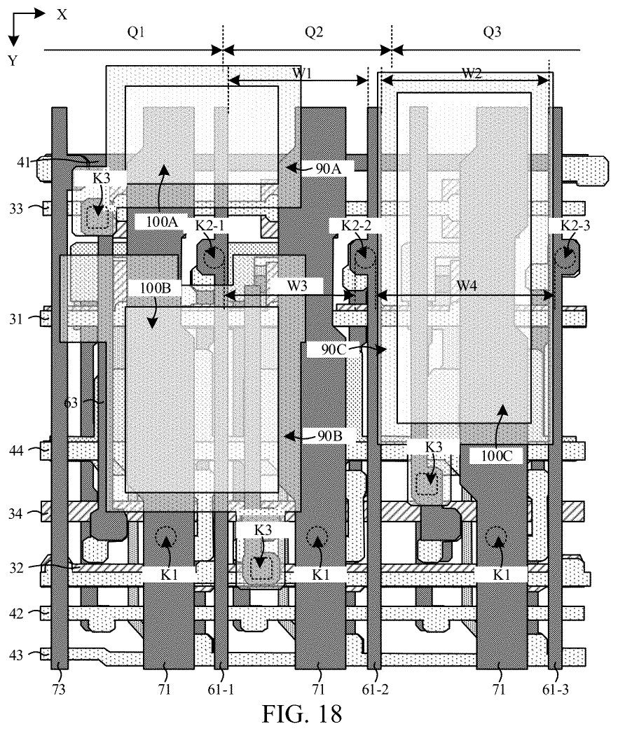

FIG. 18 is a schematic diagram of a planar structure of another display substrate according to an exemplary embodiment of the present disclosure. In an exemplary implementation, on a plane perpendicular to the display substrate, the display substrate may include a drive structure layer arranged on a base substrate and a light emitting structure layer arranged on a side of the drive structure layer away from the base substrate. On a plane parallel to the display substrate, the drive structure layer includes a plurality of circuit units, and the light emitting structure layer includes a plurality of light emitting units. FIG. 5 schematically illustrates a structure in which the drive structure layer includes three circuit units and the light emitting structure layer includes three light emitting units. The structure of the three circuit units (a first circuit unit Q1, a second circuit unit Q2, and a third circuit unit Q3) is illustrated.

In an exemplary embodiment, the structure of the pixel drive circuit in each circuit unit of the present embodiment is substantially the same as that shown in FIG. 5, the structures of the first scan signal line 31, the second scan signal line 32, the third scan signal line 33, the light emitting signal line 34, the first initial signal line 41, the second initial signal line 42, and the third initial signal line 43 are substantially the same as those shown in FIG. 5, the structures of the anode and the pixel opening in each light emitting unit are substantially the same as those shown in FIG. 5 and differ from those shown in FIG. 5 in the structures of the data signal line 61 and the first power supply line 71.

In an exemplary embodiment, the first power supply line 71 of the present embodiment is provided in each circuit unit, that is, the first circuit unit Q1, the second circuit unit Q2, and the third circuit unit Q3 are each provided with one first power supply line 71. The at least one pixel drive circuit may further include a power supply connection electrode, the at least one circuit unit may further include a power supply connection line 44, the power supply connection electrode is connected to the power supply connection line 44, and the first power supply line 71 may be connected to the power supply connection electrode in the circuit unit where the first power supply line is located through the power supply via K1 to achieve the connection between the first power supply line 71 and the power supply connection line 44.

In an exemplary embodiment, the at least one circuit unit may further include an anode connection line 63 and an initial connection line 73, and the structures of the anode connection line 63 and the initial connection line 73 are substantially the same as those shown in FIG. 5. In some possible embodiments, the at least one circuit unit may further include a second power supply line, which is not limited in the present disclosure.

In an exemplary embodiment, the positions of the data signal lines 61 in the first circuit unit Q1, the second circuit unit Q2, and the third circuit unit Q3 may be substantially the same, the data signal lines 61 may all be provided on a side of the first power supply line 71 in the first direction X, and the data signal line 61 is connected to the data connection electrode in the circuit unit where it is located through the data via K2.

In an exemplary embodiment, because the relative positions of the data signal line 61 and the first power supply line 71 in each circuit unit are substantially the same, in order to avoid the data via being located in the pixel opening, ensure the flatness of the anode, and improve the color deviation, this embodiment adopts a compression method to provide the pixel drive circuits. In some exemplary embodiments, the compression may be achieved by setting the position of the pixel drive circuit in the first direction X, or the compression may be achieved by setting the size of the pixel drive circuit in the first direction X, or the compression may be achieved by setting the structural layout of the pixel drive circuit.

In an exemplary embodiment, the present embodiment adjusts the pitch between adjacent pixel drive circuits in the first direction X by setting the position of the pixel drive circuit in the first direction X, thereby adjusting the relative position of the data via and the pixel opening, and preventing the data via from being located in the pixel opening. For example, the pixel drive circuit in the second circuit unit Q2 may be provided close to the pixel drive circuit in the first circuit unit Q1 and away from the pixel drive circuit in the third circuit unit Q3 so that the data vias in the second circuit unit Q2 and the third circuit unit Q3 can avoid the third pixel opening 100C of the third light emitting unit.

In an exemplary embodiment, the first circuit unit Q1, the second circuit unit Q2, and the third circuit unit Q3 can be sequentially arranged along the first direction X, the first circuit unit Q1, may include at least a first pixel drive circuit and a first data signal line 61-1 connected to the first pixel drive circuit through the first data via K2-1, the second circuit unit Q2 may include at least a second pixel drive circuit and a second data signal line 61-2 connected to the second pixel drive circuit through the second data via K2-2, and the third circuit unit Q3 may include at least a third pixel drive circuit and a third data signal line 61-3 connected to the third pixel drive circuit through the third data via K2-3. In an exemplary embodiment, the data signal line is connected to the pixel drive circuit through the data via means that the data signal line is connected to a data connection electrode in the pixel drive circuit through the data via, and the data connection electrode is connected to the first region of the fourth active layer through a via.

In an exemplary embodiment, a first pitch W1 may be provided between the first data signal line 61-1 and the second data signal line 61-2, a second pitch W2 may be provided between and the second data signal line 61-2 and the third data signal line 61-3, and the first pitch W1 is smaller than the second pitch W2.

In an exemplary embodiment, the first pitch W1 may be a distance between an edge of the first data signal line 61-1 on a side close to the second data signal line 61-2 and an edge of the second data signal line 61-2 on a side close to the first data signal line 61-1, or may be a distance between an edge of the first data signal line 61-1 on a side away from the second data signal line 61-2 and an edge of the second data signal line 61-2 on a side away from the first data signal line 61-1. The second pitch W2 may be a distance between an edge of the second data signal line 61-2 on a side close to the third data signal line 61-3 and an edge of the third data signal line 61-3 on a side close to the second data signal line 61-2, or a distance between an edge of the second data signal line 61-2 on a side away from the third data signal line 61-3 and an edge of the third data signal line 61-3 on a side away from the second data signal line 61-2.

In an exemplary embodiment, a third pitch W3 may be provided between the first data via K2-1 and the second data via K2-2, a fourth pitch W4 may be provided between the second data via K2-2 and the third data via K2-3, and the third pitch W3 is smaller than the fourth pitch W4.

In an exemplary embodiment, the third pitch W3 may be a distance between an edge of the first data via K2-1 on a side close to the second data via K2-2 and an edge of the second data via K2-2 on a side close to the first data via K2-1, or may be a distance between an edge of the first data via K2-1 on a side away from the second data via K2-2 and an edge of the second data via K2-2 on a side away from the first data via K2-1. The fourth pitch W4 may be a distance between an edge of the second data via K2-2 on a side close to the third data via K2-3 and an edge of the third data via K2-3 on a side close to the second data via K2-2, or a distance between an edge of the second data via K2-2 on a side away from the third data via K2-3 and an edge of the third data via K2-3 on a side away from the second data via K2-2.

In an exemplary embodiment, an orthographic projection of any one or more of the first pixel opening 100A, the second pixel opening 100B, and the third pixel opening 100C on the base substrate is not overlapped with orthographic projections of the data vias (including the first data via K2-1, the second data via K2-2, and the third data via K2-3) on the base substrate.

In an exemplary embodiment, in the second direction Y, the first data via K2-1 may be located between the first pixel opening 100A and the second pixel opening 100B.

In an exemplary embodiment, a side of the second anode 90B close to the first anode 90A may be provided with a groove configured to avoid the first data via K2-1.

In an exemplary embodiment, orthographic projections of the first pixel opening 100A and the second pixel opening 100B on the base substrate are at least partially overlapped with an orthographic projection of the first data signal line 61-1 on the base substrate, and the orthographic projections of the first pixel opening 100A and the second pixel opening 100B on the base substrate are not overlapped with orthographic projections of the second data signal line 61-2 and the third data signal line 61-3 on the base substrate.

In an exemplary embodiment, the second data via K2-2 and the third data via K2-3 may be located at two sides of the third pixel opening 100C in the first direction X.

In an exemplary embodiment, an orthographic projection of the third pixel opening 100C on the base substrate is not overlapped with orthographic projections of the first data signal line 61-1, the second data signal line 61-2, and the third data signal line 61-3 on the base substrate.

In an exemplary embodiment, an orthographic projection of any one or more of the first pixel opening 100A, the second pixel opening 100B, and the third pixel opening 100C on the base substrate is not overlapped with orthographic projections of the power supply via K1 and the anode via K3 on the base substrate.

In an exemplary embodiment, unlike the structure in which the first power supply line 71 is connected to the power supply connection line 44 through the power supply via K1 in the foregoing embodiment, the first power supply line 71 is connected to the power supply connection electrode through the power supply via K1 in the present embodiment, and because the power supply connection electrode is located on a side of the power supply connection line 44 in the second direction Y, the position of the power supply via K1 is lowered so that the pixel opening and the power supply via do not overlap. In this embodiment, the relative position of the power supply via and the pixel opening is adjusted by adjusting the position of the power supply via, thereby avoiding the power supply via being located in the pixel opening, ensuring the flatness of the anode, and improving the color deviation.

In an exemplary embodiment, the power supply via K1 may be located on a side of the second pixel opening 100B in the second direction Y, or the power supply via K1 may be located on a side of the third pixel opening 100C in the second direction Y.

In an exemplary embodiment, unlike the structure in which the anode and the pixel opening are disposed at the lower position of the circuit unit in the foregoing embodiment, the anode and the pixel opening are disposed at the upper position of the circuit unit in the present embodiment, and the relative positions of the data via, the power supply via and the pixel opening are adjusted by adjusting the positions of the anode and the pixel opening, thereby avoiding the power supply via being located in the pixel opening, ensuring the flatness of the anode, and improving the color deviation.

In an exemplary embodiment, in the second direction Y, the first pixel opening 100A, the second pixel opening 100B, and the third pixel opening 100C may be provided in a region of the corresponding circuit unit close to the previous unit row.

In an exemplary embodiment, an orthographic projection of the at least one first pixel opening 100A on the base substrate is at least partially overlapped with an orthographic projection of the first initial signal line 41 on the base substrate, and the orthographic projection of the first pixel opening 100A on the base substrate is not overlapped with an orthographic projection of the power supply connection line 44 on the base substrate.

In an exemplary embodiment, an orthographic projection of the at least one second pixel opening 100B on the base substrate is at least partially overlapped with orthographic projections of the first scan signal line 31 and the power supply connection line 44 on the base substrate, and the orthographic projection of the second pixel opening 100B on the base substrate is not overlapped with orthographic projections of the first initial signal line 41, the second initial signal line 42, and the third initial signal line 43 on the base substrate.

In an exemplary embodiment, an orthographic projection of the at least one third pixel opening 100C on the base substrate is at least partially overlapped with orthographic projections of the first scan signal line 31 and the third scan signal line 33 on the base substrate, and the orthographic projection of the third pixel opening 100C on the base substrate is not overlapped with orthographic projections of the second scan signal line 32, the light emitting signal line 34, the power supply connection line 44, and the second initial signal line 42 on the base substrate.

In an exemplary implementation, taking three circuit units as an example, the manufacturing process for the display substrate in this embodiment may include the following operations.

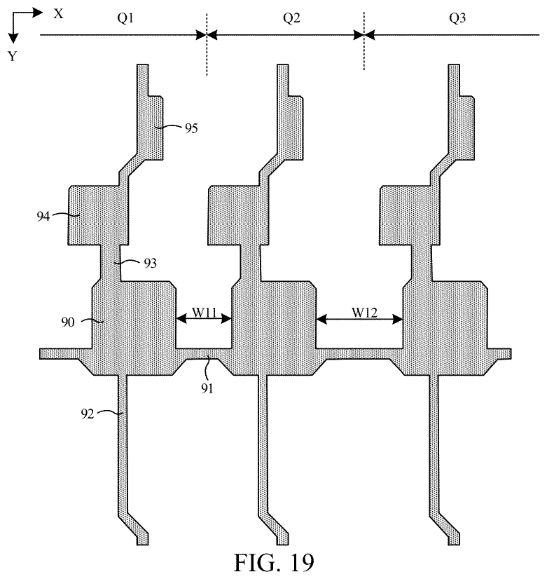

(31) A pattern of a shielding layer is formed. In an exemplary implementation, forming the pattern of the shielding layer may include: depositing a shielding thin film on a base substrate, patterning the shielding thin film through a patterning process to form the pattern of the shielding layer on the base substrate, as shown in FIG. 19.

In an exemplary embodiment, the pattern of the shielding layer of each circuit unit may include at least a shielding electrode 90, a first shielding connection strip 91, a second shielding connection strip 92, a third shielding connection strip 93, a first shielding block 94, and a second shielding block 95, and the above structures are substantially the same as those of the aforementioned embodiments.

In an exemplary embodiment, the pattern of the shielding layer in the second circuit unit Q2 is close to the pattern of the shielding layer in the first circuit unit Q1 and away from the pattern of the shielding layer in the third circuit unit Q3, that is, the distance between the pattern of the shielding layer in the first circuit unit Q1 and the pattern of the shielding layer in the second circuit unit Q2 is smaller than the distance between the pattern of the shielding layer in the second circuit unit Q2 and the pattern of the shielding layer in the third circuit unit Q3. For example, the shielding electrode 90 in the first circuit unit Q1 has an eleventh pitch W11 from the shielding electrode 90 in the second circuit unit Q2 and the shielding electrode 90 in the second circuit unit Q2 has a twelfth pitch W12 from the shielding electrode 90 in the third circuit unit Q3, and the eleventh pitch W11 is smaller than the twelfth pitch W12.

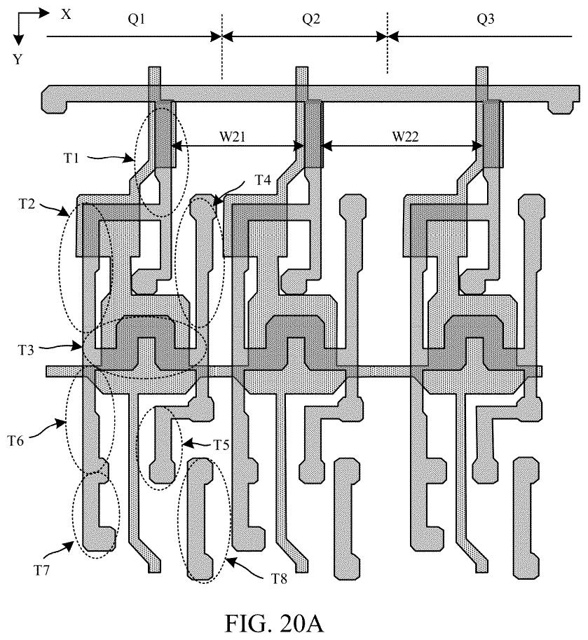

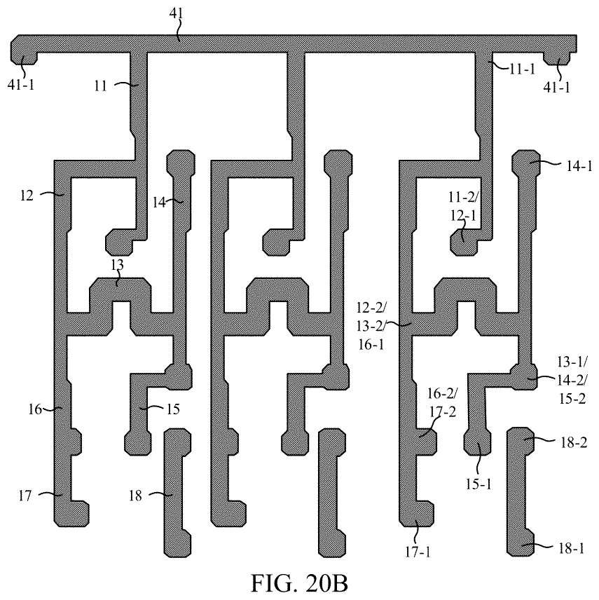

(32) A pattern of a semiconductor layer is formed. In an exemplary implementation, forming the pattern of the semiconductor layer may include: sequentially depositing a first insulating thin film and a semiconductor thin film on the base substrate on which the aforementioned pattern is formed, and patterning the semiconductor thin film through a patterning process to form a first insulating layer covering the shielding layer, and a pattern of a semiconductor layer arranged on the first insulating layer, as shown in FIG. 20A and FIG. 20B. FIG. 20B is a schematic plan view of the semiconductor layer in FIG. 20A.

In an exemplary embodiment, the pattern of the semiconductor layer of each circuit unit may include at least the first active layer 11 to the eighth active layer 18 and the first initial signal line 41, and the above-described structure is substantially the same as that of the above-described embodiment.

In an exemplary embodiment, a first initial connection block 41-1 may be provided on the first initial signal line, the first initial connection block 41-1 is configured to be connected to a subsequently formed initial connection line such that the first initial signal line extending along the first direction and the initial connection line extending along the second direction form a mesh communication structure for transmitting the first initial signal.

In an exemplary embodiment, the pattern of the semiconductor layer in the second circuit unit Q2 is close to the pattern of the semiconductor layer in the first circuit unit Q1 and away from the pattern of the semiconductor layer in the third circuit unit Q3, that is, the distance between the pattern of the semiconductor layer in the first circuit unit Q1 and the pattern of the semiconductor layer in the second circuit unit Q2 is smaller than the distance between the pattern of the semiconductor layer in the second circuit unit Q2 and the pattern of the semiconductor layer in the third circuit unit Q3. For example, there is a twenty-first pitch W21 between the first active layer 11 in the first circuit unit Q1 and the first active layer 11 in the second circuit unit Q2, and there is a twenty-second pitch W22 between the first active layer 11 in the second circuit unit Q2 and the first active layer 11 in the third circuit unit Q3, and the twenty-first pitch W21 is smaller than the twenty-second pitch W22.

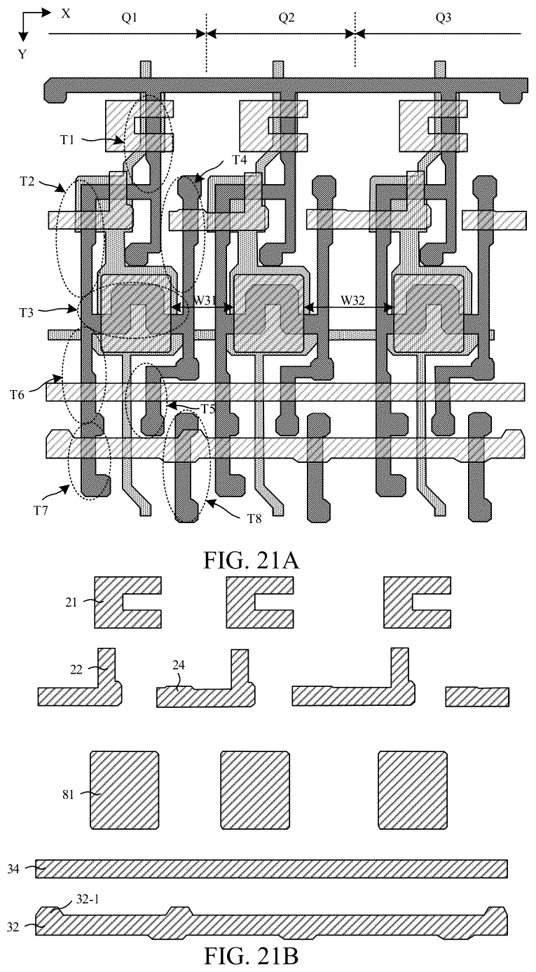

(33) A pattern of a first conductive layer is formed. In an exemplary implementation, forming the pattern of the first conductive layer may include: a second insulation thin film and a first conductive thin film are deposited sequentially on the base substrate on which the aforementioned patterns are formed, and the first conductive thin film is patterned through a patterning process to form a second insulating layer that covers the pattern of the semiconductor layer and form the pattern of the first conductive layer disposed on the second insulating layer, as shown in FIG. 21A and FIG. 21B, wherein FIG. 21B is a schematic plan view of the first conductive layer in FIG. 21A.

In an exemplary embodiment, the pattern of the first conductive layer of each circuit unit includes at least a first gate electrode 21, a second gate electrode 22, a fourth gate electrode 24, a second scan signal line 32, a light emitting signal line 34, and a first plate 81 of the storage capacitor, and the above structure are substantially the same as those of the aforementioned embodiment.

In an exemplary embodiment, the pattern of the first conductive layer in the second circuit unit Q2 is close to the pattern of the first conductive layer in the first circuit unit Q1 and away from the pattern of the first conductive layer in the third circuit unit Q3, that is, the distance between the pattern of the first conductive layer in the first circuit unit Q1 and the pattern of the first conductive layer in the second circuit unit Q2 is smaller than the distance between the pattern of the first conductive layer in the second circuit unit Q2 and the pattern of the first conductive layer in the third circuit unit Q3. For example, there is a thirty-first pitch W31 between the first plate 81 in the first circuit unit Q1 and the first plate 81 in the second circuit unit Q2, and there is a thirty-second pitch W32 between the first plate 81 in the second circuit unit Q2 and the first plate 81 in the third circuit unit Q3, and the thirty-first pitch W31 is smaller than the thirty-second pitch W32.

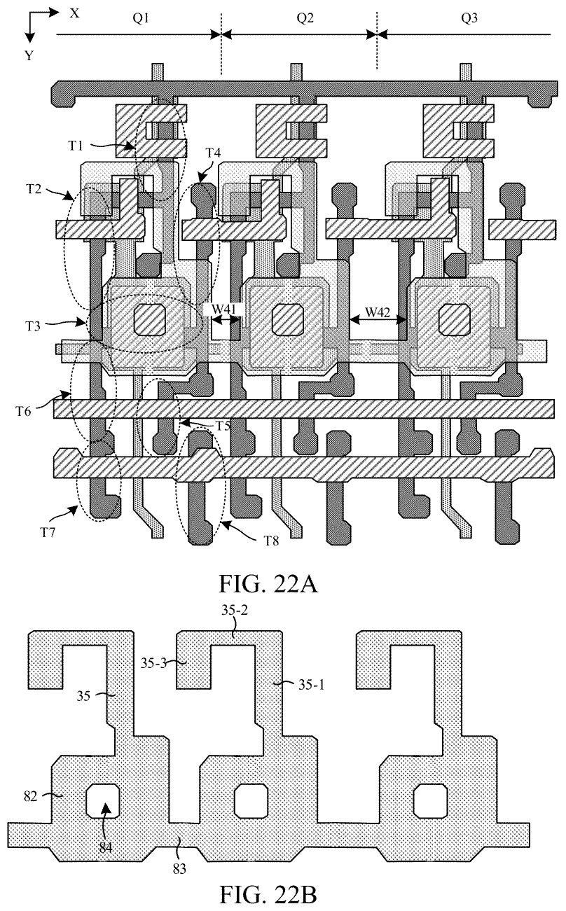

(34) A pattern of a second conductive layer is formed. In an exemplary embodiment, forming the pattern of the second conductive layer may include: depositing sequentially a third insulation thin film and a second conductive thin film on the base substrate on which the aforementioned patterns are formed, and the second conductive thin film is patterned through a patterning process to form a third insulating layer that covers the first conductive layer, and the pattern of the second conductive layer disposed on the third insulating layer, as shown in FIG. 22A and FIG. 22B. FIG. 22B is a schematic plan diagram of the second conductive layer in FIG. 22A.

In an exemplary embodiment, the pattern of the second conductive layer of each circuit unit includes at least a second plate 82 of a storage capacitor and a blocking electrode 35, and the above structures are substantially the same as those of the aforementioned embodiments.

In an exemplary embodiment, the pattern of the second conductive layer in the second circuit unit Q2 is close to the pattern of the second conductive layer in the first circuit unit Q1 and away from the pattern of the second conductive layer in the third circuit unit Q3, that is, the distance between the pattern of the second conductive layer in the first circuit unit Q1 and the pattern of the second conductive layer in the second circuit unit Q2 is smaller than the distance between the pattern of the second conductive layer in the second circuit unit Q2 and the pattern of the second conductive layer in the third circuit unit Q3. For example, there is a forty-first pitch W41 between the second plate 82 in the first circuit unit Q1 and the second plate 82 in the second circuit unit Q2, and there is a forty-second pitch W42 between the second plate 82 in the second circuit unit Q2 and the second plate 82 in the third circuit unit Q3, and the forty-first pitch W41 is smaller than the forty-second pitch W42.

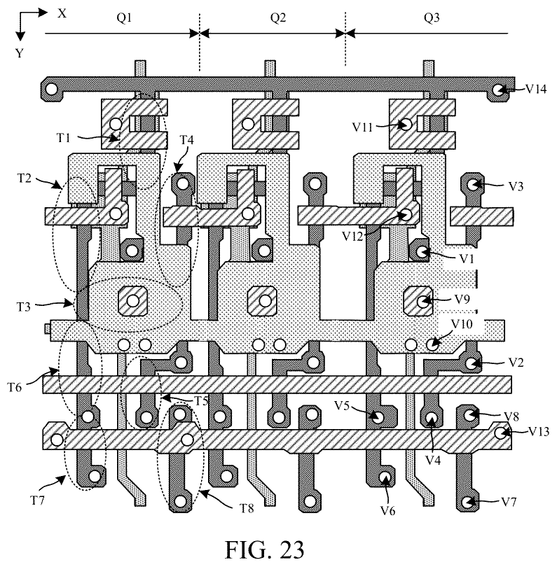

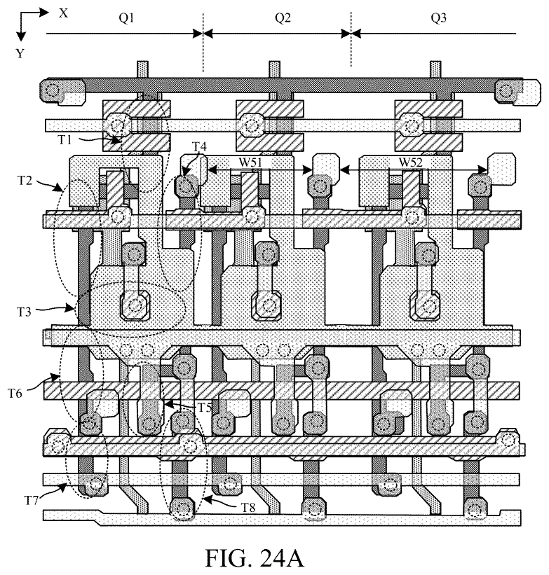

(35) A pattern of a fourth insulating layer is formed. In an exemplary implementation, forming the pattern of the fourth insulating layer may include: depositing a fourth insulation thin film on the base substrate on which the aforementioned patterns are formed, and patterning the fourth insulation thin film by a patterning process, to form a fourth insulating layer covering the second conductive layer, and a plurality of vias are provided on the fourth insulating layer, as shown in FIG. 23.

In an exemplary embodiment, the plurality of vias of each circuit unit include at least first vias V1 to fourteenth vias V14, and the structures of the first vias V1 to the thirteenth vias V13 are substantially the same as those of the aforementioned embodiments.

In an exemplary embodiment, the fourth insulating layer of the at least one circuit unit may further include a fourteenth via V14. An orthographic projection of the fourteenth via V14 on the base substrate is within a range of an orthographic projection of the first initial connection block 41-1 on the base substrate, the fourth insulating layer, the third insulating layer, and the second insulating layer in the fourteenth via V14 are etched away to expose the surface of the first initial connection block 41-1, and the fourteenth via V14 is configured such that a subsequently formed sixth connection electrode is connected with the first initial connection block 41-1 through the via.

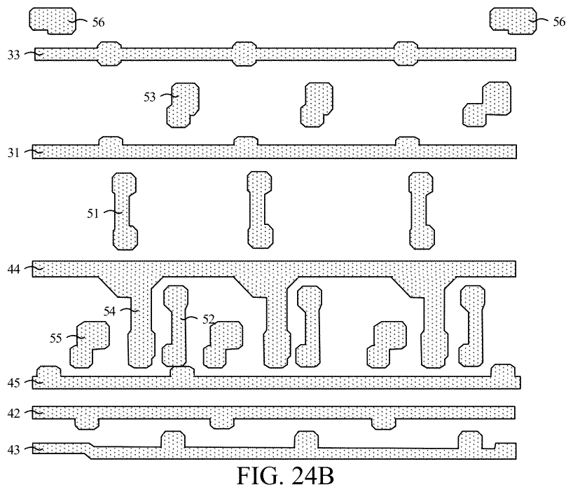

(36) A pattern of a third conductive layer is formed. In an exemplary implementation, forming the third conductive layer may include: depositing a third conductive thin film on the base substrate on which the aforementioned patterns are formed, and patterning the third conductive thin film through a patterning process to form a third conductive layer disposed on the fourth insulating layer, as shown in FIG. 24A and FIG. 24B, herein FIG. 24B is a planar schematic diagram of the third conductive layer in FIG. 24A.

In an exemplary embodiment, the third conductive layer of each circuit unit includes at least a first scan signal line 31, a third scan signal line 33, a second initial signal line 42, a third initial signal line 43, a power supply connection line 44, an auxiliary scan signal line 45, a first connection electrode 51, a second connection electrode 52, a third connection electrode 53, a fourth connection electrode 54, and a fifth connection electrode 55, and the above structures are substantially the same as those of the aforementioned embodiments.

In an exemplary embodiment, the third conductive layer of the at least one circuit unit may further include a sixth connection electrode 56. The sixth connection electrode 56 may be in a shape of a block (e.g., a rectangle), and the sixth connection electrode 56 is connected to the first initial connection block 41-1 through the fourteenth via V14. In an exemplary embodiment, the sixth connection electrode 56 is configured to connect subsequently formed initial connection lines.

In an exemplary embodiment, the pattern of the third conductive layer in the second circuit unit Q2 is close to the pattern of the third conductive layer in the first circuit unit Q1 and away from the pattern of the third conductive layer in the third circuit unit Q3, that is, the distance between the pattern of the third conductive layer in the first circuit unit Q1 and the pattern of the third conductive layer in the second circuit unit Q2 is smaller than the distance between the pattern of the third conductive layer in the second circuit unit Q2 and the pattern of the third conductive layer in the third circuit unit Q3. For example, there is a fifty-first pitch W51 between the third connection electrode 53 in the first circuit unit Q1 and the third connection electrode 53 in the second circuit unit Q2, and there is a fifty-second pitch W52 between the third connection electrode 53 in the second circuit unit Q2 and the third connection electrode 53 in the third circuit unit Q3, and the fifty-first pitch W51 is smaller than the fifty-second pitch W52.

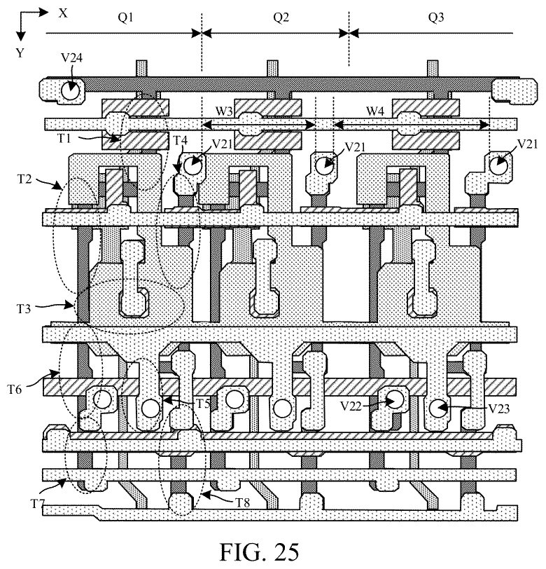

(37) A pattern of a first planarization layer is formed. In an exemplary implementation, forming a pattern of a first planarization layer may include coating a first planarization film on the base substrate on which the above-mentioned patterns are formed, patterning the first planarization film through a patterning process, forming a first planarization layer covering the third conductive layer, the first planarization layer is provided with a plurality of vias, as shown in FIG. 25.

In an exemplary embodiment, the plurality of vias of each circuit unit include at least a twenty-first via V21, a twenty-second via V22, and a twenty-third via V23, and the structures of the twenty-first via V21 and the twenty-second via V22 are substantially the same as those of the aforementioned embodiments.

In an exemplary implementation, an orthographic projection of the twenty-third via V23 on the base substrate is located within a range of an orthographic projection of the fourth connection electrode 54 on the base substrate, the first planarization layer within the twenty-third via V23 is removed to expose a surface of the fourth connection electrode 54, and the twenty-third via V23 is configured such that the subsequently formed first power supply line is connected to the fourth connection electrode 54 through the via. In an exemplary embodiment, the twenty-third via V23 may be referred to as a power supply via.

In an exemplary implementation, the twenty-first via V21 may be used as a data via. Because the pixel drive circuit in the second circuit unit Q2 is close to the pixel drive circuit in the first circuit unit Q1 and away from the pixel drive circuit in the third circuit unit Q3, the twenty-first via V21 in the second circuit unit Q2 is close to the twenty-first via V21 in the first circuit unit Q1 and away from the twenty-first via V21 in the third circuit unit Q3.

In an exemplary embodiment, there is a third pitch W3 between the twenty-first via V21 (a first data via) in the first circuit unit Q1 and the twenty-first via V21 (a second data via) in the second circuit unit Q2, and there is a fourth pitch W4 between the twenty-first via V21 (the second data via) in the second circuit unit Q2 and the twenty-first via V21 (a third data via) in the third circuit unit Q3, and the third pitch W3 is smaller than the fourth pitch W4, so that the twenty-first vias V21 in the second circuit unit Q2 and the third circuit unit Q3 can avoid subsequently formed pixel openings, ensure the flatness of the anode, and improve the color deviation.

In an exemplary embodiment, the third pitch W3 may be a distance between an edge of the twenty-first via V21 in the first circuit unit Q1 close to the twenty-first via V21 in the second circuit unit Q2 and an edge of the twenty-first via V21 in the second circuit unit Q2 close to the twenty-first via V21 in the first circuit unit Q1, or may be a distance between an edge of the twenty-first via V21 in the first circuit unit Q1 on a side away from the twenty-first via V21 in the second circuit unit Q2 and an edge of the twenty-first via V21 in the second circuit unit Q2 on a side away from the twenty-first via V21 in the first circuit unit Q1. The fourth pitch W4 may be a distance between an edge of the twenty-first via V21 in the second circuit unit Q2 on a side close to the twenty-first via V21 in the third circuit unit Q3 and an edge of the twenty-first via V21 in the third circuit unit Q3 on a side close to the twenty-first via V21 in the second circuit unit Q2, or a distance between an edge of the twenty-first via V21 in the second circuit unit Q2 on a side away from the twenty-first via V21 in the third circuit unit Q3 and an edge of the twenty-first via V21 in the third circuit unit Q3 on a side away from the twenty-first via V21 in the second circuit unit Q2.

In an exemplary embodiment, the first planarization layer of the at least one circuit unit may further include a twenty-fourth via V24. An orthographic projection of the twenty-fourth via V24 on the base substrate is within a range of an orthographic projection of the sixth connection electrode 56 on the base substrate, the first planarization layer within the twenty-fourth via V24 is removed to expose the surface of the sixth connection electrode 56, and the twenty-fourth via V24 is configured such that a subsequently formed initial connection line is connected to the sixth connection electrode 56 through the via.

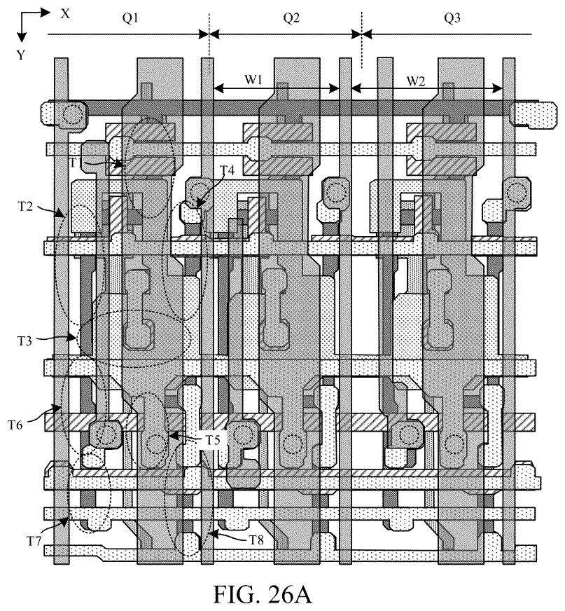

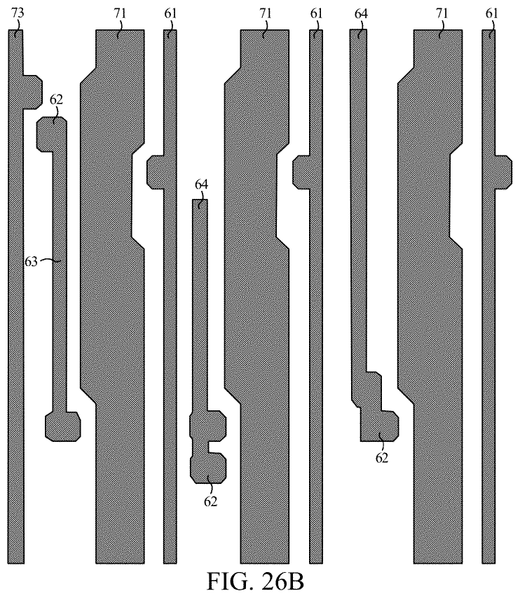

(38) A pattern of a fourth conductive layer is formed. In an exemplary implementation, forming the fourth conductive layer may include: depositing a fourth conductive thin film on the base substrate on which the aforementioned patterns are formed, and patterning the third conductive thin film through a patterning process to form a fourth conductive layer disposed on the first planarization layer, as shown in FIG. 26A and FIG. 26B, herein FIG. 26B is a planar schematic diagram of the fourth conductive layer in FIG. 26A.

In an exemplary embodiment, the fourth conductive layer of each circuit unit includes at least a data signal line 61, an anode connection electrode 62, and a first power supply line 71.

In the exemplary implementation, the data signal line 61 may be in a shape of a straight line or a bend line that extends along the second direction Y, and the data signal line 61 is connected to the third connection electrode 53 through the twenty-first via V21. Because the third connection electrode 53 is connected to the first region of the fourth active layer, it is achieved that the data signal line 61 can write a data signal to the first electrode of the fourth transistor T4.

In an exemplary embodiment, the positions of the data signal lines 61 in the first circuit unit Q1, the second circuit unit Q2, and the third circuit unit Q3 may be substantially the same, and the data signal lines 61 may all be located on a side of the first power supply line 71 in the first direction X.

In an exemplary embodiment, the pattern of the fourth conductive layer in the second circuit unit Q2 is close to the pattern of the fourth conductive layer in the first circuit unit Q1 and away from the pattern of the fourth conductive layer in the third circuit unit Q3, that is, the distance between the pattern of the fourth conductive layer in the first circuit unit Q1 and the pattern of the fourth conductive layer in the second circuit unit Q2 is smaller than the distance between the pattern of the fourth conductive layer in the second circuit unit Q2 and the pattern of the fourth conductive layer in the third circuit unit Q3. For example, there is a first pitch W1 between the data signal line 61 in the first circuit unit Q1 and the data signal line 61 in the second circuit unit Q2, and there is a second pitch W2 between the data signal line 61 in the second circuit unit Q2 and the data signal line 61 in the third circuit unit Q3, and the first pitch W1 is smaller than the second pitch W2.

In an exemplary embodiment, the first pitch W1 may be a distance between an edge of the data signal line 61 in the first circuit unit Q1 on a side close to the data signal line 61 in the second circuit unit Q2 and an edge of the data signal line 61 in the second circuit unit Q2 on a side close to the data signal line 61 in the first circuit unit Q1, or may be a distance between an edge of the data signal line 61 in the first circuit unit Q1 on a side away from the data signal line 61 in the second circuit unit Q2 and an edge of the data signal line 61 in the second circuit unit Q2 on a side away from the data signal line 61 in the first circuit unit Q1. The second pitch W2 may be a distance between an edge of the data signal line 61 in the second circuit unit Q2 on a side close to the data signal line 61 in the third circuit unit Q3 and an edge of the data signal line 61 in the third circuit unit Q3 on a side close to the data signal line 61 in the second circuit unit Q2, or a distance between an edge of the data signal line 61 in the second circuit unit Q2 on a side away from the data signal line 61 in the third circuit unit Q3 and an edge of the data signal line 61 in the third circuit unit Q3 on a side away from the data signal line 61 in the second circuit unit Q2.

In an exemplary embodiment, the anode connection electrode 62 may be in a shape of a block (e.g., a rectangle), and the anode connection electrode 62 is configured to be connected with a subsequently formed anode.

In an exemplary embodiment, the anode connection electrode 62 of the circuit unit in the first circuit unit Q1 may be provided on a side of the power supply connection line 44 in the present circuit unit in the opposite direction of the second direction Y, and the anode connection electrode 62 is connected to the fifth connection electrode 55 through the anode connection line 63.

In an exemplary embodiment, the fourth conductive layer of the circuit unit in the first circuit unit Q1 may further include an anode connection line 63, and the anode connection line 63 may be in a shape of a strip extending along the second direction Y, the first end of the anode connection line 63 is connected to the anode connection electrode 62, and the second end of the anode connection line 63 extends along the second direction Y in a direction close to the fifth connection electrode 55, and then is connected to the fifth connection electrode 55 through the twenty-second via V22.

In an exemplary embodiment, in at least one circuit unit, the anode connection electrode 62 and the anode connection line 63 may be of an interconnected integral structure.

In an exemplary embodiment, the anode connection electrodes 62 of the circuit units in the second circuit unit Q2 and the third circuit unit Q3 may be provided on a side of the power supply connection line 44 in the present circuit unit in the second direction Y, and the anode connection electrodes 62 are connected to the fifth connection electrode 55 through the twenty-second via V22.

In an exemplary embodiment, the fourth conductive layer in the second circuit unit Q2 and the third circuit unit Q3 may further include an extension electrode 64, the extension electrode 64 may be in a shape of a strip extending along the second direction Y, the first end of the extension electrode 64 is connected to the anode connection electrode 62, the second end of the extension electrode 64 extends along the opposite direction of the second direction Y, and the extension electrode 64 is configured to improve the flatness of the anode.

In an exemplary embodiment, in at least one circuit unit, the anode connection electrode 62 and the extension electrode 64 may be of an interconnected integral structure.

In an exemplary embodiment, the first power supply line 71 may be in a shape of a straight line or a bend line extending along the second direction Y, the first power supply line 71 may be provided in each circuit unit, and the first power supply line 71 is connected to the fourth connection electrode 54 through the twenty-third via V23. Because the fourth connection electrode 54 is connected to the power supply connection line 44, it is achieved that the power supply connection line 44 with a main body portion extending in the first direction X and the first power supply line 71 with a main body portion extending in the second direction Y are connected to each other, so that the first power supply line 71 and the power supply connection line 44 form a mesh communication structure for transmitting the first power supply signal in the display substrate, which can not only effectively reduce a resistance of the first power supply line 71 and reduce a voltage drop of the first power supply signal, but also effectively improve uniformity of the first power supply signal in the display substrate, effectively improve display uniformity and improve display quality.

In an exemplary embodiment, unlike the structure in which the first power supply line 71 is connected to the power supply connection line 44 through the twenty-third via V23 in the foregoing embodiment, the first power supply line 71 is connected to the fourth connection electrode 54 served as the power supply connection electrode through the twenty-third via V23 in the present embodiment, and because the fourth connection electrode 54 is located on a side of the power supply connection line 44 in the second direction Y, the position of the twenty-third via V23 is lowered so that the subsequently formed pixel openings and the twenty-third via V23 do not overlap.

In an exemplary embodiment, an orthographic projection of the first power supply line 71 on the base substrate is at least partially overlapped with an orthographic projection of the first connection electrode 51 on the base substrate so that the first power supply line 71 at a constant voltage can effectively shield the influence of other signals in the pixel drive circuit on the first node N1.

In an exemplary embodiment, the fourth conductive layer of some circuit units may further include an initial connection line 73, the initial connection line 73 may be in a shape of a straight line or a bend line extending along the second direction Y, the initial connection line 73 may be provided in the first circuit unit Q1, and the initial connection line 73 may be connected to the sixth connection electrode 56 through the twenty-fourth via V24. Because the sixth connection electrode 56 is connected with the first initial connection block 41-1, the first initial connection block 41-1 is connected with the first initial signal line 41, so that the first initial signal line with a main body portion extending along the first direction X and the initial connection line with a main body portion extending along the second direction Y form a mesh communication structure for transmitting the first initial signal on the display substrate, which can not only effectively reduce the resistance of the first initial signal line, reduce the voltage drop of the first initial signal, but also effectively improve the uniformity of the first initial signal, effectively improve the display uniformity, and improve the display quality.

In some possible embodiments, the initial connection line may be connected to the second initial signal line through a via, such that the second initial signal line and the initial connection line form a mesh communication structure for transmitting the second initial signal on the display substrate, or the initial connection line may be connected to the third initial signal line through a via, such that the third initial signal line and the initial connection line form a mesh communication structure for transmitting the third initial signal on the display substrate, which is not limited in the present disclosure.

In some possible embodiments, the fourth conductive layer of at least one circuit unit may further include a second power supply line, forming a VSS in pixel structure, which is not limited in the present disclosure.

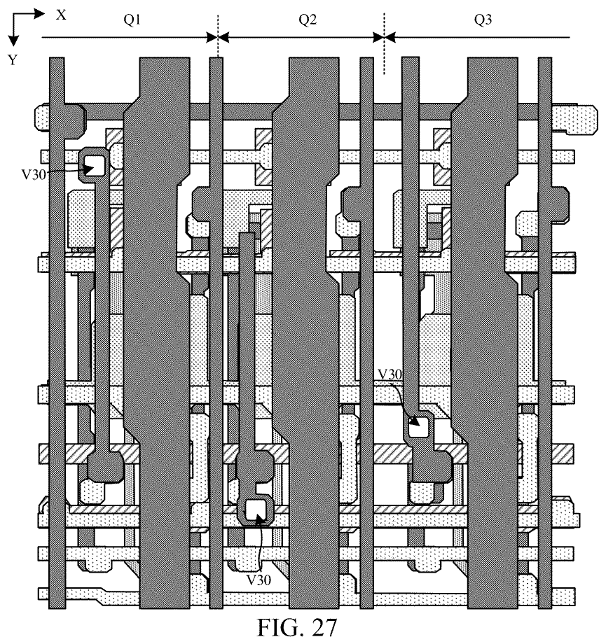

(39) A pattern of a second planarization layer is formed. In an exemplary implementation, forming the pattern of the second planarization layer may include: coating a second planarization thin film on the base substrate on which the aforementioned patterns are formed, patterning the first planarization thin film through a patterning process to form a second planarization layer covering the fourth conductive layer, herein the second planarization layer is provided with a plurality of vias, as shown in FIG. 27.

In an exemplary implementation, the plurality of vias of each circuit unit at least includes an anode via V30. An orthographic projection of the anode via V30 on the base substrate is within a range of an orthographic projection of the anode connection electrode 62 on the base substrate, the second planarization layer within the anode via V30 is removed to expose a surface of the anode connection electrode 62, and the anode connection electrode is configured such that an anode formed subsequently is connected to the anode connection electrode 62 through the via.

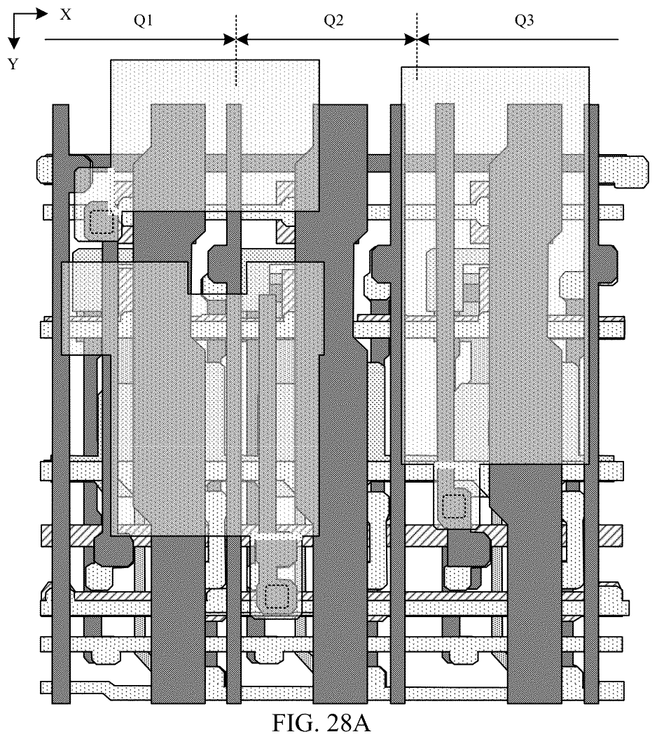

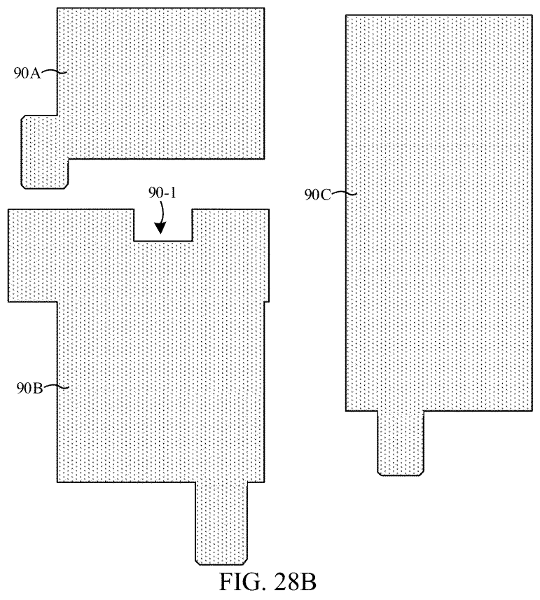

(40) A pattern of an anode conductive layer is formed. In an exemplary implementation, forming the pattern of the anode conductive layer may include: depositing an anode conductive thin film on the base substrate on which the aforementioned patterns are formed, and patterning the anode conductive thin film using a patterning process to form an anode conductive layer disposed on the second planarization layer, wherein the anode conductive layer at least includes patterns of a plurality of anodes, as shown in FIG. 28A and FIG. 28B, and FIG. 28B is a schematic plan view of the anode conductive layer in FIG. 28A.

In an exemplary embodiment, the plurality of anodes may include a first anode 90A located in the red light emitting unit, a second anode 90B located in the green light emitting unit, and a third anode 90C located in the blue light emitting unit, the first anode 90A and the second anode 90B may be sequentially disposed along the second direction Y, and the third anode 90C may be disposed on a side of the first anode 90A and the second anode 90B in the first direction X.

In an exemplary embodiment, the first anode 90A, the second anode 90B, and the third anode 90C may be connected to the anode connection electrode 62 of the corresponding circuit unit through the anode vias V30, respectively.

In an exemplary embodiment, at least one of the first anode 90A, the second anode 90B, and the third anode 90C may include an anode main body portion and an anode connection portion connected to each other, the anode connection portion is connected to the anode main body portion on the one hand and is connected to the anode connection electrode 62 through the anode via V30 on the other hand.

In an exemplary embodiment, an orthographic projection of the first anode main body portion on the base substrate is not overlapped with orthographic projections of the twenty-first via V21 served as the data via and the twenty-third via V23 served as the power supply via on the base substrate, and the orthographic projection of the first anode main body portion on the base substrate is not overlapped with an orthographic projection of the anode via V30 on the base substrate.

In an exemplary embodiment, because the first anode 90A, the second anode 90B, and the third anode 90C move upward as a whole, an orthographic projection of the first anode main body portion on the base substrate is at least partially overlapped with an orthographic projection of the first initial signal line 41 on the base substrate, and the orthographic projection of the first anode main body portion on the base substrate and an orthographic projection of the power supply connection line 44 on the base substrate do not overlap.

In an exemplary embodiment, the second anode main body portion may be provided with a groove 90-1. The groove 90-1 may be in a shape of a block (such as a rectangle), may be located on an edge of the second anode main body portion on a side close to the first anode 90 A, and the groove 90-1 is configured to avoid the twenty-first via V21, so that an orthographic projection of the second anode main body portion on the base substrate and an orthographic projection of the twenty-first via V21, which is served as a data via, on the base substrate do not overlap.

In an exemplary embodiment, because the first anode 90A, the second anode 90B, and the third anode 90C move upward as a whole, and the twenty-first via V21, which is served as a power supply via, moves downward, so that an orthographic projection of the second anode main body portion on the base substrate and an orthographic projection of the twenty-third via V23, which is served as a power supply via, do not overlap on the base substrate.

In an exemplary embodiment, because the first anode 90A, the second anode 90B, and the third anode 90C move upward as a whole, an orthographic projection of the second anode main body portion on the base substrate is at least partially overlapped with orthographic projections of the first scan signal line 31 and the power supply connection line 44 on the base substrate, and the orthographic projection of the second anode main body portion on the base substrate is not overlapped with orthographic projections of the first initial signal line 41, the second initial signal line 42, and the second initial signal line 43 on the base substrate.

In an exemplary embodiment, because the pitch between the data via in the second circuit unit Q2 and the data via in the third circuit unit Q3 is increased due to pixel compression, the twenty-first via V21 in the second circuit unit Q2 and the twenty-first via V21 in the third circuit unit Q3 are respectively located at two sides of the third anode main body portion in the first direction X, and the pitch between the twenty-first via V21 in the second circuit unit Q2 and the twenty-first via V21 in the third circuit unit Q3 is larger than the width of the third anode main body portion in the first direction X, so that an orthographic projection of the third anode main body portion on the base substrate is not overlapped with an orthographic projection of the twenty-first via V21, which is served as a data via, on the base substrate.

In an exemplary embodiment, because the first anode 90A, the second anode 90B, and the third anode 90C move upward as a whole, and the twenty-first via V21, which is a served as power supply via, moves downward, an orthographic projection of the third anode main body portion on the base substrate and an orthographic projection of the twenty-third via V23, which is served as a power supply via, do not overlap on the base substrate.

In an exemplary embodiment, because the first anode 90A, the second anode 90B, and the third anode 90C move upward as a whole, an orthographic projection of the third anode main body portion on the base substrate is at least partially overlapped with orthographic projections of the first scan signal line 31 and the third scan signal line 33 on the base substrate, and the orthographic projection of the third anode main body portion on the base substrate is not overlapped with orthographic projections of the second scan signal line 32, the light emitting signal line 34, the power supply connection line 44, and the second initial signal line 42 on the base substrate.

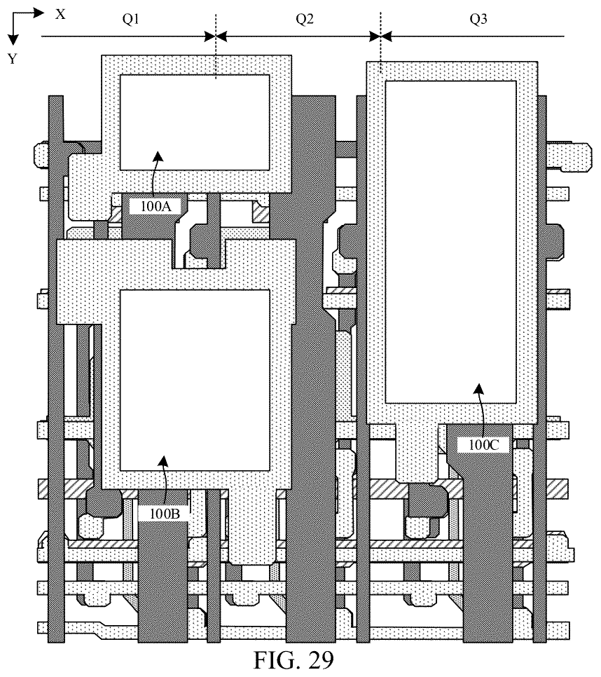

(41) A pattern of a pixel definition layer is formed. In an exemplary implementation, forming the pattern of the pixel definition layer may include: coating a pixel definition thin film on the base substrate on which the above-mentioned patterns are formed, patterning the pixel definition thin film using a patterning process, to form the pattern of the pixel definition layer covering the pattern of the anode conductive layer, and a plurality of pixel openings are provided on the pixel definition layer, as shown in FIG. 29.

In an exemplary embodiment, the plurality of pixel openings may include a first pixel opening 100A, a second pixel opening 100B, and a third pixel opening 100C, and the above structures are substantially the same as those of the aforementioned embodiments.

In an exemplary embodiment, orthographic projections of any one or more of the first pixel opening 100A, the second pixel opening 100B, and the third pixel opening 100C on the base substrate are not overlapped with an orthographic projection of the twenty-first via V21 served as a data via on the base substrate, are not overlapped with an orthographic projection of the twenty-first via V21 served as a power supply via on the base substrate, and are not overlapped with an orthographic projection of the anode via on the base substrate.

In an exemplary embodiment, in the second direction Y, the first pixel opening 100A, the second pixel opening 100B, and the third pixel opening 100C may be provided in a region of the corresponding circuit unit close to the previous unit row.

In an exemplary embodiment, an orthographic projection of at least one first pixel opening 100A on the base substrate is at least partially overlapped with an orthographic projection of the first initial signal line 41 on the base substrate, and the orthographic projection of the first pixel opening 100A on the base substrate is not overlapped with an orthographic projection of the power supply connection line 44 on the base substrate.

In an exemplary embodiment, an orthographic projection of at least one first pixel opening 100A on the base substrate is at least partially overlapped with an orthographic projection of the third initial signal line 43 on the base substrate, and the orthographic projection of the at least one first pixel opening 100A on the base substrate is not overlapped with orthographic projections of the first scan signal line 31, the second scan signal line 32, the third scan signal line 33, the light emitting signal line 34, and the second initial signal line 42 on the base substrate.

In an exemplary embodiment, an orthographic projection of at least one second pixel opening 100B on the base substrate is at least partially overlapped with orthographic projections of the first scan signal line 31 and the power supply connection line 44 on the base substrate, and the orthographic projection of the second pixel opening 100B on the base substrate is not overlapped with orthographic projections of the first initial signal line 41, the second initial signal line 42, and the third initial signal line 43 on the base substrate.

In an exemplary embodiment, an orthographic projection of the at least one second pixel opening 100B on the base substrate is not overlapped with orthographic projections of the second scan signal line 32, the third scan signal line 33, and the light emitting signal line 34 on the base substrate.

In an exemplary embodiment, an orthographic projection of at least one third pixel opening 100C on the base substrate is at least partially overlapped with orthographic projections of the first scan signal line 31 and the third scan signal line 33 on the base substrate, and the orthographic projection of the third pixel opening 100C on the base substrate is not overlapped with orthographic projections of the second scan signal line 32, the light emitting signal line 34, the power supply connection line 44, and the second initial signal line 42 on the base substrate.

In an exemplary embodiment, an orthographic projection of the at least one third pixel opening 100C on the base substrate is at least partially overlapped with orthographic projections of the first initial signal line 41 and the third initial signal line 43 on the base substrate.

In an exemplary embodiment, the subsequent preparation process may include forming an organic light emitting layer, a cathode, and an encapsulation structure layer, and the above structures are substantially the same as those of the aforementioned embodiments.

The display substrate provided by the exemplary embodiment of the present disclosure has the technical effects of the aforementioned embodiments, and by using technical methods such as pixel compression to adjust the pitch between data vias, overall upward movement of the anodes, and downward movement of the power supply vias, there are no data vias and power supply vias in the range where the pixel opening is located, and the anode exposed by the pixel opening has good flatness, which can effectively avoid defects such as screen-off watermark caused by flatness variation of the anode, and can effectively improve color deviation and improve display quality.

The aforementioned structure and the preparation process thereof shown in the present disclosure are merely exemplary description. In an exemplary embodiment, corresponding structures may be changed and patterning processes may be added or reduced according to actual needs, which is not limited here in the present disclosure.

In an exemplary embodiment, the display substrate according to the present disclosure may be applied to a display device with a pixel drive circuit, such as an OLED, quantum dot display (QLED), light emitting diode display (such as Micro LED or Mini LED), or Quantum Dot Light Emitting Diode display (QDLED), which is not limited here in the present disclosure.

The present disclosure further provides a manufacturing method for a display substrate, for manufacturing the display substrate according to the foregoing embodiments. In an exemplary implementation, the preparation method may include:
Forming a drive structure layer on a base substrate, the drive structure layer includes a plurality of circuit units, at least one circuit unit includes a pixel drive circuit, a power supply connection line extending along a first direction, and a first power supply line extending along a second direction, the first direction and the second direction intersect, the pixel drive circuit includes at least a power supply connection electrode connected to the power supply connection line, the first power supply line is connected to the power supply connection line or the power supply connection electrode through a power supply via; and
Forming a light emitting structure layer on the drive structure layer; the light emitting structure layer includes a plurality of light emitting units, at least one light emitting unit includes an anode and a pixel definition layer disposed on a side of the anode away from the base substrate, the anode is connected with a pixel drive circuit of a corresponding circuit unit, the pixel definition layer is provided with a pixel opening exposing the anode, and an orthographic projection of at least one pixel opening on the base substrate and an orthographic projection of the power supply via on the base substrate do not overlap.

A display device which includes the aforementioned display substrate is further provided in the present disclosure. The display device may be any product or component with a display function, such as a mobile phone, a tablet computer, a television, a display, a laptop computer, a digital photo frame, and a navigator, which is not limited in the embodiments of the present invention.

Although embodiments disclosed in the present disclosure are as above, it should be noted that the above embodiments are exemplary only rather than restrictive. Therefore, the present disclosure is not limited to what is specifically shown and described here. Various modifications, substitutions, or omissions may be made in forms and details of implementations without departing from the scope of the present disclosure.

1. A display substrate, comprising a drive structure layer disposed on a base substrate and a light emitting structure layer disposed on a side of the drive structure layer away from the base substrate, wherein on a plane parallel to the display substrate, the drive structure layer comprises a plurality of circuit units, at least one circuit unit comprises a pixel drive circuit, a power supply connection line extending along a first direction, and a first power supply line extending along a second direction, the first direction and the second direction are intersected, the pixel drive circuit comprises at least a power supply connection electrode connected to the power supply connection line, the first power supply line is connected to the power supply connection line or the power supply connection electrode through a power supply via; the light emitting structure layer comprises a plurality of light emitting units, at least one light emitting unit comprises an anode and a pixel definition layer disposed on a side of the anode away from the base substrate, the anode is connected with a pixel drive circuit of a corresponding circuit unit, the pixel definition layer is provided with a pixel opening exposing the anode, and an orthographic projection of at least one pixel opening on the base substrate is not overlapped with an orthographic projection of the power supply via on the base substrate.

2. The display substrate according to claim 1, wherein the plurality of light emitting units comprise at least a first light emitting unit emitting light of a first color, a second light emitting unit emitting light of a second color, and a third light emitting unit emitting light of a third color, the first light emitting unit comprises at least a first anode and a first pixel opening exposing the first anode, the second light emitting unit comprises at least a second anode and a second pixel opening that exposes the second anode, the third light emitting unit comprises at least a third anode and a third pixel opening that exposes the third anode; the second anode is disposed at a side of the first anode in the second direction, and the third anode is disposed at a side of the first anode in the first direction; orthographic projections of the first pixel opening and the second pixel opening on the base substrate are at least partially overlapped with an orthographic projection of the first power supply line on the base substrate, and an orthographic projection of the third pixel opening on the base substrate is not overlapped with the orthographic projection of the first power supply line on the base substrate.

3. The display substrate according to claim 2, wherein the orthographic projections of the first pixel opening and the second pixel opening on the base substrate are within a range of the orthographic projection of the first power supply line on the base substrate.

4. The display substrate according to claim 2, wherein in the at least one circuit unit and a circuit unit adjacent in the first direction, first power supply lines in the two circuit units are of an interconnected integral structure.

5. The display substrate according to claim 2, wherein the at least one circuit unit further comprises a data signal line, and in the at least one circuit unit and a circuit unit adjacent in the first direction, the data signal line in one circuit unit is disposed at a side of the first power supply line in an opposite direction of the first direction, and the data signal line in the other circuit unit is disposed at a side of the first power supply line in the first direction; the orthographic projections of the first pixel opening and the second pixel opening on the base substrate are not overlapped with an orthographic projection of the data signal line on the base substrate, and the orthographic projection of the third pixel opening on the base substrate is at least partially overlapped with the orthographic projection of the data signal line on the base substrate.

6. The display substrate according to claim 5, wherein the pixel drive circuit further comprises a fourth transistor and a data connection electrode, the fourth transistor comprises at least a fourth active layer, and the data signal line is connected to the data connection electrode through a data via; in the at least one circuit unit and a circuit unit adjacent in the first direction, the data connection electrode in one circuit unit is connected to a first region of the fourth active layer through a via, and the data connection electrode in the other circuit unit is connected to the first region of the fourth active layer through a data connection line.

7. The display substrate according to claim 6, wherein the pixel drive circuit further comprises a blocking electrode and a second transistor with a double-gate structure, the blocking electrode is connected to the first power supply line, an orthographic projection of the blocking electrode on the base substrate is at least partially overlapped with an orthographic projection of a second active layer between two gate electrodes of the second transistor on the base substrate, and the orthographic projection of the blocking electrode on the base substrate is at least partially overlapped with an orthographic projection of the data connection line on the base substrate.

8. The display substrate according to claim 5, wherein the pixel drive circuit further comprises a fourth node electrode and an anode connection electrode, and an anode in the at least one light emitting unit is connected to the anode connection electrode through an anode via; in the at least one circuit unit and a circuit unit adjacent in the first direction, the anode connection electrode in one circuit unit is connected to the fourth node electrode through a via, and the anode connection electrode in the other circuit unit is connected to the fourth node electrode through an anode connection line; the orthographic projections of the first pixel opening and the second pixel opening on the base substrate are not overlapped with an orthographic projection of the anode connection line on the base substrate, and the orthographic projection of the third pixel opening on the base substrate is at least partially overlapped with the orthographic projection of the anode connection line on the base substrate.

9. The display substrate according to claim 8, wherein the third pixel opening comprises an opening centerline, that is a straight line extending along the second direction and passing through a geometric center of the third pixel opening; in at least one third pixel opening, there is a first distance between the anode connection line and the opening centerline, there is a second distance between the data signal line and the opening centerline, and a ratio of the first distance to the second distance is 0.8 to 1.2.

10. The display substrate according to claim 2, wherein the at least one circuit unit further comprises at least one initial signal line extending along the first direction and a second power supply line and an initial connection line extending along the second direction, the initial connection line is connected to the initial signal line, the orthographic projections of the first pixel opening and the second pixel opening on the base substrate are not overlapped with orthographic projections of the second power supply line and the initial connection line on the base substrate, and the orthographic projection of the third pixel opening on the base substrate is at least partially overlapped with the orthographic projections of the second power supply line and the initial connection line on the base substrate.

11. The display substrate according to claim 10, wherein the third pixel opening comprises an opening centerline, that is a straight line extending along the second direction and passing through a geometric center of the third pixel opening; in at least one third pixel opening, there is a third distance between the second power supply line and the opening centerline, there is a fourth distance between the initial connection line and the opening centerline, and a ratio of the third distance to the fourth distance is 0.8 to 1.2.

12. The display substrate according to claim 2, wherein the pixel drive circuit further comprises a storage capacitor, and the at least one circuit unit further comprises a first scan signal line, a second scan signal line, a third scan signal line, a light emitting signal line, a first initial signal line, a second initial signal line, and a third initial signal line extending along the first direction and connected to the pixel drive circuit, the first scan signal line is disposed at a side of the storage capacitor in an opposite direction of the second direction, the third scan signal line is disposed at a side of the first scan signal line away from the storage capacitor, the first initial signal line is disposed at a side of the third scan signal line away from the storage capacitor, the light emitting signal line is disposed at a side of the storage capacitor in the second direction, the second scan signal line is disposed at a side of the light emitting signal line away from the storage capacitor, the second initial signal line is disposed at a side of the second scan signal line away from the storage capacitor, the third initial signal line is disposed at a side of the second initial signal line away from the storage capacitor; an orthographic projection of at least one first pixel opening on the base substrate is at least partially overlapped with an orthographic projection of the power supply connection line on the base substrate, an orthographic projection of at least one second pixel opening on the base substrate is at least partially overlapped with orthographic projections of the first initial signal line, the second initial signal line and the third initial signal line on the base substrate, and an orthographic projection of at least one third pixel opening on the base substrate is at least partially overlapped with orthographic projections of the second scan signal line, the light emitting signal line, the second initial signal line and the power supply connection line on the base substrate.

13. The display substrate according to claim 12, wherein the orthographic projection of the at least one first pixel opening on the base substrate is not overlapped with an orthographic projection of the first initial signal line on the base substrate, the orthographic projection of the at least one second pixel opening on the base substrate is not overlapped with orthographic projections of the first scan signal line and the power supply connection line on the base substrate, and the orthographic projection of the at least one third pixel opening on the base substrate is not overlapped with orthographic projections of the first scan signal line and the third scan signal line on the base substrate.

14. The display substrate according to claim 1, wherein the plurality of light emitting units comprise at least a first light emitting unit emitting light of a first color, a second light emitting unit emitting light of a second color, and a third light emitting unit emitting light of a third color, the first light emitting unit comprises at least a first anode and a first pixel opening exposing the first anode, the second light emitting unit comprises at least a second anode and a second pixel opening that exposes the second anode, the third light emitting unit comprises at least a third anode and a third pixel opening that exposes the third anode; the second anode is disposed at a side of the first anode in the second direction, and the third anode is disposed at a side of the first anode in the first direction; the pixel drive circuit further comprises a data connection electrode, and the at least one circuit unit further comprises a data signal line connected to the data connection electrode through a data via; orthographic projections of the first pixel opening, the second pixel opening, and the third pixel opening on the base substrate are not overlapped with an orthographic projection of the data via on the base substrate.

15. The display substrate according to claim 14, wherein the plurality of circuit units comprise at least a first circuit unit, a second circuit unit and a third circuit unit disposed sequentially along the first direction, the first circuit unit comprises at least a first pixel drive circuit and a first data signal line connected to the data connection electrode in the first pixel drive circuit through a first data via, the second circuit unit comprises at least a second pixel drive circuit and a second data signal line connected to the data connection electrode in the second pixel drive circuit through a second data via, the third circuit unit comprises at least a third pixel drive circuit and a third data signal line connected to the data connection electrode in the third pixel drive circuit through a third data via, orthographic projections of the first pixel opening and the second pixel opening on the base substrate are at least partially overlapped with an orthographic projection of the first data signal line on the base substrate, and an orthographic projection of the third pixel opening on the base substrate is not overlapped with orthographic projections of the first data signal line, the second data signal line, and the third data signal line on the base substrate.

16. The display substrate according to claim 15, wherein in the first direction, a pitch between the first data signal line and the second data signal line is smaller than a pitch between the second data signal line and the third data signal line, and a pitch between the first data via and the second data via is smaller than a pitch between the second data via and the third data via.

17. The display substrate according to claim 15, wherein the second data via and the third data via are disposed at two sides of the third pixel opening in the first direction, and the first data via is disposed between the first pixel opening and the second pixel opening in the second direction.

18. The display substrate according to claim 14, wherein the pixel drive circuit comprises at least a storage capacitor, and the at least one circuit unit further comprises a first scan signal line, a second scan signal line, a third scan signal line, a light emitting signal line, a first initial signal line, a second initial signal line, and a third initial signal line extending along the first direction and connected to the pixel drive circuit, the first scan signal line is disposed at a side of the storage capacitor in an opposite direction of the second direction, the third scan signal line is disposed at a side of the first scan signal line away from the storage capacitor, the first initial signal line is disposed at a side of the third scan signal line away from the storage capacitor, the light emitting signal line is disposed at a side of the storage capacitor in the second direction, the second scan signal line is disposed at a side of the light emitting signal line away from the storage capacitor, the second initial signal line is disposed at a side of the second scan signal line away from the storage capacitor, the third initial signal line is disposed at a side of the second initial signal line away from the storage capacitor; an orthographic projection of at least one first pixel opening on the base substrate is at least partially overlapped with an orthographic projection of the first initial signal line on the base substrate, an orthographic projection of at least one second pixel opening on the base substrate is at least partially overlapped with orthographic projections of the first scan signal line and the power supply connection line on the base substrate, and an orthographic projection of at least one third pixel opening on the base substrate is at least partially overlapped with orthographic projections of the first scan signal line and the third scan signal line on the base substrate.

19. The display substrate according to claim 18, wherein the orthographic projection of the at least one first pixel opening on the base substrate is not overlapped with an orthographic projection of the power supply connection line on the base substrate, the orthographic projection of the at least one second pixel opening on the base substrate is not overlapped with orthographic projections of the first initial signal line, the second initial signal line, and the third initial signal line on the base substrate, and the orthographic projection of the at least one third pixel opening on the base substrate is not overlapped with orthographic projections of the second scan signal line, the light emitting signal line, the power supply connection line, and the second initial signal line on the base substrate.

20. A display device, comprising the display substrate according to claim 1.

21. (canceled)
